(19) United States
(12) Patent Application Publication
(10) Pub. No.: US 2024/0196663 A1
(43) Pub. Date: Jun. 13, 2024

(54) DISPLAY APPARATUS, DISPLAY MODULE, AND ELECTRONIC DEVICE

(71) Applicant: SEMICONDUCTOR ENERGY LABORATORY CO., LTD., Atsugi-shi (JP)

(72) Inventors: Yasumasa YAMANE, Atsugi (JP); Nozomu SUGISAWA, Isehara (JP); Daiki NAKAMURA, Atsugi (JP); Hitomi SATO, Isehara (JP); Daigo SHIMADA, Atsugi (JP); Takeyoshi WATABE, Atsugi (JP); Nobuharu OHSAWA, Zama (JP); Toshiyuki ISA, Atsugi (JP); Shinya SASAGAWA, Chigasaki (JP); Kentaro SUGAYA, Isehara (JP)

(21) Appl. No.: 18/512,373

(22) Filed: Nov. 17, 2023

(30) Foreign Application Priority Data
Nov. 30, 2022 (JP) 2022-191812
Feb. 8, 2023 (JP) 2023-017616
Apr. 3, 2023 (JP) 2023-060377

(51) Int. Cl. H10K 59/122; H10K 59/80

(52) U.S. Cl. CPC H10K 59/122; H10K 59/80515

(57) ABSTRACT

A novel display device that is highly convenient, useful, or reliable is provided. The display apparatus includes a first light-emitting device, a second light-emitting device, and a first layer. The first light-emitting device includes a first electrode, a second electrode, a first unit between the first electrode and the second electrode, and a second layer between the first electrode and the first unit. The first unit includes a first light-emitting material. The second light-emitting device includes a third electrode, a fourth electrode, a second unit between the third electrode and the fourth electrode, and a third layer between the third electrode and the second unit. The second unit includes a second light-emitting material. The first layer is between the first electrode and the second layer and between the third electrode and the third layer, and overlaps with a first gap between the first electrode and the third electrode.

### BACKGROUND OF THE INVENTION

### 1. Field of the Invention

One embodiment of the present invention relates to a display apparatus, a display module, an electronic device, or a semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display apparatus, a light-emitting apparatus, a power storage device, a memory device, a method for driving any of them, and a method for manufacturing any of them.

### 2. Description of the Related Art

In recent years, higher resolution has been required for display panels. Examples of devices that require high-resolution display panels include a smartphone, a tablet terminal, and a laptop computer. Furthermore, higher resolution has been required for a stationary display apparatus such as a television device or a monitor device along with a higher definition. A device absolutely required to have the highest resolution display panel is a device for virtual reality (VR) or augmented reality (AR).

Examples of the display apparatus that can be used for a display panel include, typically, a liquid crystal display apparatus, a light-emitting apparatus including a light-emitting element such as an organic electroluminescent (EL) element or a light-emitting diode (LED), and electronic paper performing display by an electrophoretic method or the like.

An organic EL element generally has a structure in which, for example, a layer containing a light-emitting organic compound is provided between a pair of electrodes. By voltage application to this element, the light-emitting organic compound can emit light. A display apparatus including such an organic EL element needs no backlight which is necessary for a liquid crystal display apparatus and the like and thus can have advantages such as thinness, lightweight, high contrast, and low power consumption. Patent Document 1, for example, discloses an example of a display apparatus using an organic EL element.

Patent Document 2 discloses a display apparatus using an organic EL device for VR.

As an organic thin film with an excellent electron-injection property and electron-transport property when used as an electron-injection layer of an organic EL element, for example, a single film containing a hexahydropyrimidopyrimidine compound and a second material transporting an electron, and a stacked film of a film containing a hexahydropyrimidopyrimidine compound and a film containing the second material are known (Patent Document 3).

### REFERENCES

[Patent Document 1] Japanese Published Patent Application No. 2002-324673
[Patent Document 2] PCT International Publication No. WO2018/087625
[Patent Document 3] PCT International Publication No. WO2021/045178

### SUMMARY OF THE INVENTION

An object of one embodiment of the present invention is to provide a novel display apparatus that is highly convenient, useful, or reliable. Another object is to provide a novel display module that is highly convenient, useful, or reliable. Another object is to provide a novel electronic device that is highly convenient, useful, or reliable. Another object is to provide a novel display apparatus, a novel display module, a novel electronic device, or a novel semiconductor device.

Note that the description of these objects does not preclude the existence of other objects. In one embodiment of the present invention, there is no need to achieve all these objects. Other objects will be apparent from and can be derived from the description of the specification, the drawings, the claims, and the like.
(1) One embodiment of the present invention is a display apparatus including a first light-emitting device, a second light-emitting device, and a first layer.

The first light-emitting device includes a first electrode, a second electrode, a first unit, and a second layer. The first unit is between the first electrode and the second electrode. The first unit includes a first light-emitting material. The second layer is between the first unit and the first electrode. The second layer has an electrical resistivity greater than or equal to 1×10⁴ Ω·cm and less than or equal to 1×10⁷ Ω·cm in a film state.

The second light-emitting device includes a third electrode, a fourth electrode, a second unit, and a third layer. The third electrode is adjacent to the first electrode. A first gap is between the third electrode and the first electrode. The second unit is between the third electrode and the fourth electrode. The second unit includes a second light-emitting material. The third layer is between the second unit and the third electrode. A second gap is between the third layer and the second layer. The second gap overlaps with the first gap.

The first layer includes a region between the second layer and the first electrode. The first layer includes a region between the third layer and the third electrode. The first layer has a first opening and a second opening. The first opening overlaps with the first electrode. The second opening overlaps with the third electrode. The first layer includes a region overlapping with the first gap between the first opening and the second opening. The first layer has an insulating property.

Accordingly, the third layer can be separated from the second layer. Occurrence of a phenomenon in which current flows between the second layer and the third layer can be suppressed. A material having a low electrical resistivity can be used for the second layer and the third layer. The driving voltages of the first light-emitting device and the second light-emitting device can be reduced. A phenomenon in which one of the first light-emitting device and the second light-emitting device emits light with unintended luminance in accordance with light emission of the other of the first light-emitting device and the second light-emitting device can be suppressed. In addition, the first light-emitting device and the second light-emitting device can be individually driven. Occurrence of a cross talk phenomenon between adjacent light-emitting devices can be suppressed. The color gamut displayable on the display apparatus can be widened. The resolution of the display apparatus can be increased. The aperture ratio of a pixel of the display apparatus can be increased. As a result, a novel display apparatus that is highly convenient, useful, or reliable can be provided.
(2) Another embodiment of the present invention is the display apparatus including a fourth layer.

The fourth layer includes a region between the second electrode and the first unit. The fourth layer includes a region between the fourth electrode and the second unit. The fourth layer is in contact with the first layer in a region overlapping with the first gap. The fourth layer has a third opening and a fourth opening. The third opening overlaps with the first electrode. The fourth opening overlaps with the third electrode.
(3) Another embodiment of the present invention is the display apparatus including a fifth layer.

The fifth layer includes a region between the second electrode and the fourth layer. The fifth layer includes a region between the fourth electrode and the fourth layer. The fifth layer is in contact with the fourth layer in a region overlapping with the first gap. The fifth layer has a fifth opening and a sixth opening. The fifth opening overlaps with the first electrode. The sixth opening overlaps with the third electrode.

Thus, the first gap can be filled with the fifth layer. Moreover, a step due to the first gap can be reduced so as to be close to a flat plane. A phenomenon in which a cut or a split is generated due to the step in the conductive film can be suppressed. As a result, a novel display apparatus that is highly convenient, useful, or reliable can be provided.
(4) One embodiment of the present invention is a display apparatus including a first light-emitting device, a second light-emitting device, and a first layer.

The first light-emitting device includes a first electrode, a second electrode, a first unit, a third unit, and a first intermediate layer. The first unit is between the first electrode and the second electrode. The first unit includes a first light-emitting material. The third unit is between the second electrode and the first unit. The third unit includes a third light-emitting material.

The first intermediate layer is between the third unit and the first unit. The first intermediate layer includes a sixth layer and a seventh layer. The sixth layer is between the third unit and the seventh layer. The sixth layer contains a material having a spin density greater than or equal to 1×10¹⁸ spins/cm³ observed by an electron spin resonance method when the material is in a film state. The seventh layer contains a material having a spin density less than or equal to 1×10¹⁷ spins/cm³, preferably less than 1×10¹⁶ spins/cm³ observed by an electron spin resonance method when the material is in a film state.

The second light-emitting device includes a third electrode, a fourth electrode, a second unit, a fourth unit, and a second intermediate layer. The third electrode is adjacent to the first electrode. A first gap is between the third electrode and the first electrode. The second unit is between the third electrode and the fourth electrode. The second unit includes a second light-emitting material. The fourth unit is between the fourth electrode and the second unit. The fourth unit includes a fourth light-emitting material.

The second intermediate layer is between the fourth unit and the second unit. A third gap is between the second intermediate layer and the first intermediate layer. The third gap overlaps with the first gap,

The first layer includes a region between the first intermediate layer and the first electrode. The first layer includes a region between the second intermediate layer and the third electrode. The first layer has a first opening and a second opening. The first opening overlaps with the first electrode. The second opening overlaps with the third electrode. The first layer includes a region overlapping with the first gap between the first opening and the second opening. The first layer has an insulating property.

Therefore, the first intermediate layer can supply holes to the third unit and supply electrons to the first unit. Furthermore, the first intermediate layer can be formed without a substance with high activity such as an alkali metal or an alkaline earth metal. In addition, the resistance to the air or an impurity such as water can be increased. Moreover, a reduction in emission efficiency due to the air or an impurity such as water can be suppressed. As a result, a novel display apparatus that is highly convenient, useful, or reliable can be provided.
(5) Another embodiment of the present invention is the display apparatus in which the sixth layer has an electrical resistivity greater than or equal to 1×10⁴ Ω·cm and less than or equal to 1×10⁷ Ω·cm in a film state and the seventh layer contains a first organic compound and a second organic compound.

The first organic compound has an acid dissociation constant pKa larger than or equal to 8 and the second organic compound has no pyridine ring, no phenanthroline ring, or one phenanthroline ring.
(6) Another embodiment of the present invention is the display apparatus in which the sixth layer has an electrical resistivity greater than or equal to 1×10⁴ Ω·cm and less than or equal to 1×10⁷ Ω·cm in a film state and the seventh layer contains a first organic compound and a second organic compound.

The first organic compound has an acid dissociation constant pKa larger than or equal to 8 and the second organic compound has an acid dissociation constant pKa smaller than 4.
(7) Another embodiment of the present invention is the display apparatus in which the sixth layer has an electrical resistivity greater than or equal to 1×10⁴ Ω·cm and less than or equal to 1×10⁷ Ω·cm in a film state and the seventh layer contains a first organic compound and a second organic compound.

The first organic compound has an acid dissociation constant pKa larger than or equal to 8 and the second organic compound has a polarization term δp less than or equal to 4.0 MPa^{0.5} of a solubility parameter δ.

Accordingly, the second intermediate layer can be separated from the first intermediate layer. Occurrence of a phenomenon in which current flows between the first intermediate layer and the second intermediate layer can be suppressed. A material having a low electrical resistivity can be used for the first intermediate layer and the second intermediate layer. The driving voltages of the first light-emitting device and the second light-emitting device can be reduced. A phenomenon in which one of the first light-emitting device and the second light-emitting device emits light with unintended luminance in accordance with light emission of the other of the first light-emitting device and the second light-emitting device can be suppressed. In addition, the first light-emitting device and the second light-emitting device can be individually driven. Occurrence of a cross talk phenomenon between adjacent light-emitting devices can be suppressed. The color gamut displayable on the display apparatus can be widened. The resolution of the display apparatus can be increased. The aperture ratio of a pixel of the display apparatus can be increased. The first layer can suppress current flowing from an end portion of the first electrode to the first intermediate layer. In the case where the first unit includes a thin region in a region overlapping with the end portion of the first electrode, the first layer can suppress current flowing from the end portion of the first electrode to the first intermediate layer through the thin region. As a result, a novel display apparatus that is highly convenient, useful, or reliable can be provided.
(8) Another embodiment of the present invention is the display apparatus including a fourth layer.

The fourth layer includes a region between the second electrode and the first unit. The fourth layer includes a region between the fourth electrode and the second unit. The fourth layer is in contact with the first layer in a region overlapping with the first gap. The fourth layer includes a third opening and a fourth opening. The third opening overlaps with the first electrode. The fourth opening overlaps with the third electrode.
(9) Another embodiment of the present invention is the display apparatus including a fifth layer.

The fifth layer includes a region between the second electrode and the fourth layer. The fifth layer includes a region between the fourth electrode and the fourth layer. The fifth layer is in contact with the fourth layer in a region overlapping with the first gap. The fifth layer has a fifth opening and a sixth opening. The fifth opening overlaps with the first electrode. The sixth opening overlaps with the third electrode.

Thus, the first gap can be filled with the fifth layer. Moreover, a step due to the first gap can be reduced so as to be close to a flat plane. A phenomenon in which a cut or a split is generated due to the step in the conductive film can be suppressed. As a result, a novel display apparatus that is highly convenient, useful, or reliable can be provided.
(10) Another embodiment of the present invention is a display module including the display apparatus and at least one of a connector and an integrated circuit.
(11) Another embodiment of the present invention is an electronic device including the display apparatus and at least one of a battery, a camera, a speaker, and a microphone.

Although the block diagram in drawings attached to this specification shows components classified based on their functions in independent blocks, it is difficult to classify actual components based on their functions completely, and one component can have a plurality of functions.

Note that the light-emitting apparatus in this specification includes, in its category, an image display device that uses a light-emitting device. The light-emitting apparatus may also include, in its category, a module in which a light-emitting device is provided with a connector such as an anisotropic conductive film or a tape carrier package (TCP), a module in which a printed wiring board is provided at the end of a TCP, and a module in which an integrated circuit (IC) is directly mounted on a light-emitting device by a chip on glass (COG) method. Furthermore, a lighting device or the like may include the light-emitting apparatus.

One embodiment of the present invention can provide a novel display apparatus that is highly convenient, useful, or reliable. Another embodiment of the present invention can provide a novel display module that is highly convenient, useful, or reliable. Another embodiment of the present invention can provide a novel electronic device that is highly convenient, useful, or reliable. A novel display apparatus can be provided. A novel display module can be provided. A novel electronic device can be provided.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

In the accompanying drawings:

FIGS. 1A to 1D illustrate structures of a display apparatus of an embodiment;

FIGS. 2A and 2B illustrate a structure of a display apparatus of an embodiment;

FIGS. 3A and 3B illustrate a structure of a display apparatus of an embodiment;

FIGS. 4A to 4E illustrate structures of a display apparatus of an embodiment;

FIG. 5 illustrates a structure of a light-emitting device of an embodiment;

FIGS. 6A and 6B illustrate structures of a light-emitting device of an embodiment;

FIGS. 7A to 7C illustrate a structure of a display apparatus of an embodiment;

FIG. 8 illustrates a configuration of a display apparatus of an embodiment;

FIGS. 9A to 9G illustrate a method for manufacturing a display apparatus of an embodiment;

FIG. 10 illustrates a structure of a display module of an embodiment;

FIGS. 11A and 11B illustrate structures of display apparatuses of an embodiment;

FIG. 12 illustrates a structure of a display apparatus of an embodiment;

FIG. 13 illustrates a structure of a display apparatus of an embodiment;

FIG. 14 illustrates a structure of a display apparatus of an embodiment;

FIG. 15 illustrates a structure of a display apparatus of an embodiment;

FIG. 16 illustrates a structure of a display apparatus of an embodiment;

FIG. 17 illustrates a structure of a display module of an embodiment;

FIGS. 18A to 18C illustrates a structure of a display apparatus of an embodiment;

FIG. 19 illustrates a structure of a display apparatus of an embodiment;

FIG. 20 illustrates a structure of a display apparatus of an embodiment;

FIG. 21 illustrates a structure of a display apparatus of an embodiment;

FIG. 22 illustrates a structure of a display apparatus of an embodiment;

FIG. 23 illustrates a structure of a display apparatus of an embodiment;

FIGS. 24A to 24D illustrate examples of electronic devices of an embodiment;

FIGS. 25A to 25F illustrate examples of electronic devices of an embodiment;

FIGS. 26A to 26G illustrate examples of electronic devices of an embodiment;

FIGS. 27A to 27C illustrate a structure of a display apparatus of an example;

FIGS. 28A to 28C illustrate structures of light-emitting devices of an embodiment;

FIG. 29 illustrates a structure of a display apparatus of an example;

FIG. 30 shows current density-luminance characteristics of light-emitting devices of an example;

FIG. 31 shows luminance-current efficiency characteristics of light-emitting devices of an example;

FIG. 32 shows voltage-luminance characteristics of light-emitting devices of an example;

FIG. 33 shows voltage-current density characteristics of light-emitting devices of an example;

FIG. 34 shows luminance-blue index characteristics of light-emitting devices of an example;

FIG. 35 shows emission spectra of light-emitting devices of an example;

FIG. 36 shows current density-luminance characteristics of light-emitting devices of an example;

FIG. 37 shows luminance-current efficiency characteristics of light-emitting devices of an example;

FIG. 38 shows voltage-luminance characteristics of light-emitting devices of an example;

FIG. 39 shows voltage-current density characteristics of light-emitting devices of an example;

FIG. 40 shows emission spectra of light-emitting devices of an example;

FIG. 41 shows current density-luminance characteristics of light-emitting devices of an example;

FIG. 42 shows luminance-current efficiency characteristics of light-emitting devices of an example;

FIG. 43 shows voltage-luminance characteristics of light-emitting devices of an example;

FIG. 44 shows voltage-current density characteristics of light-emitting devices of an example;

FIG. 45 shows emission spectra of light-emitting devices of an example;

FIG. 46 illustrates a method for fabricating a display apparatus of an example;

FIG. 47 illustrates a method for fabricating a display apparatus of an example;

FIG. 48 illustrates a method for fabricating a display apparatus of an example;

FIG. 49 illustrates a method for fabricating a display apparatus of an example;

FIG. 50 illustrates a method for fabricating a display apparatus of an example;

FIG. 51 illustrates a method for fabricating a display apparatus of an example;

FIG. 52 illustrates a method for fabricating a display apparatus of an example;

FIG. 53 illustrates a method for fabricating a display apparatus of an example;

FIG. 54 illustrates a method for fabricating a display apparatus of an example;

FIG. 55 illustrates a method for fabricating a display apparatus of an example;

FIG. 56 illustrates a method for fabricating a display apparatus of an example;

FIG. 57 is a photograph showing a display state of a display apparatus of an example;

FIG. 58 is an electron microscope image illustrating a structure of a display apparatus of an example;

FIGS. 59A to 59C are electron microscope images illustrating a structure of a display apparatus of an example; and

FIGS. 60A to 60C are electron microscope images illustrating a structure of a display apparatus of an example.

### DETAILED DESCRIPTION OF THE INVENTION

One embodiment of the present invention is a display apparatus including a first light-emitting device, a second light-emitting device, and a first layer. The first light-emitting device includes a first electrode, a second electrode, a first unit, and a second layer. The first unit is between the first electrode and the second electrode. The first unit includes a first light-emitting material. The second layer is between the first unit and the first electrode. The second layer has an electrical resistivity greater than or equal to 1×10⁴ Ω·cm and less than or equal to 1×10⁷ Ω·cm in a film state. The second light-emitting device includes a third electrode, a fourth electrode, a second unit, and a third layer. The third electrode is adjacent to the first electrode. A first gap is between the third electrode and the first electrode. The second unit is between the third electrode and the fourth electrode. The second unit includes a second light-emitting material. The third layer is between the second unit and the third electrode. A second gap is between the third layer and the second layer. The second gap overlaps with the first gap. The first layer includes a region between the second layer and the first electrode. The first layer includes a region between the third layer and the third electrode. The first layer has a first opening and a second opening. The first opening overlaps with the first electrode. The second opening overlaps with the third electrode. The first layer includes a region overlapping with the first gap between the first opening and the second opening. The first layer has an insulating property.

Accordingly, the third layer can be separated from the second layer. Occurrence of a phenomenon in which current flows between the second layer and the third layer can be suppressed. A material having a low electrical resistivity can be used for the second layer and the third layer. The driving voltages of the first light-emitting device and the second light-emitting device can be reduced. A phenomenon in which one of the first light-emitting device and the second light-emitting device emits light with unintended luminance in accordance with light emission of the other of the first light-emitting device and the second light-emitting device can be suppressed. In addition, the first light-emitting device and the second light-emitting device can be individually driven. Occurrence of a cross talk phenomenon between adjacent light-emitting devices can be suppressed. The color gamut displayable on the display apparatus can be widened. The resolution of the display apparatus can be increased. The aperture ratio of a pixel of the display apparatus can be increased. As a result, a novel display apparatus that is highly convenient, useful, or reliable can be provided.

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

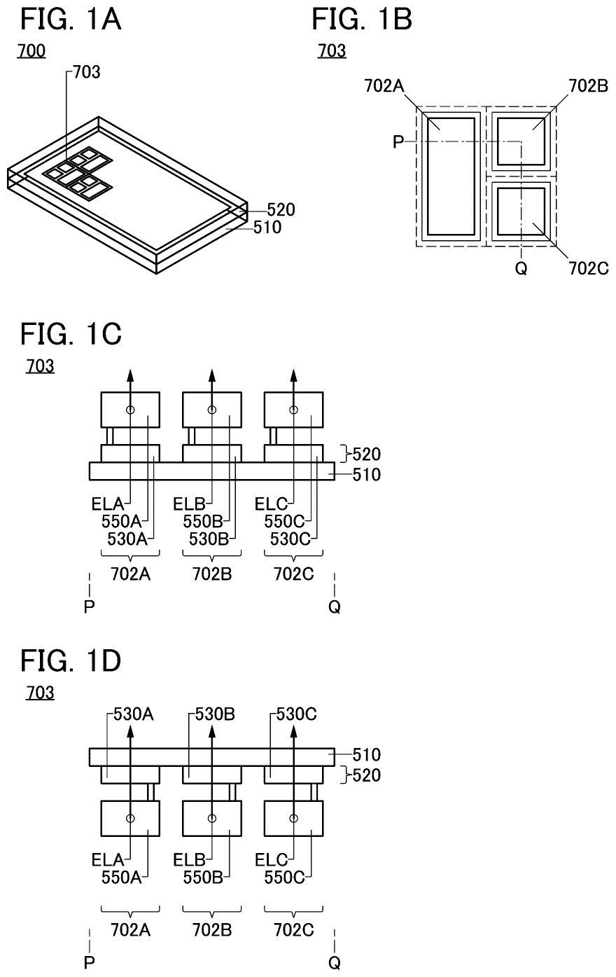

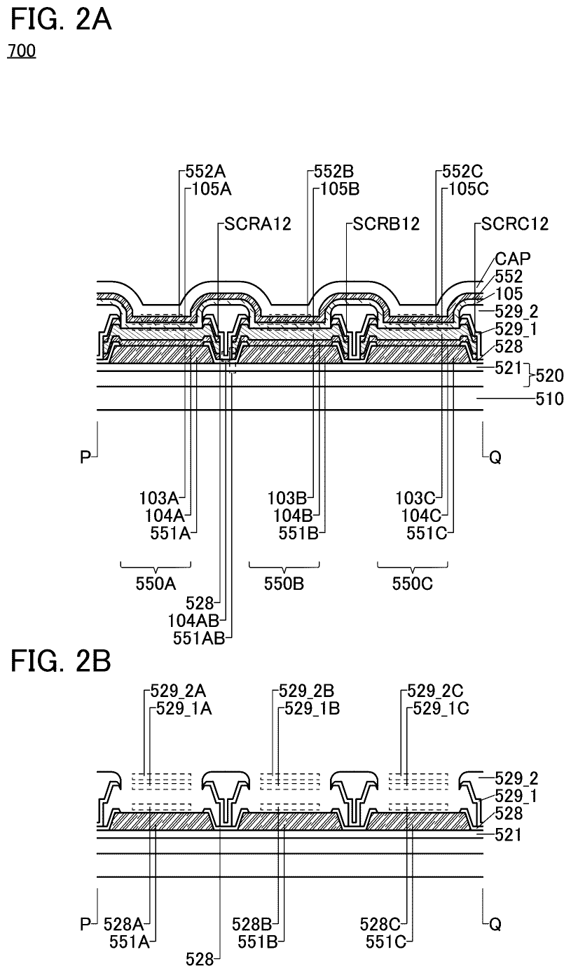

In this embodiment, a structure of a display apparatus of one embodiment of the present invention is described with reference to FIGS. 1A to 1D and FIGS. 2A and 2B.

FIG. 1A is a cross-sectional view illustrating a structure of the display apparatus of one embodiment of the present invention, and FIG. 1B is a top view illustrating part of FIG. 1A. FIG. 1C is a cross-sectional view taken along a cutting line P-Q in FIG. 1B, and FIG. 1D is a cross-sectional view illustrating a structure different from that in FIG. 1C.

FIG. 2A is a cross-sectional view illustrating the structure of the display apparatus of one embodiment of the present invention and FIG. 2B illustrates part of FIG. 2A.

### Structure Example 1 of Display Apparatus

A display apparatus 700 described in this embodiment includes a pixel set 703 (see FIG. 1A). The display apparatus 700 includes a substrate 510 and a functional layer 520.

The pixel set 703 includes a pixel 702A, a pixel 702B, and a pixel 702C (see FIG. 1B).

The pixel 702A includes a light-emitting device 550A and a pixel circuit 530A. The light-emitting device 550A is electrically connected to the pixel circuit 530A (see FIGS. 1C and 1D).

The pixel 702B includes a light-emitting device 550B and a pixel circuit 530B. The light-emitting device 550B is electrically connected to the pixel circuit 530B.

The pixel 702C includes a light-emitting device 550C and a pixel circuit 530C. The light-emitting device 550C is electrically connected to the pixel circuit 530C.

Note that the functional layer 520 includes the pixel circuits 530A, 530B, and 530C. The pixel circuit 530A is positioned between the light-emitting device 550A and the substrate 510, the pixel circuit 530B is positioned between the light-emitting device 550B and the substrate 510, and the pixel circuit 530C is positioned between the light-emitting device 550C and the substrate 510.

In the display apparatus 700 of one embodiment of the present invention, for example, the light-emitting device 550A emits light ELA in a direction where the pixel circuit 530A is not provided, the light-emitting device 550B emits light ELB in a direction where the pixel circuit 530B is not provided, and the light-emitting device 550C emits light ELC in a direction where the pixel circuit 530C is not provided (see FIG. 1C). In other words, the display apparatus 700 of one embodiment of the present invention is a top-emission display apparatus.

In the display apparatus 700 of one embodiment of the present invention, for example, the light-emitting device 550A emits light ELA in a direction where the pixel circuit 530A is provided, the light-emitting device 550B emits light ELB in a direction where the pixel circuit 530B is provided, and the light-emitting device 550C emits light ELC in a direction where the pixel circuit 530C is provided (see FIG. 1D). In other words, the display apparatus 700 of one embodiment of the present invention is a bottom-emission display apparatus.

### Structure Example of Light-Emitting Device 550A

The light-emitting device 550A includes an electrode 551A, an electrode 552A, a unit 103A, and a layer 104A (see FIG. 2A).

The unit 103A is positioned between the electrode 551A and the electrode 552A and contains a light-emitting material EMA. For example, a fluorescent substance, a phosphorescent substance, or a substance exhibiting thermally activated delayed fluorescence can be used for the light-emitting material EMA. Note that the details of a structure applicable to the unit 103A are described in Embodiment 3.

The layer 104A is positioned between the unit 103A and the electrode 551A and has an electrical resistivity greater than or equal to 1×10⁴ Ω·cm and less than or equal to 1×10⁷ Ω·cm in a film state. For example, an electron-accepting substance or a composite material containing an electron-accepting substance and a hole-transport material can be used for the layer 104A. Note that the details of structures applicable to the electrode 551A and the layer 104A are described in Embodiment 4. Moreover, with use of a material deposited over a substrate by an evaporation method as a sample, the properties of the material in a film state can be measured, for example.

### Structure Example of Light-Emitting Device 550B

The light-emitting device 550B includes an electrode 551B, an electrode 552B, a unit 103B, and a layer 104B.

The electrode 551B is adjacent to the electrode 551A and a gap 551AB is positioned between the electrode 551B and the electrode 551A.

The unit 103B is positioned between the electrode 551B and the electrode 552B and contains a light-emitting material EMB. For example, the material that can be used as the light-emitting material EMA can be used as the light-emitting material EMB.

The layer 104B is positioned between the unit 103B and the electrode 551B and a gap 104AB is positioned between the layer 104B and the layer 104A. The gap 104AB overlaps with the gap 551AB.

### Structure Example of Layer 528

The display apparatus 700 described in this embodiment includes a layer 528. The layer 528 includes a region positioned between the layer 104A and the electrode 551A and a region positioned between the layer 104B and the electrode 551B (see FIG. 2A).

The layer 528 has an opening 528A and an opening 528B, which overlap with the electrode 551A and the electrode 551B, respectively (see FIG. 2B).

The layer 528 includes a region overlapping with the gap 551AB between the opening 528A and the opening 528B and has an insulating property.

Accordingly, the layer 104B can be separated from the layer 104A. Occurrence of a phenomenon in which current flows between the layer 104A and the layer 104B can be suppressed. A material having a low electrical resistivity can be used for the layer 104A and the layer 104B. The driving voltages of the light-emitting device 550A and the light-emitting device 550B can be reduced. A phenomenon in which one of the light-emitting device 550A and the light-emitting device 550B emits light with unintended luminance in accordance with light emission of the other of the light-emitting device 550A and the light-emitting device 550B can be suppressed. In addition, the light-emitting device 550A and the light-emitting device 550B can be individually driven. Occurrence of a cross talk phenomenon between adjacent light-emitting devices can be suppressed. The color gamut displayable on the display apparatus can be widened. The resolution of the display apparatus can be increased. The aperture ratio of a pixel of the display apparatus can be increased. As a result, a novel display apparatus that is highly convenient, useful, or reliable can be provided.

### Structure Example of Light-Emitting Device 550C

The light-emitting device 550C includes an electrode 551C, an electrode 552C, a unit 103C, and a layer 104C.

The electrode 551C is adjacent to the electrode 551B.

The unit 103C is positioned between the electrode 551C and the electrode 552C and contains a light-emitting material EMC.

The layer 104C is positioned between the unit 103C and the electrode 551C.

### Structure Example 2 of Display Apparatus

The display apparatus 700 described in this embodiment includes a layer 529_1 (see FIG. 2A).

### Structure Example of Layer 529_1

The layer 529_1 includes a region positioned between the electrode 552A and the unit 103A and a region positioned between the electrode 552B and the unit 103B (see FIG. 2A). The layer 529_1 includes a region in contact with the unit 103A and a region in contact with the unit 103B. The layer 529_1 is in contact with the layer 528 in a region overlapping with the gap 551AB.

The layer 529_1 has an opening 529_1A and an opening 529_1B (see FIG. 2B). The opening 529_1A and the opening 529_1B overlap with the electrode 551A and the electrode 551B, respectively.

The layer 529_1 can be formed by an atomic layer deposition (ALD) method or a chemical vapor deposition (CVD) method, for example. Thus, a film with favorable coverage can be formed.

Specifically, a metal oxide, a metal nitride, or the like can be used for the layer 529_1. For example, aluminum oxide or silicon nitride can be used.

### Structure Example 3 of Display Apparatus

The display apparatus 700 described in this embodiment includes a layer 529_2 (see FIG. 2A).

### Structure Example of Layer 529_2

The layer 529_2 includes a region positioned between the electrode 552A and the layer 529_1 and a region positioned between the electrode 552B and the layer 529_1. The layer 529_2 is in contact with the layer 529_1 in a region overlapping with the gap 551AB.

The layer 529_2 has an opening 529_2A and an opening 529_2B (see FIG. 2B). The opening 529_2A and the opening 529_2B overlap with the electrode 551A and the electrode 551B, respectively. The layer 529_2 has an opening 529_2C.

The layer 529_2 can be formed using a photosensitive resin, for example. Specifically, an acrylic resin or the like can be used.

Thus, the gap 551AB can be filled with the layer 529_2. Moreover, a step due to the gap 551AB can be reduced so as to be close to a flat plane. A phenomenon in which a cut or a split is generated due to the step in a conductive film 552 can be suppressed. As a result, a novel display apparatus that is highly convenient, useful, or reliable can be provided.

### Structure Example 4 of Display Apparatus

The display apparatus 700 described in this embodiment includes an insulating layer 521 and the conductive film 552. The display apparatus 700 further includes a layer 105, a layer SCRA12, a layer SCRB12, and a layer SCRC12.

### Structure Example of Insulating Layer 521

The insulating layer 521 overlaps with the conductive film 552 with the electrodes 551A and 551B therebetween. The electrode 551C is positioned between the insulating layer 521 and the conductive film 552.

### Structure Example of Conductive Film 552

The conductive film 552 includes the electrodes 552A and 552B. The conductive film 552 further includes the electrode 552C.

For example, a conductive material can be used for the conductive film 552. Specifically, a single layer or a stack using a metal, an alloy, or a material containing a conductive compound can be used for the conductive film 552. Note that a structure example that can be employed for the conductive film 552 is described in detail in Embodiment 5.

### Structure Example of Layer 105

The layer 105 includes a layer 105A and a layer 105B. The layer 105 further includes a layer 105C. For the layer 105, a material that facilitates carrier injection from the electrodes 552A, 552B, and 552C can be used. An electron-injection material can be used for the layer 105, for example. Note that a structure example that can be employed for the layer 105 is described in detail in Embodiment 5.

### Structure Example of Layer SCRA12, Layer SCRB12, or Layer SCRC12

For example, a film containing a metal, a metal oxide, an organic material, or an inorganic insulating material can be used as the layer SCRA12, the layer SCRB12, or the layer SCRC12.

In this specification and the like, a device formed using a metal mask or a fine metal mask (FMM) may be referred to as a device having a metal mask (MM) structure. In this specification and the like, a device formed without using a metal mask or an FMM is sometimes referred to as a device having a metal maskless (MML) structure.

This embodiment can be combined with any of the other embodiments in this specification as appropriate.

### Embodiment 2

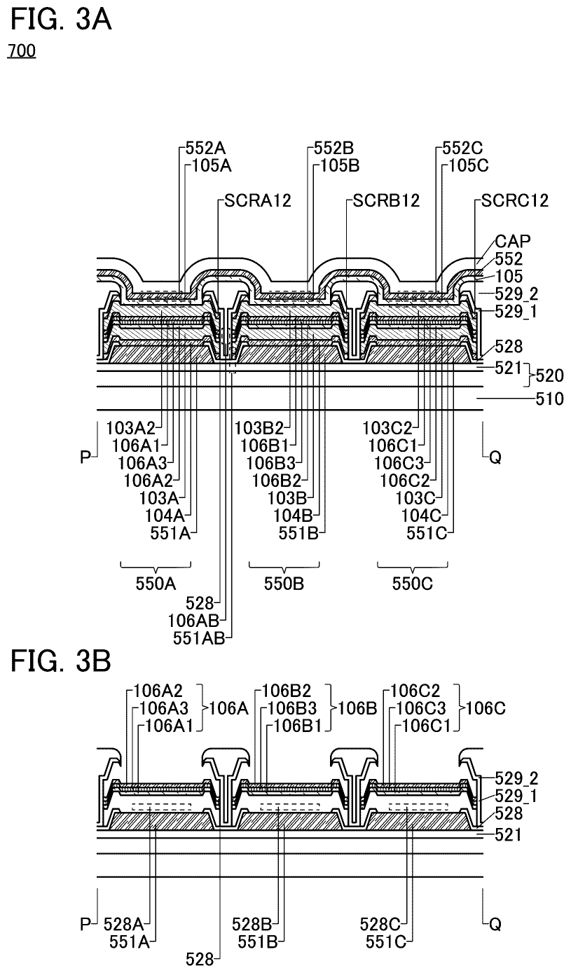

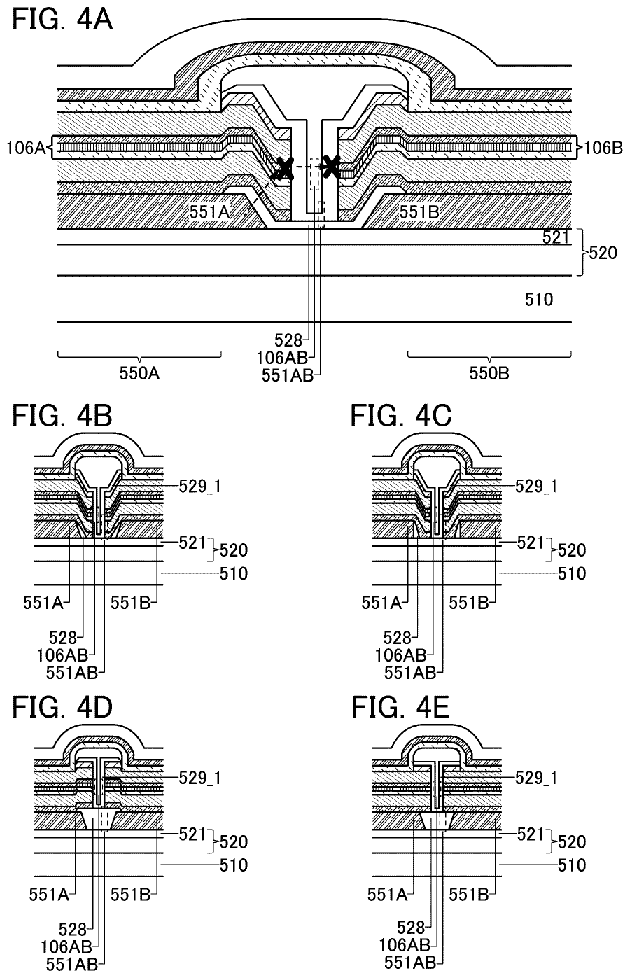

In this embodiment, a structure of a display apparatus of one embodiment of the present invention is described with reference to FIGS. 3A and 3B and FIGS. 4A to 4E.

FIG. 3A is a cross-sectional view illustrating the structure of the display apparatus of one embodiment of the present invention and FIG. 3B illustrates part of FIG. 3A.

FIG. 4A is a cross-sectional view illustrating the structure of the display apparatus of one embodiment of the present invention. FIGS. 4B to 4E illustrate structures different from that in FIG. 4A.

### Structure Example 1 of Display Apparatus

The display apparatus 700 described in this embodiment includes the light-emitting devices 550A and 550B and the layer 528 (see FIG. 3A). Note that the display apparatus 700 is different from the display apparatus described in Embodiment 1 in the structures of the light-emitting devices 550A, 550B, and 550C. Different portions are described in detail here, and the above description is referred to for portions having the same structure as the above.

### Structure Example of Light-Emitting Device 550A

The light-emitting device 550A includes the electrode 551A, the electrode 552A, the unit 103A, a unit 103A2, and an intermediate layer 106A.

The unit 103A is positioned between the electrode 551A and the electrode 552A and contains the light-emitting material EMA.

The unit 103A2 is positioned between the electrode 552A and the unit 103A and contains a light-emitting material EMA2.

The intermediate layer 106A is positioned between the unit 103A2 and the unit 103A. The intermediate layer 106A includes a layer 106A1 and a layer 106A2, and the layer 106A1 is positioned between the unit 103A2 and the layer 106A2 (see FIG. 3B). The intermediate layer 106A further includes a layer 106A3, and the layer 106A3 is positioned between the layer 106A1 and the layer 106A2.

The layer 106A1 contains a material having a spin density greater than or equal to 1×10¹⁸ spins/cm³ observed by an electron spin resonance (ESR) method when the material is in a film state.

The layer 106A2 contains a material having a spin density less than or equal to 1×10¹⁷ spins/cm³, preferably less than 1×10¹⁶ spins/cm³ observed by an ESR method when the material is in a film state.

### Structure Example of Light-Emitting Device 550B

The light-emitting device 550B includes the electrode 551B, the electrode 552B, the unit 103B, a unit 103B2, and an intermediate layer 106B.

The electrode 551B is adjacent to the electrode 551A and the gap 551AB is positioned between the electrode 551B and the electrode 551A.

The unit 103B is positioned between the electrode 551B and the electrode 552B and contains the light-emitting material EMB.

The unit 103B2 is positioned between the electrode 552B and the unit 103B and contains a light-emitting material EMB2.

The intermediate layer 106B is positioned between the unit 103B2 and the unit 103B. The gap 106AB is positioned between the intermediate layer 106B and the intermediate layer 106A and overlaps with the gap 551AB. Note that the structure that can be employed for the intermediate layer 106A can be employed for the intermediate layer 106B.

The intermediate layer 106B includes a layer 106B1 and a layer 106B2, and the layer 106B1 is positioned between the unit 103B2 and the layer 106B2 (see FIG. 3B). The structure that can be employed for the layer 106A1 can be employed for the layer 106B1, and the structure that can be employed for the layer 106A2 can be employed for the layer 106B2. The intermediate layer 106B further includes a layer 106B3, and the layer 106B3 is positioned between the layer 106B1 and the layer 106B2. The structure that can be employed for the layer 106A3 can be employed for the layer 106B3.

### Structure Example of Layer 528

The display apparatus 700 described in this embodiment includes the layer 528 (see FIG. 3A). The layer 528 includes a region positioned between the intermediate layer 106A and the electrode 551A and a region positioned between the intermediate layer 106B and the electrode 551B.

The layer 528 has the opening 528A and the opening 528B, which overlap with the electrode 551A and the electrode 551B, respectively.

The layer 528 includes a region overlapping with the gap 551AB between the opening 528A and the opening 528B and has an insulating property.

For example, an insulating inorganic material, an insulating organic material, or an insulating composite material of an inorganic material and an organic material can be used for the layer 528.

Specifically, an inorganic oxide film, an inorganic nitride film, an inorganic oxynitride film, and the like, or a layered material obtained by stacking some of these films can be used as the layer 528.

For example, a film including any of a silicon oxide film, a silicon nitride film, a silicon oxynitride film, an aluminum oxide film, and the like, or a film including a layered material obtained by stacking some of these films can be used as the layer 528. Note that a silicon nitride film is a dense film and has an excellent function of inhibiting diffusion of impurities.

For example, polyester, polyolefin, polyamide, polyimide, polycarbonate, polysiloxane, or an acrylic resin, or a layered or composite material including resins selected from these can be used for the layer 528.

Therefore, the intermediate layer 106A can supply holes to the unit 103A2 and supply electrons to the unit 103A. Furthermore, the intermediate layer 106A can be formed without a substance with high activity such as an alkali metal or an alkaline earth metal. In addition, the resistance to the air or an impurity such as water can be increased. Moreover, a reduction in emission efficiency due to the air or an impurity such as water can be suppressed. As a result, a novel display apparatus that is highly convenient, useful, or reliable can be provided.

### Structure Example of Light-Emitting Device 550C

The light-emitting device 550C includes the electrode 551C, the electrode 552C, the unit 103C, a unit 103C2, and an intermediate layer 106C. The electrode 551C is adjacent to the electrode 551B.

The unit 103C is positioned between the electrode 551C and the electrode 552C and contains the light-emitting material EMC.

The unit 103C2 is positioned between the electrode 552C and the unit 103C and contains a light-emitting material EMC2.

The intermediate layer 106C is positioned between the unit 103C2 and the unit 103C. The intermediate layer 106C includes a layer 106C1 and a layer 106C2, and the layer 106C1 is positioned between the unit 103C2 and the layer 106C2 (see FIG. 3B). The intermediate layer 106C further includes a layer 106C3, and the layer 106C3 is positioned between the layer 106C1 and the layer 106C2.

### Structure Example 1 of Intermediate Layer 106A

The layer 106A1 of the intermediate layer 106A has an electrical resistivity greater than or equal to 1×10⁴ Ω·cm and less than or equal to 1×10⁷ Ω·cm in a film state,

The layer 106A2 of the intermediate layer 106A contains an organic compound OCA and an organic compound ETMA.

The organic compound OCA has an acid dissociation constant pKa larger than or equal to 8.

As an organic compound having a large acid dissociation constant pKa, an organic compound having a pyrrolidine skeleton, a piperidine skeleton, or a hexahydropyrimidopyrimidine skeleton is preferably used. An organic compound having a guanidine skeleton is preferably used. Specific examples include organic compounds having basic skeletons represented by Structural Formulae (120) to (123) below.

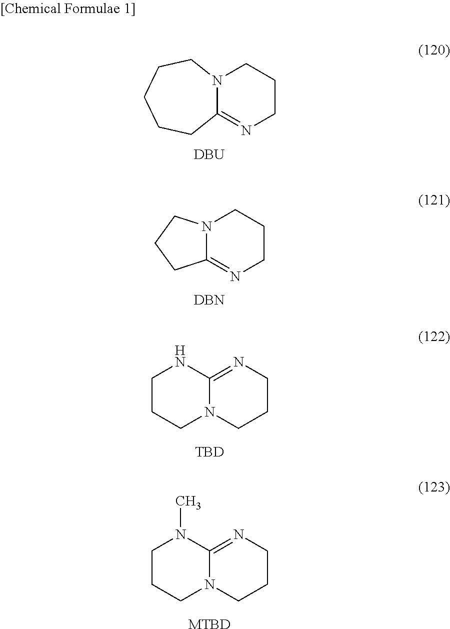

It is preferable that the organic compound having an acid dissociation constant pKa larger than or equal to 8 be specifically an organic compound which includes a bicyclo ring structure having 2 or more nitrogen atoms in the bicyclo ring and a heteroaromatic hydrocarbon ring having 2 to 30 carbon atoms in the ring or an aromatic hydrocarbon ring having 6 to 30 carbon atoms in the ring, and more specifically be an organic compound which has a 1,3,4,6,7,8-hexahydro-2H-pyrimido[1,2-a]pyrimidine group and a heteroaromatic hydrocarbon ring having 2 to 30 carbon atoms in the ring or an aromatic hydrocarbon ring having 6 to 30 carbon atoms in the ring. An organic compound which includes a bicyclo ring structure having 2 or more nitrogen atoms in the bicyclo ring and a heteroaromatic hydrocarbon ring having 2 to 30 carbon atoms in the ring, more specifically an organic compound which has a 1,3,4,6,7,8-hexahydro-2H-pyrimido[1,2-a]pyrimidine group and a heteroaromatic hydrocarbon ring having 2 to 30 carbon atoms in the ring is further preferred.

Further specifically, an organic compound represented by General Formula (G1) below is preferable.

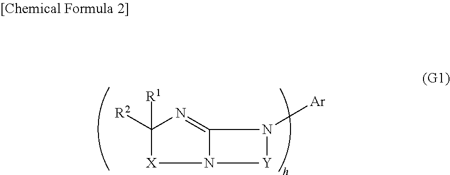

In the organic compound represented by General Formula (G1) above, X represents a group represented by General Formula (G1-1) below, and Y represents a group represented by General Formula (G1-2) below. R¹ and R² each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Ar preferably represents the substituted or unsubstituted heteroaromatic hydrocarbon ring having 2 to 30 carbon atoms in the ring.

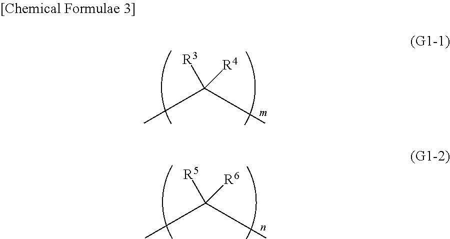

In General Formulae (G1-1) and (G1-2) above, R³ to R⁶ each independently represent hydrogen or deuterium, m represents an integer of 0 to 4, n represents an integer of 1 to 5, and m+1≥n is satisfied (m+1 is n or more). In the case where m or n is 2 or more, R³s may be the same or different from each other, and the same applies to R⁴, R⁵, and R⁶.

The organic compound represented by General Formula (G1) above is preferably any one of compounds represented by General Formulae (G2-1) to (G2-6) below.

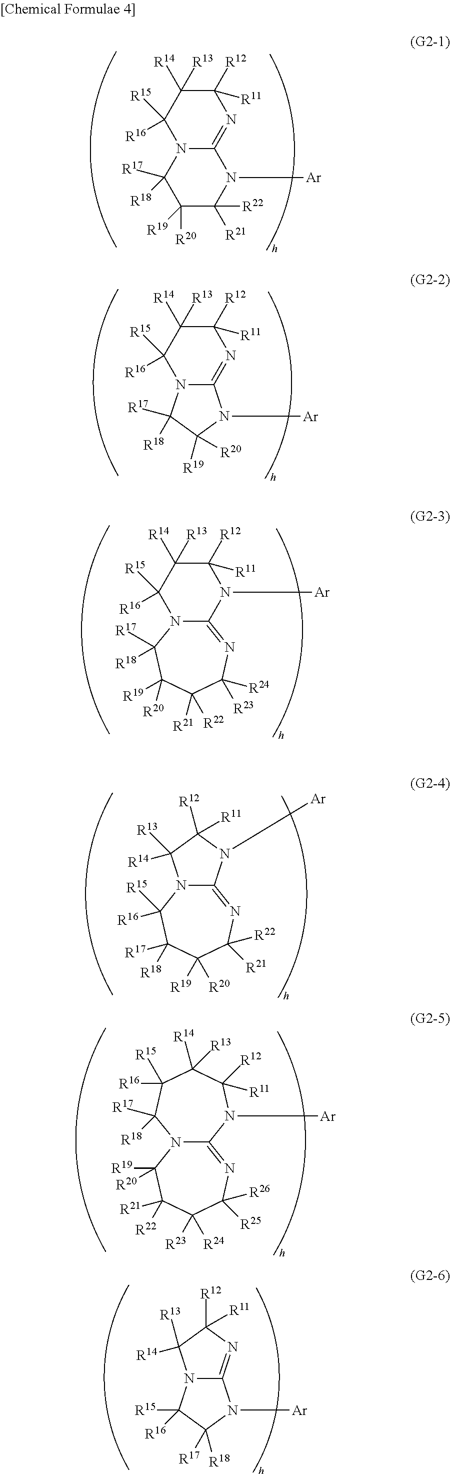

Note that R¹¹ to R²⁶ each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Ar preferably represents the substituted or unsubstituted heteroaromatic hydrocarbon ring having 2 to 30 carbon atoms in the ring.

In General Formula (G1) and General Formulae (G2-1) to (G2-6) above, the substituted or unsubstituted heteroaromatic hydrocarbon ring having 2 to 30 carbon atoms in the ring or the substituted or unsubstituted aromatic hydrocarbon ring having 6 to 30 carbon atoms in the ring that is represented by Ar is specifically a pyridine ring, a bipyridine ring, a pyrimidine ring, a bipyrimidine ring, a pyrazine ring, a bipyrazine ring, a triazine ring, a quinoline ring, an isoquinoline ring, a benzoquinoline ring, a phenanthroline ring, a quinoxaline ring, a benzoquinoxaline ring, a dibenzoquinoxaline ring, an azofluorene ring, a diazofluorene ring, a carbazole ring, a benzocarbazole ring, a dibenzocarbazole ring, a dibenzofuran ring, a benzonaphthofuran ring, a dinaphthofuran ring, a dibenzothiophene ring, a benzonaphthothiophene ring, a dinaphthothiophene ring, a benzofuropyridine ring, a benzofuropyrimidine ring, a benzothiopyridine ring, a benzothiopyrimidine ring, a naphthofuropyridine ring, a naphthofuropyrimidine ring, a naphthothiopyridine ring, a naphthothiopyrimidine ring, an acridine ring, a xanthene ring, a phenothiazine ring, a phenoxazine ring, a phenazine ring, a triazole ring, an oxazole ring, an oxadiazole ring, a thiazole ring, a thiadiazole ring, an imidazole ring, a benzimidazole ring, a pyrazole ring, a pyrrole ring, or the like. In General Formula (G1) and General Formulae (G2-1) to (G2-6) above, the substituted or unsubstituted aromatic hydrocarbon ring having 6 to 30 carbon atoms in the ring that is represented by Ar is specifically a benzene ring, a naphthalene ring, a fluorene ring, a dimethylfluorene ring, a diphenylfluorene ring, a spirofluorene ring, an anthracene ring, a phenanthrene ring, a triphenylene ring, a pyrene ring, a tetracene ring, a chrysene ring, a benzo[a]anthracene ring, or the like. Ar is especially preferably the ring represented by any one of Structural Formulae (Ar-1) to (Ar-27) below.

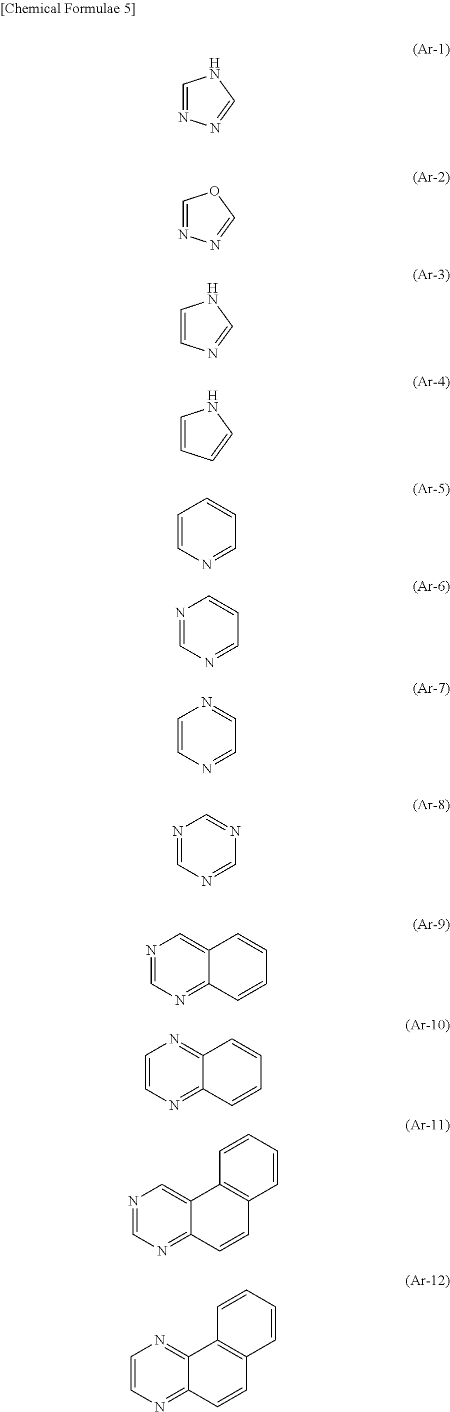

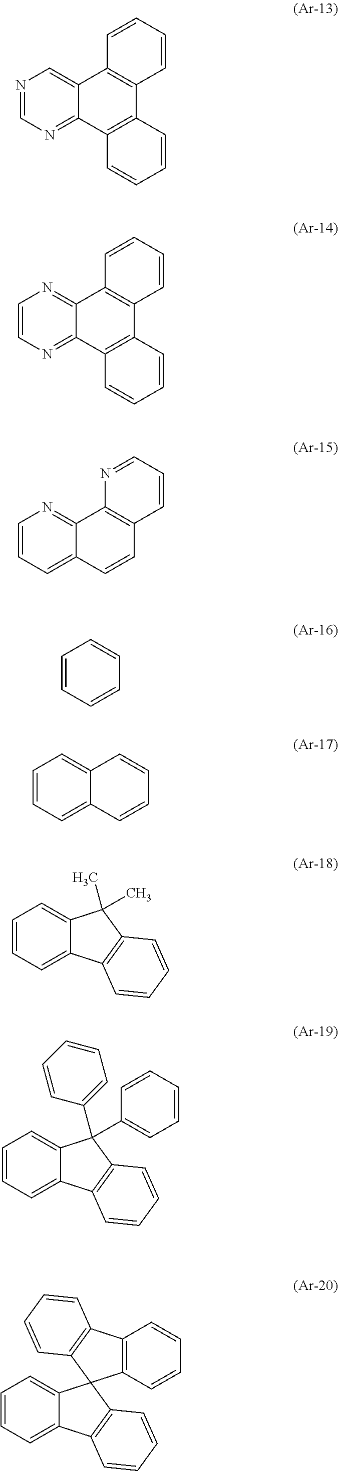

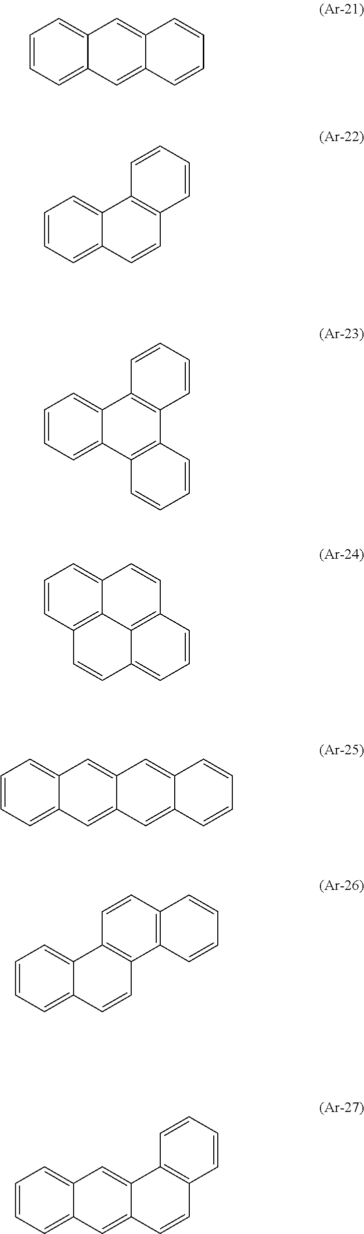

Note that Ar preferably has a nitrogen atom in its ring and is preferably bonded to the skeleton within parentheses in General Formula (G1) above by a bond of the nitrogen atom or a carbon atom adjacent to the nitrogen atom.

As specific examples of the organic compounds represented by General Formula (G1) and General Formulae (G2-1) to (G2-6) above, organic compounds represented by Structural Formulae (101) to (117) below, such as 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF) (Structural Formula 108) and 1-(9,9′-spirobi[9H-fluoren]-2-yl)-1,3,4,6,7,8-hexahydro-2H-pyrimido[1,2-a]pyrimidine (abbreviation: 2hppSF) (Structural Formula 109), can be given.

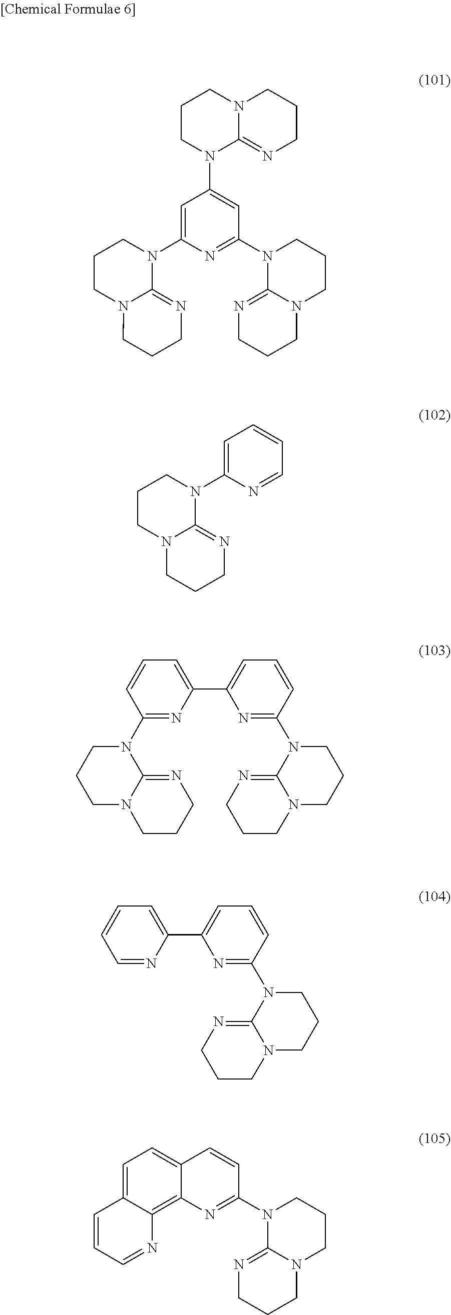 [SMILES: c1c(N2CCCN3CCCN=C32)cc(N2CCCN3CCCN=C32)nc1N1CCCN2CCCN=C21 ; c1ccc(N2CCCN3CCCN=C32)nc1 ; c1cc(-c2cccc(N3CCCN4CCCN=C43)n2)nc(N2CCCN3CCCN=C32)c1 ; c1ccc(-c2cccc(N3CCCN4CCCN=C43)n2)nc1 ; c1cnc2c(c1)ccc1ccc(N3CCCN4CCCN=C43)nc12]

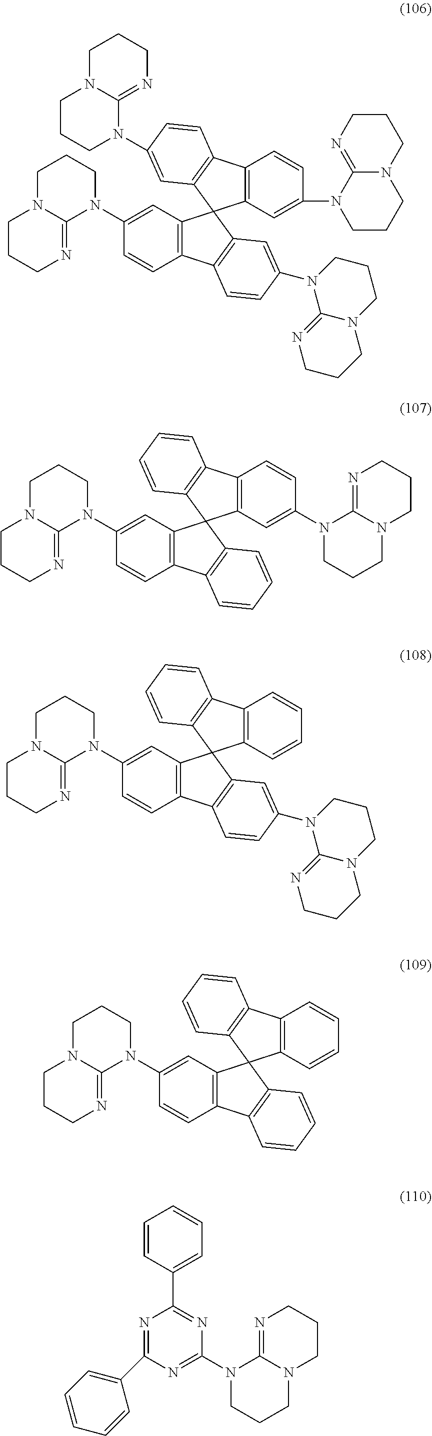 [SMILES: c1cc2c(cc1N1CCCN3CCCN=C31)C1(c3cc(N4CCCN5CCCN=C54)ccc3-2)c2cc(N3CCCN4CCCN=C43)ccc2-c2ccc(N3CCCN4CCCN=C43)cc21 ; c1ccc2c(c1)-c1ccc(N3CCCN4CCCN=C43)cc1C21c2ccccc2-c2ccc(N3CCCN4CCCN=C43)cc21 ; c1ccc2c(c1)-c1ccccc1C21c2cc(N3CCCN4CCCN=C43)ccc2-c2ccc(N3CCCN4CCCN=C43)cc21 ; c1ccc2c(c1)-c1ccccc1C21c2ccccc2-c2ccc(N3CCCN4CCCN=C43)cc21 ; c1ccc(-c2nc(-c3ccccc3)nc(N3CCCN4CCCN=C43)n2)cc1]

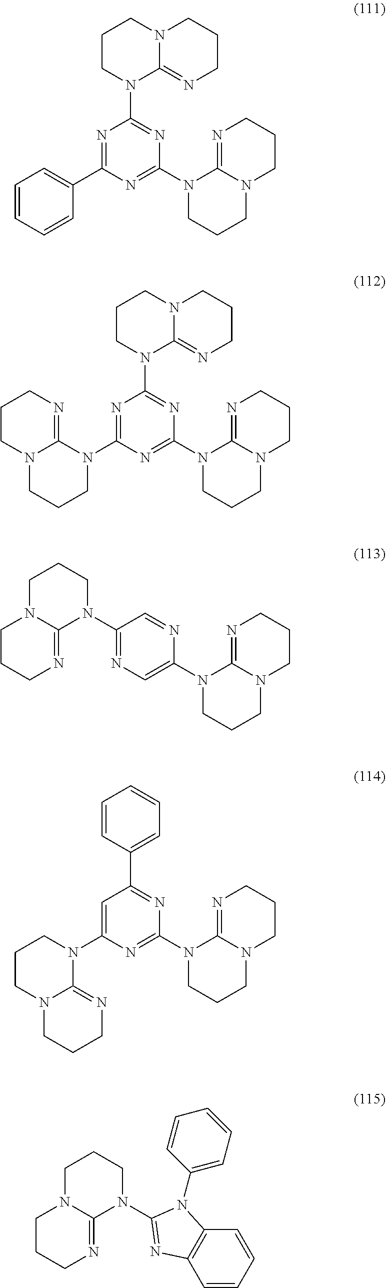 [SMILES: c1ccc(-c2nc(N3CCCN4CCCN=C43)nc(N3CCCN4CCCN=C43)n2)cc1 ; C1CN=C2N(C1)CCCN2c1nc(N2CCCN3CCCN=C32)nc(N2CCCN3CCCN=C32)n1 ; c1nc(N2CCCN3CCCN=C32)cnc1N1CCCN2CCCN=C21 ; c1ccc(-c2cc(N3CCCN4CCCN=C43)nc(N3CCCN4CCCN=C43)n2)cc1 ; c1ccc(-n2c(N3CCCN4CCCN=C43)nc3ccccc32)cc1]

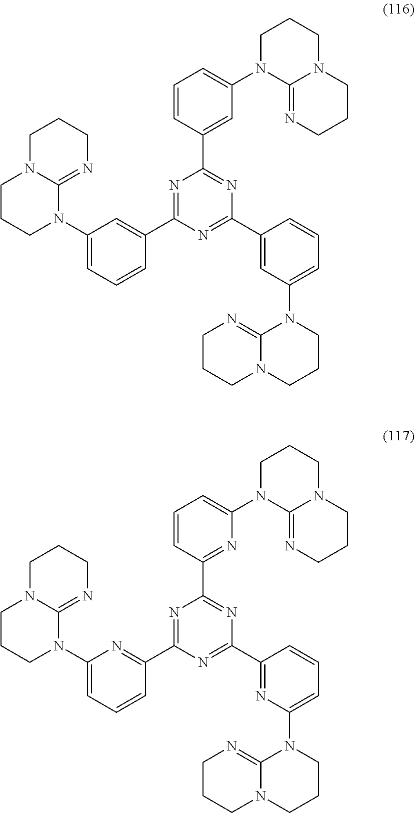 [SMILES: c1cc(-c2nc(-c3cccc(N4CCCN5CCCN=C54)c3)nc(-c3cccc(N4CCCN5CCCN=C54)c3)n2)cc(N2CCCN3CCCN=C32)c1 ; c1cc(-c2nc(-c3cccc(N4CCCN5CCCN=C54)n3)nc(-c3cccc(N4CCCN5CCCN=C54)n3)n2)nc(N2CCCN3CCCN=C32)c1]

Such organic compounds are stable, and unlike an alkali metal, an alkaline earth metal, or a compound thereof, such organic compounds hardly have a concern about metal contamination in a production line and can be easily evaporated, for example, and thus can be favorably used in a light-emitting device fabricated by a photolithography technique. Needless to say, it is also effective to use such organic compounds for a light-emitting device that does not use a photolithography technique.

Note that a strongly basic substance having an acid dissociation constant pKa larger than or equal to 8 preferably has no electron-transport skeleton in order to suppress recombination of an electron injected from the layer 106A3 into the layer 106A2 and a hole injected from the unit 103A and then blocked by the layer 106A2 on the substance. Specifically, for example, an organic compound such as 1-(9,9′-spirobi[9H-fluoren]-2-yl)-1,3,4,6,7,8-hexahydro-2H-pyrimido[1,2-a]pyrimidine (abbreviation: 2hppSF), 2,9-bis(1,3,4,6,7,8-hexahydro-2H-pyrimido[1,2-a]pyrimidin-1-yl)-1,10-phenanthroline (abbreviation: 2,9hpp2Phen), 4,7-di-1-pyrrolidinyl-1,10-phenanthroline (abbreviation: Pyrrd-Phen), or 8,8′-pyridine-2,6-diyl-bis(5,6,7,8-tetrahydroimidazo[1,2-a]pyrimidine) (abbreviation: 2,6tip2Py) can be used as a strongly basic substance having an acid dissociation constant pKa larger than or equal to 8.

A material having a large acid dissociation constant pKa has a large dipole moment. A material having a large dipole moment interacts with a hole. When a material having an acid dissociation constant pKa larger than or equal to 8 is used as the organic compound OCA, for example, the organic compound OCA interacts with a hole and the hole-transport property of the layer 106A2 can be significantly reduced.

In addition, a material having a large acid dissociation constant pKa has high nucleophilicity. A material having high nucleophilicity may react with a molecule, which has received a hole and become a cation radical, to generate a new molecule or a new intermediate state. When a material having an acid dissociation constant pKa larger than or equal to 8 is used as the organic compound OCA, for example, the organic compound OCA generates a new molecule or a new intermediate state and the hole-transport property of the layer 106A2 can be significantly reduced.

Some holes that transfer from the electrode 551A to the layer 106A2 through the unit 103A remain at an interface between the unit 103A and the layer 106A2 or in the layer 106A2. Accordingly, electrons are attracted from the layer 106A1 and an electric double layer is formed on the layer 106A1 side of the layer 106A2. Moreover, a vacuum level between the unit 103A and the layer 106A2 or between the layer 106A2 and the layer 106A1 is distorted and electrons are supplied from the layer 106A2 to the unit 103A.

Note that a material having a large acid dissociation constant pKa has high water solubility. When a material having an acid dissociation constant pKa larger than or equal to 8 is used as the organic compound OCA, for example, the water resistance of the layer 106A2 is lowered and a problem such as peeling of the layer 106A2 from another layer occurs in the manufacturing process. This might cause a defect in a light-emitting device.

A nitrogen-containing heterocyclic compound having a guanidine skeleton can be used as the organic compound OCA, for example. Specifically, an organic compound having a 1,3,4,6,7,8-hexahydro-2H-pyrimido[1,2-a]pyrimidine group, an organic compound having a 5,6,7,8-tetrahydroimidazo[1,2-a]pyrimidine group, or a nitrogen-containing heterocyclic compound having a pyrrolidine group can be used as the organic compound OCA.

For example, an organic compound such as 1-(9,9′-spirobi[9H-fluoren]-2-yl)-1,3,4,6,7,8-hexahydro-2H-pyrimido[1,2-a]pyrimidine (abbreviation: 2hppSF), 2,9-bis(1,3,4,6,7,8-hexahydro-2H-pyrimido[1,2-a]pyrimidin-1-yl)-1,10-phenanthroline (abbreviation: 2,9hpp2Phen), 4,7-di-1-pyrrolidinyl-1,10-phenanthroline (abbreviation: Pyrrd-Phen), or 8,8′-pyridine-2,6-diyl-bis(5,6,7,8-tetrahydroimidazo[1,2-a]pyrimidine) (abbreviation: 2,6tip2Py) can be used as the organic compound OCA. The structures of 2hppSF, 2,9hpp2Phen, Pyrrd-Phen, and 2,6tip2Py are shown below.

Note that the acid dissociation constant pKa of 2hppSF, 2,9hpp2Phen, Pyrrd-Phen, and 2,6tip2Py is 13.95, 13.35, 11.23, and 9.58, respectively.

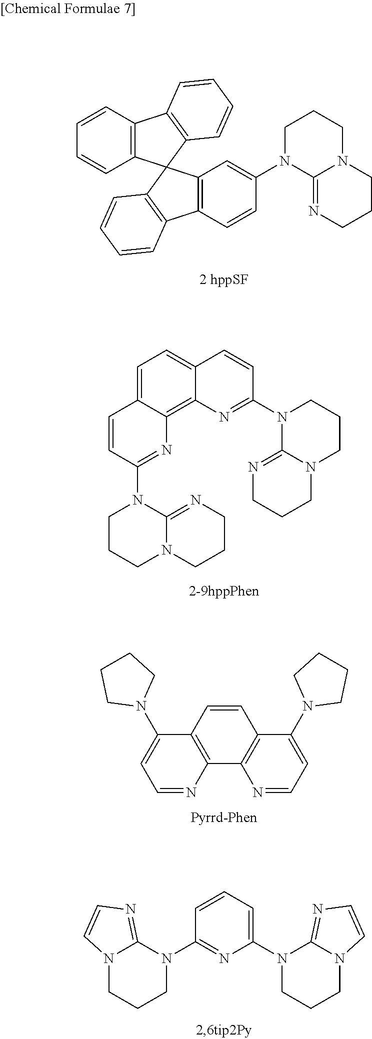 [SMILES: c1ccc2c(c1)-c1ccccc1C21c2ccccc2-c2ccc(N3CCCN4CCCN=C43)cc21 ; c1cc2ccc3ccc(N4CCCN5CCCN=C54)nc3c2nc1N1CCCN2CCCN=C21 ; c1cc(N2CCCC2)c2ccc3c(N4CCCC4)ccnc3c2n1 ; c1cc(N2CCCn3ccnc32)nc(N2CCCn3ccnc32)c1]

The organic compound OCA preferably has no electron-donating property. The organic compound OCA preferably shows no electron-donating property with respect to the organic compound ETMA. When having an electron-donating property, the organic compound OCA easily reacts with an atmospheric component such as water or oxygen and thus becomes unstable. In the intermediate layer containing the organic compounds OCA and ETMA, which is one embodiment of the present invention, the hole-transport property of the layer 106A2 can be significantly low; thus, the intermediate layer can function in a tandem structure even though the organic compound OCA has no electron-donating property. Thus, an intermediate layer and a tandem light-emitting device that are stable with respect to an atmospheric component such as water or oxygen can be fabricated. It is preferable that a small signal or no signal be observed by an ESR method in the layer 106A2 containing the organic compounds OCA and ETMA. For example, spin density derived from a signal observed at a g-factor of around 2.00 is preferably less than or equal to 1×10¹⁷ spins/cm³, further preferably less than 1×10¹⁶ spins/cm³. Note that a film of the material used for the layer 106A2 is formed over a quartz substrate as a sample and the spin density of the film can be observed by an ESR method. The observation can be performed with an ESR spectrometer E500 (manufactured by Bruker Corporation) at room temperature under the conditions where the resonance frequency is 9.56 GHz, the output power is 1 mW, the modulated magnetic field is 50 mT, the modulation width is 0.5 mT, the time constant is 0.04 sec, and the sweep time is 1 min. This method can be employed for observing a signal in the layer 106A2 by an ESR method.

Note that a substance having a high electron-transport property can be used as the organic compound ETMA. The substance having a high electron-transport property refers to a substance having an electron-transport property higher than a hole-transport property. Specifically, it is preferable to use a substance having an electron mobility higher than or equal to 1×10⁻⁷ cm²/Vs, preferably higher than or equal to 1×10⁻⁶ cm²/Vs when the square root of the electric field strength [V/cm] is 600. As the organic compound having a high electron-transport property, a heteroaromatic compound can be used, for example. The heteroaromatic compound refers to a cyclic compound containing at least two different kinds of elements in a ring. Examples of cyclic structures include a three-membered ring, a four-membered ring, a five-membered ring, and a six-membered ring, among which a five-membered ring and a six-membered ring are particularly preferable. The elements contained in the heteroaromatic compound are preferably one or more of nitrogen, oxygen, and sulfur, in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and an organic compound having a π-electron deficient heteroaromatic ring including the nitrogen-containing heteroaromatic compound, is preferably used.

The organic compound ETMA has no pyridine ring, no phenanthroline ring, or one phenanthroline ring, for example. The acid dissociation constant pKa of a pyridine molecule and a phenanthroline molecule is 5.25 and 4.8, respectively. An organic compound having a pyridine ring or a phenanthroline ring has high water solubility; the larger the number of pyridine rings or phenanthroline rings is, the higher the water solubility is. For example, an organic compound having no pyridine ring, no phenanthroline ring, or one phenanthroline ring has lower water solubility than an organic compound having two or more pyridine rings or two or more phenanthroline rings. The water resistance of the layer 106A2 can be higher in the case where an organic compound having no pyridine ring, no phenanthroline ring, or one phenanthroline ring is used as the organic compound ETMA than in the case where an organic compound having two or more pyridine rings or two or more phenanthroline rings is used as the organic compound ETMA. Moreover, occurrence of a problem such as peeling of the layer 106A2 from another layer can be suppressed in the manufacturing process. Accordingly, occurrence of a problem that causes a defect in a light-emitting device can be suppressed.

As the organic compound ETMA, any of the following compounds can be used, for example: 9-(1-naphthyl)-10-[4-(2-naphthyl)phenyl]anthracene (abbreviation: αN-βNPAnth), 2,9-di(naphthalen-2-yl)-4,7-diphenyl-1,10-phenanthroline (abbreviation: NBPhen), 9-[3′-(dibenzothiophen-4-yl)biphenyl-3-yl]naphtho[1′,2′:4,5]furo[2,3-b]pyrazine (abbreviation: 9mDBtBPNfpr), 8-(biphenyl-4-yl)-4-[3-(dibenzothiophen-4-yl)phenyl]-[1]benzofuro[3,2-d]pyrimidine (abbreviation: 8BP-4mDBtPBfpm), 9-[3-(4,6-diphenyl-1,3,5-triazin-2-yl)phenyl]-9′-phenyl-2,3′-bi-9H-carbazole (abbreviation: mPCCzPTzn-02), 4,8-bis[3-(dibenzothiophen-4-yl)phenyl]-[1]benzofuro[3,2-d]pyrimidine (abbreviation: 4,8mDBtP2Bfpm), 4-[3,5-bis(9H-carbazol-9-yl)phenyl]-2-phenyl-6-(biphenyl-4-yl)pyrimidine (abbreviation: 6BP-4Cz2PPm), 2-[3-(3′-dibenzothiophen-4-yl)biphenyl]dibenzo[f,h]quinoxaline (abbreviation: 2mDBTBPDBq-II), 11-[4-(biphenyl-4-yl)-6-phenyl-1,3,5-triazin-2-yl]-11,12-dihydro-12-(biphenyl-4-yl)indolo[2,3-a]carbazole (abbreviation: BP-BPIcz(II)Tzn), and 11-[3′-(dibenzothiophen-4-yl)biphenyl-3-yl]phenanthro[9′,10′:4,5]furo[2,3-b]pyrazine (abbreviation: 11mDBtBPPnfpr). Structural formulae are shown below.

Note that none of αN-βNPAnth, 9mDBtBPNfpr, 8BP-4mDBtPBfpm, mPCCzPTzn-02, 4,8mDBtP2Bfpm, 6BP-4Cz2PPm, 2mDBTBPDBq-II, BP-BPIcz(II)Tzn, and 11mDBtBPPnfpr have a pyridine ring or a phenanthroline ring. In addition, NBPhen has one phenanthroline ring.

### Structure Example 2 of Intermediate Layer 106A

The layer 106A1 of the intermediate layer 106A has an electrical resistivity greater than or equal to 1×10⁴ Ω·cm and less than or equal to 1×10⁷ Ω·cm in a film state,

The layer 106A2 of the intermediate layer 106A contains the organic compound OCA and the organic compound ETMA. The organic compound OCA has an acid dissociation constant pKa larger than or equal to 8 and the organic compound ETMA has an acid dissociation constant pKa smaller than 4. For example, an organic compound having an acid dissociation constant pKa smaller than 4 has lower water solubility than an organic compound having an acid dissociation constant pKa larger than or equal to 4. The water resistance of the layer 106A2 can be higher in the case where an organic compound having an acid dissociation constant pKa smaller than 4 is used as the organic compound ETMA than in the case where an organic compound having an acid dissociation constant pKa larger than or equal to 4 is used as the organic compound ETMA. Moreover, occurrence of a problem such as peeling of the layer 106A2 from another layer can be suppressed in the manufacturing process. Accordingly, occurrence of a problem that causes a defect in a light-emitting device can be suppressed.

For example, αN-βNPAnth, 9mDBtBPNfpr, 8BP-4mDBtPBfpm, mPCCzPTzn-02, 4,8mDBtP2Bfpm, 6BP-4Cz2PPm, 2mDBTBPDBq-II, BP-BPIcz(II)Tzn, or 11mDBtBPPnfpr can be used as the organic compound ETMA.

Note that the acid dissociation constant pKa of 4,8mDBtP2Bfpm is 0.60. In the case where the acid dissociation constant pKa of an organic compound is unknown, the acid dissociation constants pKa of skeletons in the organic compound are calculated and the largest acid dissociation constant pKa can be regarded as the acid dissociation constant pKa of the organic compound. Among the skeletons of 11mDBtBPPnfpr, a pyrazine skeleton has the largest acid dissociation constant pKa, for example. Note that the acid dissociation constant pKa of a pyrazine molecule is 0.37.

### Structure Example 3 of Intermediate Layer 106A

The layer 106A1 of the intermediate layer 106A has an electrical resistivity greater than or equal to 1×10⁴ Ω·cm and less than or equal to 1×10⁷ Ω·cm in a film state,

The layer 106A2 of the intermediate layer 106A contains the organic compound OCA and the organic compound ETMA. The organic compound OCA has an acid dissociation constant pKa larger than or equal to 8 and the organic compound ETMA has a polarization term δp less than or equal to 4.0 MPa^{0.5} of a solubility parameter δ. For example, an organic compound having a polarization term δp less than or equal to 4.0 MPa^{0.5} of a solubility parameter δ has lower water solubility than an organic compound having a polarization term δp greater than 4.0 MPa^{0.5} of a solubility parameter δ. The water resistance of the layer 106A2 can be higher in the case where an organic compound having a polarization term op less than or equal to 4.0 MPa^{0.5} of a solubility parameter δ is used as the organic compound ETMA than in the case where an organic compound having a polarization term δp greater than 4.0 MPa^{0.5} of a solubility parameter δ is used as the organic compound ETMA. Moreover, occurrence of a problem such as peeling of the layer 106A2 from another layer can be suppressed in the manufacturing process. Accordingly, occurrence of a problem that causes a defect in a light-emitting device can be suppressed.

For example, αN-βNPAnth, NBPhen, 9mDBtBPNfpr, 8BP-4mDBtPBfpm, mPCCzPTzn-02, 4,8mDBtP2Bfpm, 6BP-4Cz2PPm, 2mDBTBPDBq-II, BP-BPIcz(II)Tzn, or 11mDBtBPPnfpr can be used as the organic compound ETMA.

Note that the polarization term δp of the solubility parameter δ of αN-βNPAnth, NBPhen, 9mDBtBPNfpr, 8BP-4mDBtPBfpm, mPCCzPTzn-02, 6BP-4Cz2PPm, 4,8mDBtP2Bfpm, 2mDBTBPDBq-II, BP-BPIcz(II)Tzn, and 11mDBtBPPnfpr is 4.0 MPa^{0.5}, 4.0 MPa^{0.5}, 3.8 MPa^{0.5}, 3.5 MPa^{0.5}, 3.5 MPa^{0.5}, 3.4 MPa^{0.5}, 3.4 MPa^{0.5}, 3.2 MPa^{0.5}, 3.2 MPa^{0.5}, and 3.1 MPa^{0.5}, respectively.

Accordingly, the intermediate layer 106B can be separated from the intermediate layer 106A. Occurrence of a phenomenon in which current flows between the intermediate layer 106A and the intermediate layer 106B can be suppressed. A material having a low electrical resistivity can be used for the intermediate layer 106A and the intermediate layer 106B. The driving voltages of the light-emitting device 550A and the light-emitting device 550B can be reduced. A phenomenon in which one of the light-emitting device 550A and the light-emitting device 550B emits light with unintended luminance in accordance with light emission of the other of the light-emitting device 550A and the light-emitting device 550B can be suppressed. In addition, the light-emitting device 550A and the light-emitting device 550B can be individually driven. Occurrence of a cross talk phenomenon between adjacent light-emitting devices can be suppressed. The color gamut displayable on the display apparatus can be widened. The resolution of the display apparatus can be increased. The aperture ratio of a pixel of the display apparatus can be increased. The layer 528 can suppress current flowing from an end portion of the electrode 551A to the intermediate layer 106A. In the case where the unit 103A includes a thin region in a region overlapping with the end portion of the electrode 551A, the layer 528 can suppress current flowing from the end portion of the electrode 551A to the intermediate layer 106A through the thin region. As a result, a novel display apparatus that is highly convenient, useful, or reliable can be provided.

The intermediate layer 106B is separated from the intermediate layer 106A, and occurrence of a phenomenon in which current flows between the intermediate layer 106A and the intermediate layer 106B can be suppressed (see FIG. 4A). The layer 528 can suppress current flowing from the end portion of the electrode 551A to the intermediate layer 106A (see FIG. 4A). Note that X in the drawing indicates that current flowing through the intermediate layer 106A is suppressed.

For example, the layer 528 can have a shape in contact with not a top surface but a side surface of the electrode 551A (see FIGS. 4B and 4C). Note that FIG. 4B illustrates the case where the end portion of the electrode 551A is tapered and the angle between the side surface of the end portion of the electrode 551A and the insulating layer 521 is smaller than 90°. FIG. 4C illustrates the case where the angle between the side surface of the end portion of the electrode 551A and the insulating layer 521 is 90°. Either structure can be formed by a method in which the electrode 551A is formed, an insulating film is formed, and then anisotropic etching is performed on the insulating film without using a mask. The manufacturing process can be thus simplified. In addition, improvement in the yield can be expected. Moreover, the manufacturing cost can be reduced.

Alternatively, for example, the layer 528 can have a shape filling a step formed in the gap 551AB (see FIGS. 4D and 4E). Note that FIG. 4D illustrates the case where the thickness of the layer 528 is larger than the depth of the step formed in the gap 551AB. For example, an insulating film thick enough to fill the step formed in the gap 551AB is formed by a coating method and then an unnecessary portion of the insulating film is removed by a photolithography method, whereby the layer 528 can be formed. FIG. 4E illustrates the case where the thickness of the layer 528 is equal to the depth of the step formed in the gap 551AB. For example, an insulating film thick enough to fill the step formed in the gap 551AB is formed and then an unnecessary portion of the insulating film is removed by a chemical mechanical polishing (CMP) method, whereby the layer 528 can be formed to have a predetermined shape.

### Structure Example 2 of Display Apparatus

The display apparatus 700 described in this embodiment includes the layer 529_1 (see FIG. 3A).

### Structure Example of Layer 529_1

The layer 529_1 includes a region positioned between the electrode 552A and the unit 103A and a region positioned between the electrode 552B and the unit 103B. The layer 529_1 includes a region in contact with the unit 103A, a region in contact with the unit 103A2, a region in contact with the unit 103B, and a region in contact with the unit 103B2. The layer 529_1 is in contact with the layer 528 in a region overlapping with the gap 551AB.

The layer 529_1 has the opening 529_1A and the opening 529_1B (see FIG. 3B). The opening 529_1A and the opening 529_1B overlap with the electrode 551A and the electrode 551B, respectively.

The layer 529_1 can be formed by an ALD method or a CVD method, for example. Thus, a film with favorable coverage can be formed.

Specifically, a metal oxide, a metal nitride, or the like can be used for the layer 529_1. For example, aluminum oxide or silicon nitride can be used.

### Structure Example 3 of Display Apparatus

The display apparatus 700 described in this embodiment includes the layer 529_2 (see FIG. 3A).

### Structure Example of Layer 529_2

The layer 529_2 includes a region positioned between the electrode 552A and the layer 529_1 and a region positioned between the electrode 552B and the layer 529_1. The layer 529_2 is in contact with the layer 529_1 in a region overlapping with the gap 551AB.

The layer 529_2 has the opening 529_2A and the opening 529_2B. The opening 529_2A and the opening 529_2B overlap with the electrode 551A and the electrode 551B, respectively.

The layer 529_2 can be formed using a photosensitive resin, for example. Specifically, an acrylic resin or the like can be used.

Thus, the gap 551AB can be filled with the layer 529_2. Moreover, a step due to the gap 551AB can be reduced so as to be close to a flat plane. A phenomenon in which a cut or a split is generated due to the step in the conductive film 552 can be suppressed. As a result, a novel display apparatus that is highly convenient, useful, or reliable can be provided.

### Structure Example 4 of Display Apparatus

The display apparatus 700 described in this embodiment includes the insulating layer 521 and the conductive film 552. The display apparatus 700 further includes the layer 105, the layer SCRA12, the layer SCRB12, and the layer SCRC12.

### Structure Example of Insulating Layer 521

The insulating layer 521 overlaps with the conductive film 552 with the electrodes 551A and 551B therebetween. The electrode 551C is positioned between the insulating layer 521 and the conductive film 552.

### Structure Example of Conductive Film 552

The conductive film 552 includes the electrodes 552A and 552B. The conductive film 552 further includes the electrode 552C.

For example, a conductive material can be used for the conductive film 552. Specifically, a single layer or a stack using a metal, an alloy, or a material containing a conductive compound can be used for the conductive film 552. Note that a structure example that can be employed for the conductive film 552 is described in detail in Embodiment 5.

### Structure Example of Layer 105

The layer 105 includes the layer 105A and the layer 105B. The layer 105 further includes the layer 105C. For the layer 105, a material that facilitates carrier injection from the electrodes 552A, 552B, and 552C can be used. An electron-injection material can be used for the layer 105, for example. Note that a structure example that can be employed for the layer 105 is described in detail in Embodiment 5.

### Structure Example of Layer SCRA12, Layer SCRB12, or Layer SCRC12

For example, a film containing a metal, a metal oxide, an organic material, or an inorganic insulating material can be used as the layer SCRA12, the layer SCRB12, or the layer SCRC12. Note that the layer SCRA12 has a function of protecting the layers 104A, 106A2, 106A3, and 106A1 and the units 103A and 103A2 in the manufacturing process. The layer SCRB12 has a function of protecting the layers 104B, 106B2, 106B3, and 106B1 and the units 103B and 103B2 in the manufacturing process. The layer SCRC12 has a function of protecting the layers 104C, 106C2, 106C3, and 106C1 and the units 103C and 103C2 in the manufacturing process.

This embodiment can be combined with any of the other embodiments in this specification as appropriate.

### Embodiment 3

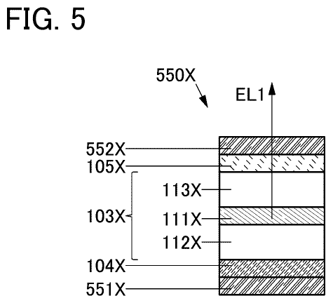

In this embodiment, a structure of a light-emitting device that can be used for a display apparatus of one embodiment of the present invention is described with reference to FIG. 5.

FIG. 5 is a cross-sectional view illustrating the structure of the light-emitting device that can be used for the display apparatus of one embodiment of the present invention.

The structure of a light-emitting device 550X described in this embodiment can be employed for a display apparatus of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### Structure Example of Light-Emitting Device 550X

The light-emitting device 550X described in this embodiment includes an electrode 551X, an electrode 552X, and a unit 103X. The electrode 552X overlaps with the electrode 551X, and the unit 103X is positioned between the electrode 552X and the electrode 551X.

### Structure Example of Unit 103X

The unit 103X has a single-layer structure or a stacked-layer structure. For example, the unit 103X includes a layer 111X, a layer 112X, and a layer 113X (see FIG. 5). The unit 103X has a function of emitting light ELX.

The layer 111X is positioned between the layer 113X and the layer 112X, the layer 113X is positioned between the electrode 552X and the layer 111X, and the layer 112X is positioned between the layer 111X and the electrode 551X.

For example, a layer selected from functional layers such as a light-emitting layer, a hole-transport layer, an electron-transport layer, and a carrier-blocking layer can be used for the unit 103X. A layer selected from functional layers such as a hole-injection layer, an electron-injection layer, an exciton-blocking layer, and a charge-generation layer can also be used for the unit 103X.

### Structure Example of Layer 112X

A hole-transport material can be used for the layer 112X, for example. The layer 112X can be referred to as a hole-transport layer. A material having a wider bandgap than the light-emitting material contained in the layer 111X is preferably used for the layer 112X. In that case, transfer of energy from excitons generated in the layer 111X to the layer 112X can be inhibited.

### [Hole-Transport Material]

A material having a hole mobility of 1×10⁻⁶ cm²/Vs or higher can be suitably used as the hole-transport material.

As the hole-transport material, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

The following are examples that can be used as a compound having an aromatic amine skeleton: 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP) can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV) can be used.

As a compound having a furan skeleton, for example, 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II) can be used.

### Structure Example of Layer 113X

An electron-transport material, a material having an anthracene skeleton, and a mixed material can be used for the layer 113X, for example. The layer 113X can be referred to as an electron-transport layer. A material having a wider bandgap than the light-emitting material contained in the layer 111X is preferably used for the layer 113X. In that case, transfer of energy from excitons generated in the layer 111X to the layer 113X can be inhibited.

### [Electron-Transport Material]

For example, a material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In this case, the electron-transport property in the electron-transport layer can be suppressed. The amount of electrons injected into the light-emitting layer can be controlled. The light-emitting layer can be prevented from having excess electrons.

For example, a metal complex or an organic compound having a π-electron deficient heteroaromatic ring skeleton can be used as the electron-transport material.

As a metal complex, bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can be used, for example.

As an organic compound having a r-electron deficient heteroaromatic ring skeleton, a heterocyclic compound having a polyazole skeleton, a heterocyclic compound having a diazine skeleton, a heterocyclic compound having a pyridine skeleton, a heterocyclic compound having a triazine skeleton, or the like can be used, for example. In particular, the heterocyclic compound having a diazine skeleton or the heterocyclic compound having a pyridine skeleton has favorable reliability and thus is preferable. In addition, the heterocyclic compound having a diazine (pyrimidine or pyrazine) skeleton has a high electron-transport property to contribute to a reduction in driving voltage.

As a heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II) can be used, for example.

As a heterocyclic compound having a diazine skeleton, 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,8-bis[3-(dibenzothiophen-4-yl)phenyl]benzo[h]quinazoline (abbreviation: 4,8mDBtP2Bqn) can be used, for example.

As a heterocyclic compound having a pyridine skeleton, 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be used, for example.

As a heterocyclic compound having a triazine skeleton, 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnfBPTzn-02) can be used, for example.

### [Material Having Anthracene Skeleton]

An organic compound having an anthracene skeleton can be used for the layer 113X. In particular, an organic compound having both an anthracene skeleton and a heterocyclic skeleton can be suitably used.

For example, an organic compound having both an anthracene skeleton and a nitrogen-containing five-membered ring skeleton can be used for the layer 113X. Alternatively, an organic compound having both an anthracene skeleton and a nitrogen-containing five-membered ring skeleton where two heteroatoms are included in a ring can be used for the layer 113X. Specifically, it is preferable to use, as the heterocyclic skeleton, a pyrazole ring, an imidazole ring, an oxazole ring, a thiazole ring, or the like.

For example, an organic compound having both an anthracene skeleton and a nitrogen-containing six-membered ring skeleton can be used for the layer 113X. Alternatively, an organic compound having both an anthracene skeleton and a nitrogen-containing six-membered ring skeleton where two heteroatoms are included in a ring can be used for the layer 113X. Specifically, it is preferable to use, as the heterocyclic skeleton, a pyrazine ring, a pyrimidine ring, a pyridazine ring, or the like.

### Structure Example of Mixed Material

A material in which a plurality of kinds of substances are mixed can be used for the layer 113X. Specifically, a mixed material which contains an alkali metal, an alkali metal compound, or an alkali metal complex and an electron-transport substance can be used for the layer 113X. Note that the electron-transport material preferably has a highest occupied molecular orbital (HOMO) level of −6.0 eV or higher.

The mixed material can be suitably used for the layer 113X in combination with a structure using a composite material, which is separately described, for the layer 104X. For example, a composite material of an electron-accepting substance and a hole-transport material can be used for the layer 104X. Specifically, a composite material of an electron-accepting substance and a substance having a relatively deep HOMO level HM1, which is higher than or equal to −5.7 eV and lower than or equal to −5.4 eV, can be used for the layer 104X (see FIG. 5). Using the mixed material for the layer 113X in combination with the structure using such a composite material for the layer 104X leads to an increase in the reliability of the light-emitting device.

Furthermore, a structure using a hole-transport material for the layer 112X is preferably combined with the structure using the mixed material for the layer 113X and the composite material for the layer 104X. For example, a substance having a HOMO level HM2, which differs by −0.2 eV to 0 eV from the relatively deep HOMO level HM1, can be used for the layer 112X (see FIG. 5). This leads to an increase in the reliability of the light-emitting device. Note that in this specification and the like, the structure of the above-described light-emitting device may be referred to as a Recombination-Site Tailoring Injection structure (ReSTI structure).

The concentration of the alkali metal, the alkali metal compound, or the alkali metal complex preferably changes in the thickness direction of the layer 113X (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

### Structure Example 1 of Layer 111X

Either a structure containing a light-emitting material or a structure containing a light-emitting material and a host material can be employed for the layer 111X, for example. The layer 111X can be referred to as a light-emitting layer. The layer 111X is preferably provided in a region where holes and electrons are recombined. This allows efficient conversion of energy generated by recombination of carriers into light and emission of the light.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having reflectivity to the layer 111X be adjusted and the layer 111X be placed in an appropriate position in accordance with an emission wavelength. With this structure, the amplitude can be increased by utilizing an interference phenomenon between light reflected by the electrode or the like and light emitted from the layer 111X. Light with a predetermined wavelength can be intensified and the spectrum of the light can be narrowed. In addition, bright light emission colors with high intensity can be obtained. In other words, the layer 111X is placed in an appropriate position between electrodes and the like, and thus a microcavity structure can be formed.

For example, a fluorescent substance, a phosphorescent substance, or a substance exhibiting thermally activated delayed fluorescence (TADF) (also referred to as a TADF material) can be used for the light-emitting material. Thus, energy generated by recombination of carriers can be released as the light ELX from the light-emitting material (see FIG. 5).

### [Fluorescent Substance]

A fluorescent substance can be used for the layer 111X. For example, fluorescent substances exemplified below can be used for the layer 111X. Note that fluorescent substances that can be used for the layer 111X are not limited to the following, and a variety of known fluorescent substances can be used for the layer 111X.

Specifically, any of the following fluorescent substances can be used: 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N,N′-(pyrene-1,6-diyl)bis[(6,N-diphenylbenzo[b]naphtho[1,2-d]furan)-8-amine] (abbreviation: 1,6BnfAPrn-03), N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), and the like.

Condensed aromatic diamine compounds typified by pyrenediamine compounds such as 1,6FLPAPrn, 1,6mMemFLPAPrn, and 1,6BnfAPrn-03 are particularly preferable because they have high hole-trapping properties and have high emission efficiency or high reliability.

Other examples of fluorescent substances include N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, 9,10-diphenyl-2-[N-phenyl-N-(9-phenyl-carbazol-3-yl)-amino]-anthracene (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracene-2-amine (abbreviation: 2YGABPhA), N,N,9-triphenylanthracene-9-amine (abbreviation: DPhAPhA), coumarin 545T, N,N′-diphenylquinacridone (abbreviation: DPQd), rubrene, and 5,12-bis(biphenyl-4-yl)-6,11-diphenyltetracene (abbreviation: BPT).

Other examples of fluorescent substances include 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis {2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM).

### [Phosphorescent Substance]

A phosphorescent substance can be used for the layer 111X. For example, phosphorescent substances exemplified below can be used for the layer 111X. Note that phosphorescent substances that can be used for the layer 111X are not limited to the following, and a variety of known phosphorescent substances can be used for the layer 111X.

For example, any of the following can be used for the layer 111X: an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, a platinum complex, and the like.

### [Phosphorescent Substance (Blue)]

As an organometallic iridium complex having a 4H-triazole skeleton or the like, tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato)iridium(III) (abbreviation: [Ir(Prptz1-Me)₃]), or the like can be used.

As an organometallic iridium complex having an imidazole skeleton or the like, fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or the like can be used. As an organometallic iridium complex having a phenylpyridine derivative with an electron-withdrawing group as a ligand, or the like, bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: Ir(CF₃ppy)₂(pic)), bis[2-(4′,6′-difluorophenyl)pyridinato-N,C^{2′}]iridium(III) acetylacetonate (abbreviation: FIracac), or the like can be used. These substances are compounds exhibiting blue phosphorescence and having an emission wavelength peak at 440 nm to 520 nm.

### [Phosphorescent Substance (Green)]

As an organometallic iridium complex having a pyrimidine skeleton or the like, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like can be used.

As an organometallic iridium complex having a pyrazine skeleton or the like, (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like can be used.

As an organometallic iridium complex having a pyridine skeleton or the like, tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), or the like can be used.

Examples of a rare earth metal complex are tris(acetylacetonato) (monophenanthroline)terbium(III) (abbreviation: [Tb(acac)₃(Phen)]), and the like.

These are compounds that mainly exhibit green phosphorescence and have an emission wavelength peak at 500 nm to 600 nm. Note that an organometallic iridium complex having a pyrimidine skeleton has distinctively high reliability or emission efficiency.

### [Phosphorescent Substance (Red)]

As an organometallic iridium complex having a pyrimidine skeleton or the like, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(d1npm)₂(dpm)]), or the like can be used.

As an organometallic iridium complex having a pyrazine skeleton or the like, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), or the like can be used.

As a rare earth metal complex or the like, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato](monophenanthroline)europium(III) (abbreviation: [Eu(TTA)₃(Phen)]), or the like can be used.

As a platinum complex or the like, 2,3,7,8,12,13,17,18-octaethyl-21H,23H-porphyrin platinum(II) (abbreviation: PtOEP) or the like can be used.

These are compounds that exhibit red phosphorescence and have an emission peak at 600 nm to 700 nm. Furthermore, the organometallic iridium complexes having a pyrazine skeleton can provide red light emission with chromaticity favorably used for display apparatuses.

### [Substance Exhibiting Thermally Activated Delayed Fluorescence (TADF)]

A TADF material can be used for the layer 111X. When a TADF material is used as the light-emitting substance, the S1 level of a host material is preferably higher than that of the TADF material. In addition, the T1 level of the host material is preferably higher than that of the TADF material.

For example, any of the TADF materials exemplified below can be used as the light-emitting material. Note that without being limited thereto, a variety of known TADF materials can be used.

In the TADF material, the difference between the S1 level and the T1 level is small, and reverse intersystem crossing (upconversion) from the triplet excited state into the singlet excited state can be achieved by a small amount of thermal energy. Thus, the singlet excited state can be efficiently generated from the triplet excited state. In addition, the triplet excitation energy can be converted into luminescence.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used as the TADF material.

Specifically, the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

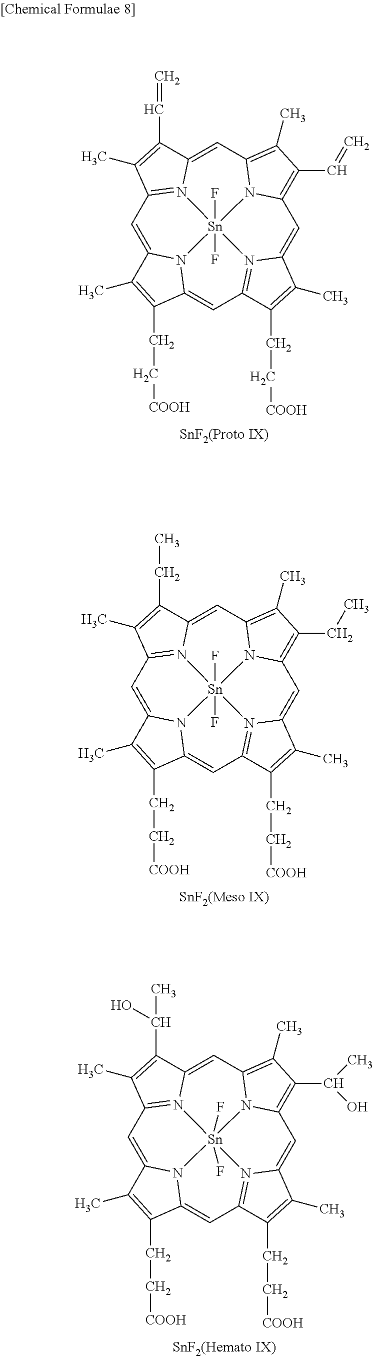

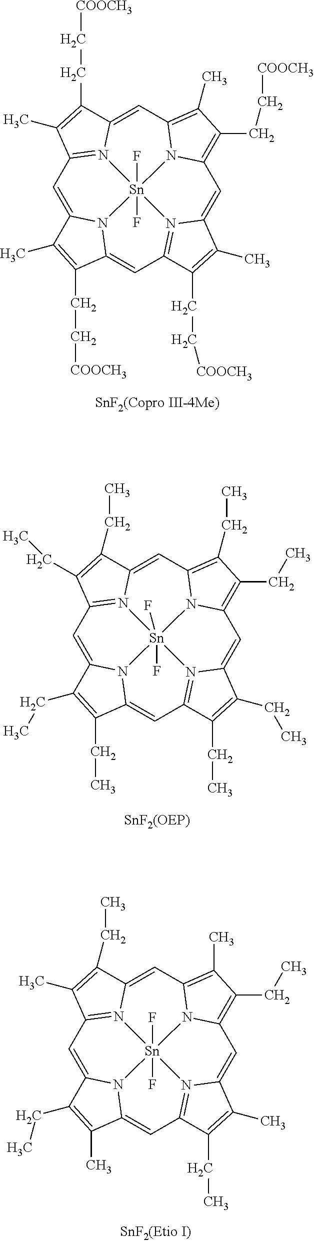

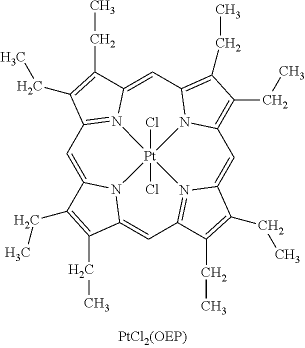

Furthermore, a heterocyclic compound having one or both of a r-electron rich heteroaromatic ring and a π-electron deficient heteroaromatic ring can be used, for example, as the TADF material.

Specifically, the following compounds whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

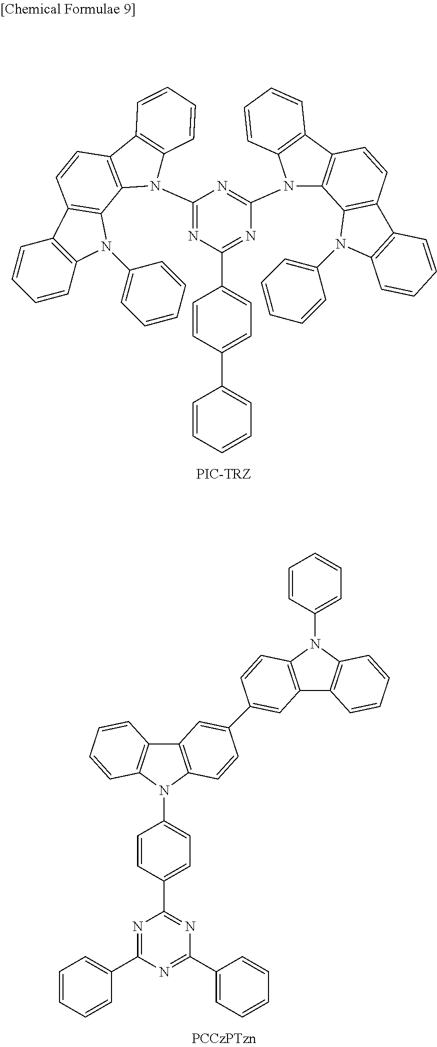 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

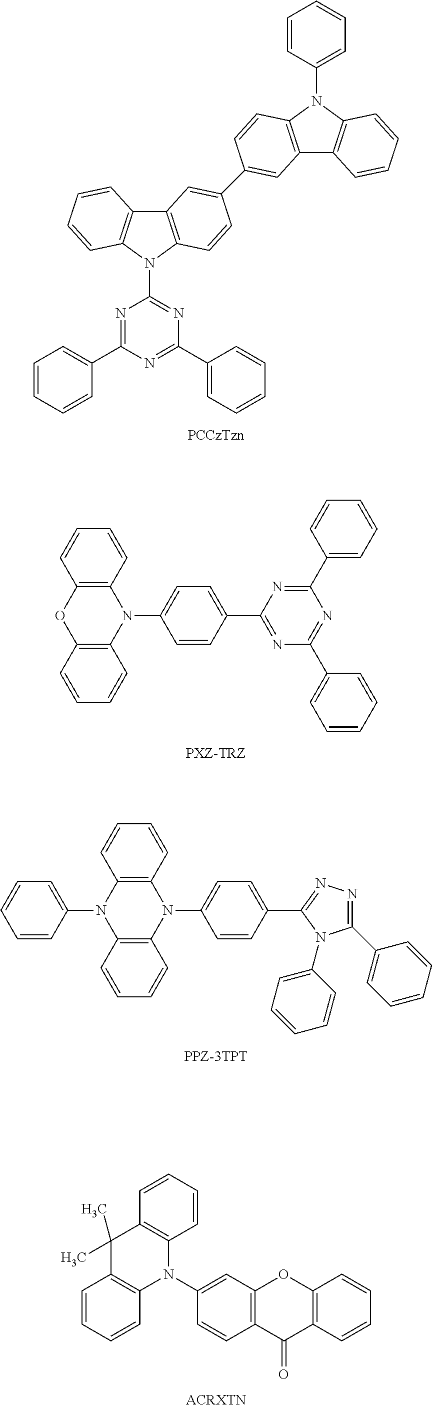 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21]

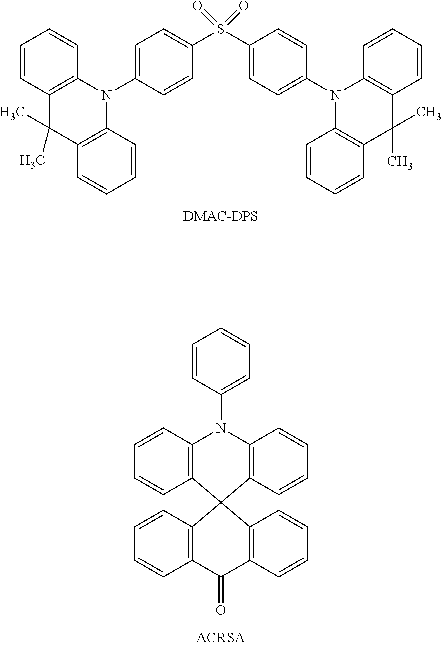 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Such a heterocyclic compound is preferable because of having high electron-transport and bolo-transport properties owing to a π-electron rich heteroaromatic ring and π-electron deficient heteroaromatic ring, Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high electron-accepting properties and high reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a T-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane and boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, a r-electron deficient skeleton and a π-electron rich skeleton can be used instead of at least one of the π-electron deficient heteroaromatic ring and the π-electron rich heteroaromatic ring.

### Structure Example 2 of Layer 111X

A carrier-transport material can be used as the host material. For example, a hole-transport material, an electron-transport material, a substance exhibiting thermally activated delayed fluorescence (TADF), a material having an anthracene skeleton, or a mixed material can be used as the host material. A material having a wider bandgap than the light-emitting material contained in the layer 111X is preferably used as the host material. Thus, transfer of energy from excitons generated in the layer 111X to the host material can be inhibited.

### [Hole-Transport Material]

A material having a hole mobility of 1×10⁻⁶ cm²/Vs or higher can be suitably used as the hole-transport material. For example, a hole-transport material that can be used for the layer 112X can be used for the layer 111X.

### [Electron-Transport Material]

A metal complex or an organic compound having a r-electron deficient heteroaromatic ring skeleton can be used as the electron-transport material. For example, an electron-transport material that can be used for the layer 113X can be used for the layer 111X.

### [Material Having Anthracene Skeleton]

An organic compound having an anthracene skeleton can be used as the host material. An organic compound having an anthracene skeleton is particularly preferable in the case where a fluorescent substance is used as the light-emitting substance. Thus, a light-emitting device with high emission efficiency and high durability can be obtained.

Among the organic compounds having an anthracene skeleton, an organic compound having a diphenylanthracene skeleton, in particular, a 9,10-diphenylanthracene skeleton, is chemically stable and thus is preferable. The host material preferably has a carbazole skeleton because the hole-injection and hole-transport properties are improved. In particular, the host material preferably has a dibenzocarbazole skeleton because the HOMO level thereof is shallower than that of the host material having a carbazole skeleton by approximately 0.1 eV so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

Examples of the substances that can be used include 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-[4-(2-naphthyl)phenyl]anthracene (abbreviation: αN-βNPAnth), 9-[4-(9-phenylcarbazol-3-yl)]phenyl-10-phenylanthracene (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 3-[4-(1-naphthyl)phenyl]-9-phenyl-9H-carbazole (abbreviation: PCPN), and the like.

In particular, CzPA, cgDBCzPA, 2mBnfPPA, and PCzPA have excellent characteristics.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on the lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no x bond and a saturated hydrocarbon are preferably used. Specific examples include an alkyl group having 3 to 10 carbon atoms, a substituted or unsubstituted cycloalkyl group having 3 to carbon atoms, and a trialkylsilyl group having 3 to 10 carbon atoms. It is further preferable that the fluorescent substance have a plurality of protecting groups. The substituents having no r bond are poor in carrier-transport performance; therefore, the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a r bond, further preferably has an aromatic ring, and still further preferably has a condensed aromatic ring or a condensed heteroaromatic ring.

Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

For example, the TADF material that can be used as the light-emitting material can be used as the host material.

### Structure Example 1 of Mixed Material

A material in which a plurality of kinds of substances are mixed can be used as the host material. For example, a material which includes an electron-transport material and a hole-transport material can be used as the mixed material. The weight ratio of the hole-transport material to the electron-transport material contained in the mixed material is (the hole-transport material/the electron-transport material)=(1/19) or more and (19/1) or less. Thus, the carrier-transport property of the layer 111X can be easily adjusted and a recombination region can be easily controlled.

### Structure Example 2 of Mixed Material

In addition, a material mixed with a phosphorescent substance can be used as the host material. When a fluorescent substance is used as the light-emitting substance, a phosphorescent substance can be used as an energy donor for supplying excitation energy to the fluorescent substance.

### Structure Example 3 of Mixed Material

A mixed material containing a material to form an exciplex can be used as the host material. For example, a material in which an emission spectrum of a formed exciplex overlaps with a wavelength on the lowest-energy-side absorption band of the light-emitting substance can be used as the host material. This enables smooth energy transfer and improves emission efficiency. The driving voltage can be suppressed. With such a structure, light emission can be efficiently obtained by exciplex-triplet energy transfer (ExTET), which is energy transfer from the exciplex to the light-emitting substance (phosphorescent material).

A phosphorescent substance can be used as at least one of the materials forming an exciplex. Accordingly, reverse intersystem crossing can be used. Triplet excitation energy can be efficiently converted into singlet excitation energy.

Combination of an electron-transport material and a hole-transport material whose HOMO level is higher than or equal to that of the electron-transport material is preferable for forming an exciplex. The lowest unoccupied molecular orbital (LUMO) level of the hole-transport material is preferably higher than or equal to that of the electron-transport material. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the hole-transport material and the electron-transport material are mixed is shifted to the longer wavelength side than the emission spectrum of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient PL lifetime of the mixed film has longer lifetime components or a larger proportion of delayed components than the transient PL lifetime of each of the materials, observed by comparison of transient photoluminescence (PL) of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of these materials.

This embodiment can be combined with any of the other embodiments in this specification as appropriate.

### Embodiment 4

In this embodiment, a structure of a light-emitting device that can be used for a display apparatus of one embodiment of the present invention is described with reference to FIG. 5.

The structure of the light-emitting device 550X described in this embodiment can be employed for a display apparatus of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### Structure Example of Light-Emitting Device 550X

The light-emitting device 550X described in this embodiment includes the electrode 551X, the electrode 552X, the unit 103X, and the layer 104X (see FIG. 5).

The electrode 552X overlaps with the electrode 551X, and the unit 103X is positioned between the electrode 552X and the electrode 551X. The layer 104X is positioned between the electrode 551X and the unit 103X. For example, the structure described in Embodiment 3 can be employed for the unit 103X.

### Structure Example of Electrode 551X

For example, a conductive material can be used for the electrode 551X. Specifically, a single layer or a stack using a metal, an alloy, or a film containing a conductive compound can be used for the electrode 551X.

A film that efficiently reflects light can be used for the electrode 551X, for example. Specifically, an alloy containing silver, copper, and the like, an alloy containing silver, palladium, and the like, or a metal film of aluminum or the like can be used for the electrode 551X.

For example, a metal film that transmits part of light and reflects another part of light can be used for the electrode 551X. Thus, a microcavity structure can be provided in the light-emitting device 550X. Alternatively, light with a predetermined wavelength can be extracted more efficiently than light with the other wavelengths. Alternatively, light with a narrow spectral half-width can be extracted. Alternatively, light of a bright color can be extracted.

For example, a film having a property of transmitting visible light can be used for the electrode 551X. Specifically, a single layer or a stack using a metal film, an alloy film, a conductive oxide film, or the like that is thin enough to transmit light can be used for the electrode 551X.

In particular, a material having a work function higher than or equal to 4.0 eV can be suitably used for the electrode 551X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

For another example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

### Structure Example 1 of Layer 104X

A hole-injection material can be used for the layer 104X, for example. The layer 104X can be referred to as a hole-injection layer.

For example, a material having a hole mobility lower than or equal to 1×10⁻³ cm²/Vs when the square root of the electric field strength [V/cm] is 600 can be used for the layer 104X. A film having an electrical resistivity greater than or equal to 1×10⁴ Ω·cm and less than or equal to 1×10⁷ Ω·cm can be used as the layer 104X. The electrical resistivity of the layer 104X is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### Structure Example 2 of Layer 104X

Specifically, an electron-accepting substance can be used for the layer 104X. Alternatively, a composite material containing a plurality of kinds of substances can be used for the layer 104X. This can facilitate the injection of holes from the electrode 551X, for example. Alternatively, the driving voltage of the light-emitting device 550X can be reduced.

### [Electron-Accepting Substance]

An organic compound or an inorganic compound can be used as the electron-accepting substance. The electron-accepting substance can extract electrons from an adjacent hole-transport layer or a hole-transport material by the application of an electric field.

For example, a compound having an electron-withdrawing group (a halogen group or a cyano group) can be used as the electron-accepting substance. Note that an electron-accepting organic compound is easily evaporated, which facilitates film deposition. Thus, the productivity of the light-emitting device 550X can be increased.

Specifically, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylene-1,3,4,5,6,8,9,10-octafluoro-7H-pyren-2-ylidene)malononitrile, or the like can be used.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferred.

Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

For the electron-accepting substance, a transition metal oxide such as a molybdenum oxide, a vanadium oxide, a ruthenium oxide, a tungsten oxide, or a manganese oxide can be used.

It is possible to use any of the following materials: phthalocyanine-based compounds such as phthalocyanine (abbreviation: H₂Pc); phthalocyanine-based complex compounds such as copper(II) phthalocyanine (abbreviation: CuPc); and compounds having an aromatic amine skeleton such as 4,4′-bis[N-(4-diphenylaminophenyl)-N-phenylamino]biphenyl (abbreviation: DPAB) and N,N′-bis[4-bis(3-methylphenyl)aminophenyl]-N,N′-diphenyl-4,4′-diaminobiphenyl (abbreviation: DNTPD).

In addition, high molecular compounds such as poly(3,4-ethylenedioxythiophene)/polystyrenesulfonic acid (abbreviation: PEDOT/PSS), and the like can be used.

### Structure Example 1 of Composite Material

For example, a composite material containing an electron-accepting substance and a hole-transport material can be used for the layer 104X. Accordingly, not only a material having a high work function but also a material having a low work function can also be used for the electrode 551X. Alternatively, a material used for the electrode 551X can be selected from a wide range of materials regardless of its work function.

For the hole-transport material in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility of 1×10⁻⁶ cm²/Vs or higher can be suitably used as the hole-transport material in the composite material. For example, the hole-transport material that can be used for the layer 112X can be used for the composite material.

A substance having a relatively deep HOMO level can be suitably used as the hole-transport material in the composite material. Specifically, the HOMO level is preferably higher than or equal to −5.7 eV and lower than or equal to −5.4 eV. Accordingly, hole injection to the unit 103X can be facilitated. Hole injection to the layer 112X can be facilitated. The reliability of the light-emitting device 550X can be increased.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), or 1,3,5-tris[N-(4-diphenylaminophenyl)-N-phenylamino]benzene (abbreviation: DPA3B) can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, or coronene can be used.

As the aromatic hydrocarbon having a vinyl group, for example, 4,4′-bis(2,2-diphenylvinyl)biphenyl (abbreviation: DPVBi) or 9,10-bis[4-(2,2-diphenylvinyl)phenyl]anthracene (abbreviation: DPVPA) can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can be used.

Furthermore, a substance having any of a carbazole skeleton, a dibenzofuran skeleton, a dibenzothiophene skeleton, and an anthracene skeleton can be suitably used as the hole-transport material in the composite material, for example. Moreover, a substance including any of the following can be used as the hole-transport material in the composite material: an aromatic amine having a substituent that has a dibenzofuran ring or a dibenzothiophene ring, an aromatic monoamine that has a naphthalene ring, and an aromatic monoamine in which a 9-fluorenyl group is bonded to nitrogen of amine through an arylene group. With the use of a substance including an N,N-bis(4-biphenyl)amino group, the reliability of the light-emitting device 550X can be increased.

Specific examples of the above-described substances include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBABNB), 4-[4-(2-naphthyl)phenyl]-4′,4″-diphenyltriphenylamine (abbreviation: BBABNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPBNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

### Structure Example 2 of Composite Material

For example, a composite material including an electron-accepting substance, a hole-transport material, and a fluoride of an alkali metal or a fluoride of an alkaline earth metal can be used as the hole-injection material. In particular, a composite material in which the proportion of fluorine atoms is higher than or equal to 20% can be suitably used. Thus, the refractive index of the layer 104X can be reduced. A layer with a low refractive index can be formed inside the light-emitting device 550X. The external quantum efficiency of the light-emitting device 550X can be improved.

This embodiment can be combined with any of the other embodiments in this specification as appropriate.

### Embodiment 5

In this embodiment, a structure of a light-emitting device that can be used for a display apparatus of one embodiment of the present invention is described with reference to FIG. 5.

The structure of the light-emitting device 550X described in this embodiment can be employed for a display apparatus of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### Structure Example of Light-Emitting Device 550X

The light-emitting device 550X described in this embodiment includes the electrode 551X, the electrode 552X, the unit 103X, and a layer 105X (see FIG. 5).

The electrode 552X includes a region overlapping with the electrode 551X, and the unit 103X includes a region positioned between the electrode 551X and the electrode 552X. The layer 105X includes a region positioned between the unit 103X and the electrode 552X. For example, the structure described in Embodiment 3 can be employed for the unit 103X.

### Structure Example of Electrode 552X

For example, a conductive material can be used for the electrode 552X. Specifically, a single layer or a stack using a metal, an alloy, or a material containing a conductive compound can be used for the electrode 552X.

The material that can be used for the electrode 551X described in Embodiment 4 can be used for the electrode 552X, for example. In particular, a material having a lower work function than the electrode 551X can be suitably used for the electrode 552X. Specifically, a material having a work function lower than or equal to 3.8 eV is preferably used.

For example, an element belonging to Group 1 of the periodic table, an element belonging to Group 2 of the periodic table, a rare earth metal, or an alloy containing any of these elements can be used for the electrode 552X.

Specifically, an element such as lithium (Li) or cesium (Cs), an element such as magnesium (Mg), calcium (Ca), or strontium (Sr), an element such as europium (Eu) or ytterbium (Yb), or an alloy containing any of these elements such as an alloy of magnesium and silver or an alloy of aluminum and lithium can be used for the electrode 552X.

### Structure Example of layer 105X

An electron-injection material can be used for the layer 105X, for example. The layer 105X can be referred to as an electron-injection layer.

Specifically, an electron-donating substance can be used for the layer 105X. Alternatively, a material in which an electron-donating substance and an electron-transport material are combined can be used for the layer 105X. Alternatively, electride can be used for the layer 105X. This can facilitate the injection of electrons from the electrode 552X, for example. Alternatively, not only a material having a low work function but also a material having a high work function can also be used for the electrode 552X. Alternatively, a material used for the electrode 552X can be selected from a wide range of materials regardless of its work function. Specifically, aluminum (Al), silver (Ag), indium oxide-tin oxide (abbreviation: ITO), indium oxide-tin oxide containing silicon or silicon oxide, or the like can be used for the electrode 552X. The driving voltage of the light-emitting device 550X can be reduced.

### [Electron-Donating Substance]

For example, an alkali metal, an alkaline earth metal, a rare earth metal, or a compound thereof (an oxide, a halide, a carbonate, or the like) can be used as the electron-donating substance. Alternatively, an organic compound such as tetrathianaphthacene (abbreviation: TTN), nickelocene, or decamethylnickelocene can be used as the electron-donating substance.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### Structure Example 1 of Composite Material

A material composed of two or more kinds of substances can be used as the electron-injection material. For example, an electron-donating substance and an electron-transport material can be used for the composite material.

### [Electron-Transport Material]

A material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In this case, the amount of electrons injected into the light-emitting layer can be controlled. The light-emitting layer can be prevented from having excess electrons.

A metal complex or an organic compound having a π-electron deficient heteroaromatic ring skeleton can be used as the electron-transport material. For example, an electron-transport material that can be used for the layer 113X can be used for the layer 105X.

### Structure Example 2 of Composite Material

A material including a fluoride of an alkali metal in a microcrystalline state and an electron-transport material can be used for the composite material. Alternatively, a material including a fluoride of an alkaline earth metal in a microcrystalline state and an electron-transport material can be used for the composite material. In particular, a composite material including a fluoride of an alkali metal or a fluoride of an alkaline earth metal at 50 wt % or higher can be suitably used. Alternatively, a composite material including an organic compound having a bipyridine skeleton can be suitably used. Thus, the refractive index of the layer 105X can be reduced. The external quantum efficiency of the light-emitting device 550X can be improved.

### Structure Example 3 of Composite Material

For example, a composite material of a first organic compound including an unshared electron pair and a first metal can be used for the layer 105X. The sum of the number of electrons of the first organic compound and the number of electrons of the first metal is preferably an odd number. The molar ratio of the first metal to 1 mol of the first organic compound is preferably greater than or equal to 0.1 and less than or equal to 10, further preferably greater than or equal to 0.2 and less than or equal to 2, still further preferably greater than or equal to 0.2 and less than or equal to 0.8.

Accordingly, the first organic compound including an unshared electron pair interacts with the first metal and thus can form a singly occupied molecular orbital (SOMO). Furthermore, in the case where electrons are injected from the electrode 552X into the layer 105X, a barrier therebetween can be reduced.

The layer 105X can adopt a composite material that allows the spin density measured by an ESR method to be preferably greater than or equal to 1×10¹⁶ spins/cm³, further preferably greater than or equal to 5×10¹⁶ spins/cm³, still further preferably greater than or equal to 1×10¹⁷ spins/cm³.

### [Organic Compound Including Unshared Electron Pair]

For example, an electron-transport material can be used for the organic compound including an unshared electron pair. For example, a compound having an electron deficient heteroaromatic ring can be used. Specifically, a compound having at least one of a pyridine ring, a diazine ring (a pyrimidine ring, a pyrazine ring, and a pyridazine ring), and a triazine ring can be used. Accordingly, the driving voltage of the light-emitting device 550X can be reduced.

Note that the LUMO level of the organic compound including an unshared electron pair is preferably higher than or equal to −3.6 eV and lower than or equal to −2.3 eV. In general, the HOMO level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris(3′-(pyridin-3-yl)biphenyl-3-yl)-1,3,5-triazine (abbreviation: TmPPPyTz), 2,2′-(1,3-phenylene)bis(9-phenyl-1,10-phenanthroline) (abbreviation: mPPhen2P), or the like can be used as the organic compound including an unshared electron pair. Note that NBPhen has a higher glass transition temperature (Tg) than BPhen and thus has high heat resistance.

Alternatively, for example, copper phthalocyanine can be used as the organic compound including an unshared electron pair. The number of electrons of the copper phthalocyanine is an odd number.

### [First Metal]

When the number of electrons of the first organic compound including an unshared electron pair is an even number, for example, a composite material of the first organic compound and the first metal that belongs to an odd-numbered group in the periodic table can be used for the layer 105X.

For example, manganese (Mn), which is a metal belonging to Group 7, cobalt (Co), which is a metal belonging to Group 9, copper (Cu), silver (Ag), and gold (Au), which are metals belonging to Group 11, aluminum (Al) and indium (In), which are metals belonging to Group 13 are odd-numbered groups in the periodic table. Note that elements belonging to Group 11 have a lower melting point than elements belonging to Group 7 or Group 9 and thus are suitable for vacuum evaporation. In particular, Ag is preferable because of its low melting point. By using a metal having a low reactivity with water or oxygen as the first metal, the moisture resistance of the light-emitting device 550X can be improved.

The use of Ag for the electrode 552X and the layer 105X can increase the adhesion between the layer 105X and the electrode 552X.

When the number of electrons of the first organic compound including an unshared electron pair is an odd number, a composite material of the first organic compound and the first metal that belongs to an even-numbered group in the periodic table can be used for the layer 105X. For example, iron (Fe), which is a metal belonging to Group 8, is an element belonging to an even-numbered group in the periodic table.

### [Electride]

For example, a substance obtained by adding electrons at high concentration to an oxide where calcium and aluminum are mixed can be used, for example, as the electron-injection material.

This embodiment can be combined with any of the other embodiments in this specification as appropriate.

### Embodiment 6

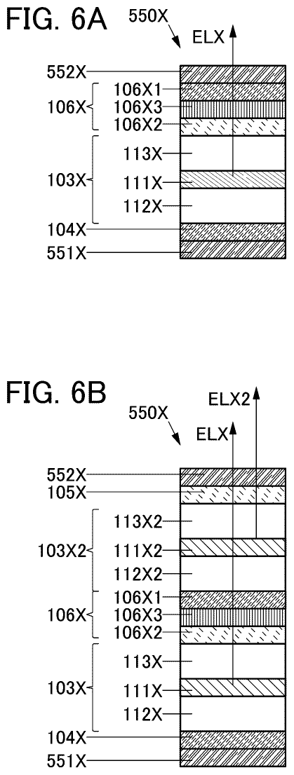

In this embodiment, a structure of a light-emitting device that can be used for a display apparatus of one embodiment of the present invention is described with reference to FIG. 6A.

FIG. 6A is a cross-sectional view illustrating the structure of the light-emitting device of one embodiment of the present invention.

The structure of the light-emitting device 550X described in this embodiment can be employed for a display apparatus of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### Structure Example of Light-Emitting Device 550X

The light-emitting device 550X described in this embodiment includes the electrode 551X, the electrode 552X, the unit 103X, and an intermediate layer 106X (see FIG. 6A).

The electrode 552X includes a region overlapping with the electrode 551X, and the unit 103X includes a region positioned between the electrode 551X and the electrode 552X. The intermediate layer 106X includes a region positioned between the electrode 552X and the unit 103X.

### Structure Example 1 of Intermediate Layer 106X

The intermediate layer 106X has a function of supplying electrons to the anode side and supplying holes to the cathode side when voltage is applied. The intermediate layer 106X can be referred to as a charge-generation layer.

For example, the hole-injection material that can be used for the layer 104X described in Embodiment 4 can be used for the intermediate layer 106X. Specifically, the electron-accepting material or the composite material can be used for the intermediate layer 106X.

Alternatively, for example, a stacked-layer film in which a film containing the composite material and a film containing a hole-transport material are stacked can be used for the intermediate layer 106X. Note that the film containing a hole-transport material is positioned between the film containing the composite material and the cathode.

### Structure Example 2 of Intermediate Layer 106X

A stacked-layer film in which a layer 106X1 and a layer 106X2 are stacked can be used for the intermediate layer 106X. The layer 106X1 includes a region positioned between the unit 103X and the electrode 552X and the layer 106X2 includes a region positioned between the unit 103X and the layer 106X1.

### Structure Example of Layer 106X1

For example, the hole-injection material that can be used for the layer 104X described in Embodiment 4 can be used for the layer 106X1. Specifically, the electron-accepting material or the composite material can be used for the layer 106X1. A film having an electrical resistivity greater than or equal to 1×10⁴ Ω·cm and less than or equal to 1×10⁷ Ω·cm can be used as the layer 106X1. The electrical resistivity of the layer 106X1 is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### Structure Example of Layer 106X2

The material that can be used for the layer 105X described in Embodiment 5 can be used for the layer 106X2, for example.

### Structure Example 3 of Intermediate Layer 106X

A stacked-layer film in which the layer 106X1, the layer 106X2, and a layer 106X3 are stacked can be used for the intermediate layer 106X. The layer 106X3 includes a region positioned between the layer 106X1 and the layer 106X2.

### Structure Example of Layer 106X3

For example, an electron-transport material can be used for the layer 106X3. The layer 106X3 can be referred to as an electron-relay layer. With the layer 106X3, a layer that is on the anode side and in contact with the layer 106X3 can be distanced from a layer that is on the cathode side and in contact with the layer 106X3. Interaction between the layer that is on the anode side and in contact with the layer 106X3 and the layer that is on the cathode side and in contact with the layer 106X3 can be reduced. Electrons can be smoothly supplied to the layer that is on the anode side and in contact with the layer 106X3.

A substance whose LUMO level is positioned between the LUMO level of an electron-accepting substance contained in the layer 106X1 and the LUMO level of the substance contained in the layer 106X2 can be suitably used for the layer 106X3.

For example, a material having a LUMO level in a range higher than or equal to −5.0 eV, preferably higher than or equal to −5.0 eV and lower than or equal to −3.0 eV, can be used for the layer 106X3.

Specifically, a phthalocyanine-based material can be used for the layer 106X3. For example, phthalocyanine (abbreviation: H₂Pc), copper(II) phthalocyanine (abbreviation: CuPc), zinc phthalocyanine (abbreviation: ZnPc), or a metal complex having a metal-oxygen bond and an aromatic ligand can be used for the layer 106X3.

This embodiment can be combined with any of the other embodiments in this specification as appropriate.

### Embodiment 7

In this embodiment, a structure of the light-emitting device 550X that can be used for a display apparatus of one embodiment of the present invention is described with reference to FIG. 6B.

FIG. 6B is a cross-sectional view illustrating a structure of a light-emitting device of one embodiment of the present invention which is different from that in FIG. 6A.

The structure of the light-emitting device 550X described in this embodiment can be employed for a display apparatus of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### Structure Example of Light-Emitting Device 550X

The light-emitting device 550X described in this embodiment includes the electrode 551X, the electrode 552X, the unit 103X, the intermediate layer 106X, and a unit 103X2 (see FIG. 6B).

The unit 103X is positioned between the electrode 552X and the electrode 551X, and the intermediate layer 106X is positioned between the electrode 552X and the unit 103X.

The unit 103X2 is positioned between the electrode 552X and the intermediate layer 106X. The unit 103X2 has a function of emitting light ELX2.

In other words, the light-emitting device 550X includes the stacked units between the electrode 551X and the electrode 552X. The number of stacked units is not limited to two and may be three or more. A structure including the stacked units positioned between the electrode 551X and the electrode 552X and the intermediate layer 106X positioned between the units is referred to as a stacked light-emitting device or a tandem light-emitting device in some cases.

This structure enables high luminance emission while the current density is kept low. Reliability can be improved. The driving voltage can be reduced in comparison with that of the light-emitting device with the same luminance. The power consumption can be reduced.

### Structure Example 1 of Unit 103X2

The unit 103X2 has a single-layer structure or a stacked-layer structure. For example, the unit 103X2 includes a layer 111X2, a layer 112X2, and a layer 113X2. The unit 103X2 has a function of emitting the light ELX2.

The layer 111X2 is positioned between the layer 113X2 and the layer 112X2, the layer 113X2 is positioned between the electrode 552X and the layer 111X2, and the layer 112X2 is positioned between the layer 111X2 and the intermediate layer 106X.

The structure that can be employed for the unit 103X can be employed for the unit 103X2. Specifically, the description of the unit 103X can be used for the description of the unit 103X2 by replacing “X” in the reference numerals of the components of the unit 103X with “X2”. For example, the same structure as the unit 103X can be employed for the unit 103X2.

### Structure Example 2 of Unit 103X2

The structure that is different from the structure of the unit 103X can be employed for the unit 103X2. For example, the unit 103X2 can have a structure emitting light whose hue is different from that of light emitted from the unit 103X.

Specifically, a stack including the unit 103X emitting red light and green light and the unit 103X2 emitting blue light can be employed. With this structure, a light-emitting device emitting light of a desired color can be provided. A light-emitting device emitting white light can be provided, for example.

### Structure Example of Intermediate Layer 106X

The intermediate layer 106X has a function of supplying electrons to one of the unit 103X and the unit 103X2 and supplying holes to the other. For example, the intermediate layer 106X described in Embodiment 6 can be used.

### <Method for Fabricating Light-Emitting Device 550X>

For example, each of the electrode 551X, the electrode 552X, the unit 103X, the intermediate layer 106X, and the unit 103X2 can be formed by a dry process, a wet process, an evaporation method, a droplet discharging method, a coating method, a printing method, or the like. A formation method may differ between components of the device.

Specifically, the light-emitting device 550X can be manufactured with a vacuum evaporation apparatus, an inkjet apparatus, a coating apparatus such as a spin coater, a gravure printing apparatus, an offset printing apparatus, a screen printing apparatus, or the like.

For example, the electrode can be formed by a wet process or a sol-gel method using a paste of a metal material. In addition, an indium oxide-zinc oxide film can be formed by a sputtering method using a target obtained by adding zinc oxide to indium oxide at a concentration higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at a concentration higher than or equal to 0.5 wt % and lower than or equal to 5 wt % and zinc oxide at a concentration higher than or equal to 0.1 wt % and lower than or equal to 1 wt %.

This embodiment can be combined with any of the other embodiments in this specification as appropriate.

### Embodiment 8

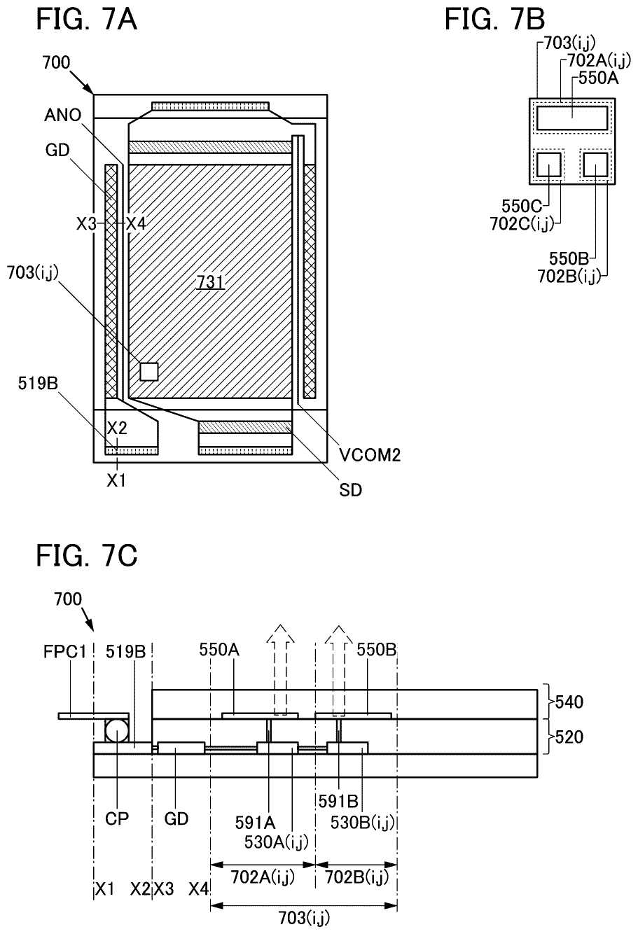

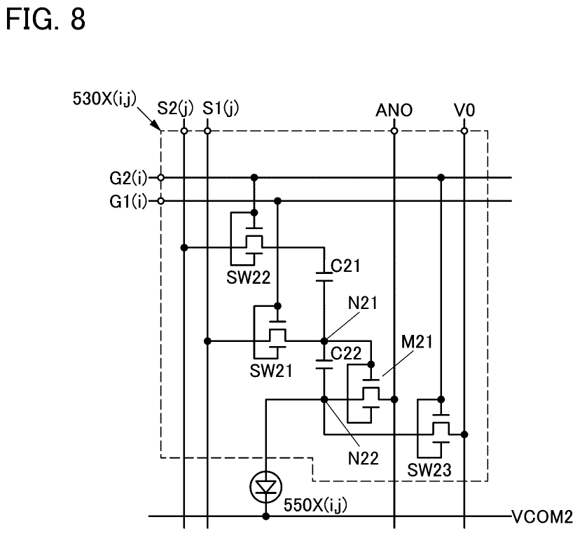

In this embodiment, a structure of a display apparatus of one embodiment of the present invention is described with reference to FIGS. 7A to 7C and FIG. 8.

FIGS. 7A to 7C illustrate a structure of a display apparatus of one embodiment of the present invention. FIG. 7A is a top view of the display apparatus of one embodiment of the present invention, and FIG. 7B is a top view illustrating part of FIG. 7A. FIG. 7C illustrates cross sections taken along cutting lines X1-X2 and X3-X4 in FIG. 7A and a cross section of a pixel set 703(i,j).

FIG. 8 is a circuit diagram illustrating the structure of the display apparatus of one embodiment of the present invention.

In this specification, an integer variable of 1 or more may be used for reference numerals. For example, “(p)” where p is an integer variable of 1 or more may be used for part of a reference numeral that specifies any one of up to p components. For another example, “(m,n)” where each of m and n is an integer variable of 1 or more may be used for part of a reference numeral that specifies any one of up to m x n components.

### Structure Example 1 of Display Apparatus 700

The display apparatus 700 of one embodiment of the present invention includes a region 731 (see FIG. 7A). The region 731 includes the pixel set 703(i,j).

### Structure Example 1 of Pixel Set 703(i,j)

The pixel set 703(i,j) includes a pixel 702A(i,j), a pixel 702B(i,j), and a pixel 702C(i,j) (see FIGS. 7B and 7C).

The pixel 702A(i,j) includes a pixel circuit 530A(i,j) and the light-emitting device 550A. The light-emitting device 550A is electrically connected to the pixel circuit 530A(i,j).

For example, the light-emitting device described in any of Embodiments 3 to 7 can be used as the light-emitting device 550A.

The pixel 702B(i,j) includes a pixel circuit 530B(i,j) and the light-emitting device 550B. The light-emitting device 550B is electrically connected to the pixel circuit 530B(i,j). Similarly, the pixel 702C(i,j) includes the light-emitting device 550C.

For example, the structure described in any of Embodiments 3 to 7 can be employed for the light-emitting devices 550A to 550C.

### Structure Example 2 of Display Apparatus 700

The display apparatus 700 of one embodiment of the present invention includes a functional layer 540 and the functional layer 520 (see FIG. 7C). The functional layer 540 overlaps with the functional layer 520.

The functional layer 540 includes the light-emitting device 550A.

The functional layer 520 includes the pixel circuit 530A(i,j) and a wiring (see FIG. 7C). The pixel circuit 530A(i,j) is electrically connected to the wiring. For example, a conductive film provided in an opening 591A in the functional layer 520 can be used for the wiring. The wiring electrically connects a terminal 519B to the pixel circuit 530A(i,j). Note that a conductive material CP electrically connects the terminal 519B to a flexible printed circuit board FPC1. In addition, a conductive film provided in an opening 591B in the functional layer 520 can be used for the wiring, for example.

### Structure Example 3 of Display Apparatus 700

In addition, the display apparatus 700 of one embodiment of the present invention includes a driver circuit GD and a driver circuit SD (see FIG. 7A).

### Structure Example of Driver Circuit GD

The driver circuit GD supplies a first selection signal and a second selection signal.

### Structure Example of Driver Circuit SD

The driver circuit SD supplies a first control signal and a second control signal.

### Structure Example of Wiring

As the wiring, a conductive film G1(i), a conductive film G2(i), a conductive film S1(j), a conductive film S2(j), a conductive film ANO, a conductive film VCOM2, and a conductive film V0 are included (see FIG. 8).

The conductive film G1(i) is supplied with the first selection signal, and the conductive film G2(i) is supplied with the second selection signal.

The conductive film S1(j) is supplied with the first control signal, and the conductive film S2(j) is supplied with the second control signal.

### Structure Example 1 of Pixel Circuit 530A(i,j)

The pixel circuit 530A(i,j) is electrically connected to the conductive film G1(i) and the conductive film S1(j). The conductive film G1(i) supplies the first selection signal, and the conductive film S1(j) supplies the first control signal.

The pixel circuit 530A(i,j) drives the light-emitting device 550A in response to the first selection signal and the first control signal. The light-emitting device 550A emits light.

In the light-emitting device 550A, one of the electrodes is electrically connected to the pixel circuit 530A(i,j) and the other electrode is electrically connected to the conductive film VCOM2.

### Structure Example 2 of Pixel Circuit 530A(i,j)

The pixel circuit 530A(i,j) includes a switch SW21, a switch SW22, a transistor M21, a capacitor C21, and a node N21.

The transistor M21 includes a gate electrode electrically connected to the node N21, a first electrode electrically connected to the light-emitting device 550A, and a second electrode electrically connected to the conductive film ANO.

The switch SW21 includes a first terminal electrically connected to the node N21, a second terminal electrically connected to the conductive film S1(j), and a gate electrode having a function of controlling an on/off state of the switch SW21 according to the potential of the conductive film G1(i).

The switch SW22 includes a first terminal electrically connected to the conductive film S2(j), and a gate electrode having a function of controlling an on/off state of the switch SW22 according to the potential of the conductive film G2(i).

The capacitor C21 includes a conductive film electrically connected to the node N21 and a conductive film electrically connected to a second electrode of the switch SW22.

Accordingly, an image signal can be stored in the node N21. Alternatively, the potential of the node N21 can be changed using the switch SW22. Alternatively, the intensity of light emitted from the light-emitting device 550A can be controlled with the potential of the node N21. As a result, a novel apparatus that is highly convenient, useful, or reliable can be provided.

### Structure Example 3 of Pixel Circuit 530A(i,j)

The pixel circuit 530A(i,j) includes a switch SW23, a node N22, and a capacitor C22.

The switch SW23 includes a first terminal electrically connected to the conductive film V0, a second terminal electrically connected to the node N22, and a gate electrode having a function of controlling an on/off state of the switch SW23 according to the potential of the conductive film G2(i).

The capacitor C22 includes a conductive film electrically connected to the node N21 and a conductive film electrically connected to the node N22.

The first electrode of the transistor M21 is electrically connected to the node N22.

### <Method for Manufacturing Display Apparatus 700>

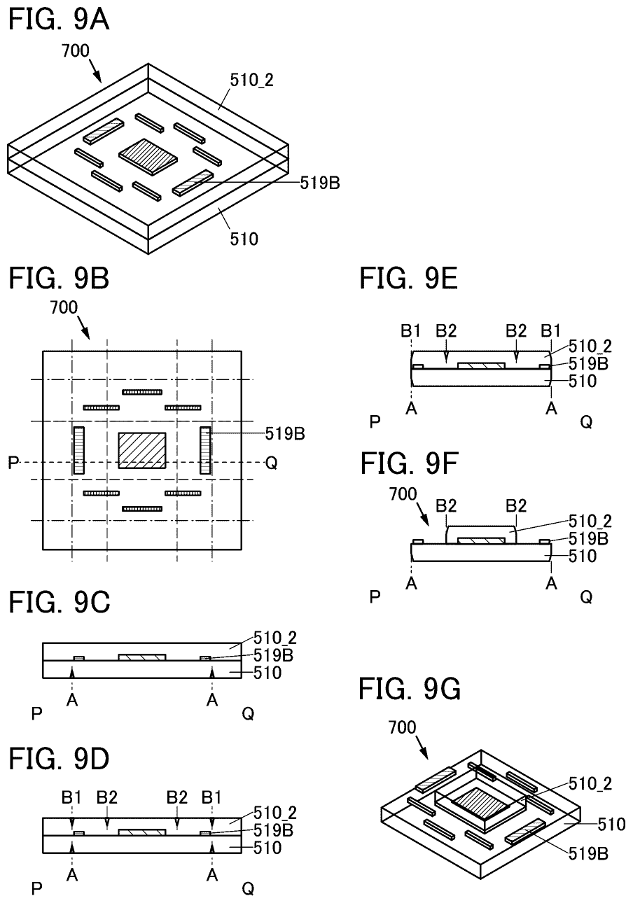

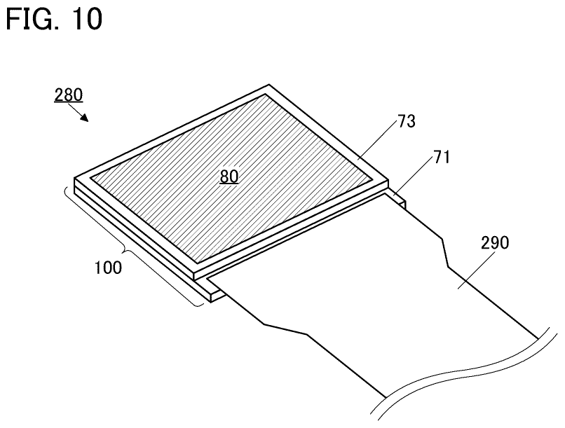

A method for manufacturing a display apparatus of one embodiment of the present invention is described (see FIGS. 9A to 9G).

FIG. 9A is a perspective view illustrating the appearance of a workpiece in the manufacturing process, which is provided with the display apparatus 700. FIG. 9B is a front view of the display apparatus 700 in the manufacturing process. FIG. 9C is a cross-sectional view illustrating the structure taken along a cutting line P-Q in FIG. 9B. FIGS. 9D to 9F illustrate a method for separating the display apparatus 700 from the workpiece. FIG. 9G is a perspective view illustrating the appearance of the display apparatus 700 separated from the workpiece.

### <<Structure of Workpiece>>

The workpiece illustrated in FIGS. 9A and 9B is provided with the display apparatus 700, and includes the substrate 510 and a substrate 510_2. The display apparatus 700 includes the terminal 519B.

<<Method for Separating Display Apparatus 700 from Workpiece>>

A method for removing unnecessary portions from the workpiece, separating the display apparatus 700 from the workpiece, and exposing the terminal 519B is described (see FIGS. 9C to 9F).

### [Step 1]

In Step 1, grooves A are formed on the substrate 510 (see FIG. 9C). For example, grooves each having a depth approximately half the thickness of the substrate 510 are formed on the substrate 510 with use of a dicer. Specifically, grooves each having a depth of 0.4 mm are formed on the substrate 510 having a thickness of 0.7 mm. Note that a single crystal silicon wafer can be used as the substrate 510, for example. In dicing, cooling water is supplied to cool a blade and the workpiece and remove cutting dust. By forming the grooves A each having a depth approximately half the thickness of the substrate 510 before unnecessary portions of the substrate 510_2 are removed, a phenomenon in which cooling water containing cutting dust enters a gap between the substrate 510 and the substrate 510_2 can be prevented. Accordingly, a phenomenon in which cutting dust in the gap between the substrate 510 and the substrate 510_2 is pushed inside the gap by pressure applied to the workpiece in the process and damages the display apparatus 700 can be prevented.

### [Step 2]

In Step 2, grooves B are formed on the substrate 510_2 and unnecessary portions of the substrate 510_2 are separated (see FIG. 9D). For example, the grooves are formed on the substrate 510_2 with use of a scriber. Note that the grooves B1 are formed to overlap with the grooves A. The grooves B2 are formed so that the terminals 519B are exposed after unnecessary portions of the substrate 510_2 are removed. A non-alkali glass substrate can be used as the substrate 510_2, for example.

### [Step 3]

In Step 3, force is applied so that the groove A and the groove B1 are connected, whereby unnecessary portions of the substrate 510 and the substrate 510_2 are removed (see FIG. 9E).

### [Step 4]

In Step 4, force is applied so that the grooves B2 expand toward the substrate 510 side, whereby unnecessary portions of the substrate 510_2 are removed (see FIG. 9F).

By performing Step 1 to Step 4 on the workpiece, the display apparatus 700 can be separated from the workpiece (see FIG. 9G).

This embodiment can be combined with any of the other embodiments in this specification as appropriate.

### Embodiment 9

In this embodiment, a display module of one embodiment of the present invention is described.

### <Display Module>

FIG. 10 is a perspective view illustrating a structure of a display module 280.

The display module 280 includes a display apparatus 100, and an FPC 290 or a connector. The display apparatus 100 includes a display region 80. The display apparatus described in Embodiment 1 or Embodiment 2 can be used as the display apparatus 100, for example.

The FPC 290 is supplied with a signal and electric power from the outside and supplies the signal and the electric power to the display apparatus 100. An IC may be mounted on the FPC 290. Note that a connector is a mechanical component for electrical connection through a conductor, and the conductor can electrically connect the display apparatus 100 to a component to be connected. For example, the FPC 290 can be used as the conductor. The connector can detach the display apparatus 100 from the connected component.

### <<Display Apparatus 100A>>

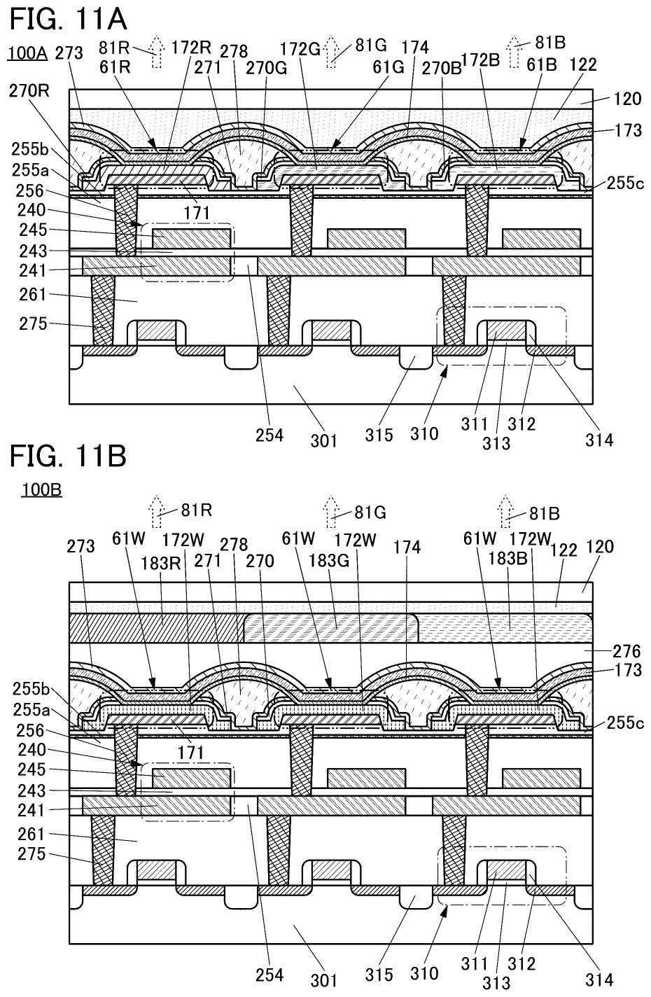

FIG. 11A is a cross-sectional view illustrating a structure of a display apparatus 100A. The display apparatus 100A can be used as the display apparatus 100 of the display module 280, for example. A substrate 301 corresponds to a substrate 71 in FIG. 10.

The display apparatus 100A includes the substrate 301, a transistor 310, an element isolation layer 315, an insulating layer 261, a capacitor 240, an insulating layer 255 (an insulating layer 255a, an insulating layer 255b, and an insulating layer 255c), a light-emitting device 61R, a light-emitting device 61G, and a light-emitting device 61B. The insulating layer 261 is provided over the substrate 301, and the transistor 310 is positioned between the substrate 301 and the insulating layer 261. The insulating layer 255a is provided over the insulating layer 261, the capacitor 240 is positioned between the insulating layer 261 and the insulating layer 255a, and the insulating layer 255a is positioned between the capacitors 240 and the light-emitting devices 61R, 61G, and 61B.

### [Transistor 310]

The transistor 310 includes a conductive layer 311, a pair of low-resistance regions 312, an insulating layer 313, and an insulating layer 314, and its channel is formed in part of the substrate 301. The conductive layer 311 functions as a gate electrode. The insulating layer 313 is positioned between the substrate 301 and the conductive layer 311 and functions as a gate insulating layer. The substrate 301 includes the pair of low-resistance regions 312 doped with an impurity. Note that such regions function as a source and a drain. The side surface of the conductive layer 311 is covered with the insulating layer 314.

The element isolation layer 315 is embedded in the substrate 301, and positioned between two adjacent transistors 310.

### [Capacitor 240]

The capacitor 240 includes a conductive layer 241, a conductive layer 245, and an insulating layer 243, and the insulating layer 243 is positioned between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is positioned over the insulating layer 261 and is embedded in an insulating layer 254. The conductive layer 241 is electrically connected to one of the source and the drain of the transistor 310 through a plug 275 embedded in the insulating layer 261. The insulating layer 243 covers the conductive layer 241. The conductive layer 245 overlaps with the conductive layer 241 with the insulating layer 243 therebetween.

[Insulating Layer 255a, Insulating Layer 255b, and Insulating Layer 255c]

The display apparatus 100A includes the insulating layer 255a, the insulating layer 255b, and the insulating layer 255c, and the insulating layer 255b is positioned between the insulating layer 255a and the insulating layer 255c.

### [Light-Emitting Device 61R, Light-Emitting Device 61G, and Light-Emitting Device 61B]

The light-emitting devices 61R, 61G, and 61B are provided over the insulating layer 255c. For example, the light-emitting device described in any of Embodiments 3 to 7 can be used as any of the light-emitting devices 61R, 61G, and 61B. The light-emitting device 61R, the light-emitting device 61G, and the light-emitting device 61B emit light 81R, light 81G, and light 81B, respectively. The light-emitting devices share a common layer 174.

The light-emitting device 61R includes a conductive layer 171 and an EL layer 172R, and the EL layer 172R covers the top and side surfaces of the conductive layer 171. The sacrificial layer 270 includes sacrificial layers 270R, 270G, and 270B. The sacrificial layer 270R is positioned over the EL layer 172R. The light-emitting device 61G includes the conductive layer 171 and an EL layer 172G, and the EL layer 172G covers the top and side surfaces of the conductive layer 171. The sacrificial layer 270G is positioned over the EL layer 172G. The light-emitting device 61B includes the conductive layer 171 and an EL layer 172B, and the EL layer 172B covers the top and side surfaces of the conductive layer 171. The sacrificial layer 270B is positioned over the EL layer 172B.

The conductive layer 171 is electrically connected to one of the source and the drain of the transistor 310 through a plug 256 embedded in the insulating layers 243, 255a, 255b, and 255c, the conductive layer 241 embedded in the insulating layer 254, and the plug 275 embedded in the insulating layer 261. The top surface of the insulating layer 255c and the top surface of the plug 256 are level with or substantially level with each other. Any of a variety of conductive materials can be used for the plugs.

### [Protective Layer 271, Insulating Layer 278, Protective Layer 273, and Bonding Layer 122]

A protective layer 271 and an insulating layer 278 are positioned between adjacent light-emitting devices, e.g., between the light-emitting device 61R and the light-emitting device 61G, and the insulating layer 278 is provided over the protective layer 271. A protective layer 273 is provided over the light-emitting devices 61R, 61G, and 61B.

A bonding layer 122 attaches the protective layer 273 to a substrate 120.

### [Substrate 120]

The substrate 120 corresponds to a substrate 73 in FIG. 10. A light-blocking layer can be provided for the surface of the substrate 120 on the bonding layer 122 side, for example. A variety of optical members can be provided on the outer side of the substrate 120.

A film can be used as the substrate. In particular, a film with a low water absorption rate can be suitably used. For example, the water absorption rate is preferably 1% or lower, further preferably 0.1% or lower. Thus, a change in size of the film can be inhibited. Furthermore, generation of wrinkles or the like can be inhibited. Moreover, a change in shape of the display apparatus can be inhibited.

For example, a polarizing plate, a retardation plate, a light diffusion layer (e.g., a diffusion film), an anti-reflection layer, a light-condensing film, or the like can be used as the optical member.

It is possible that a highly optically isotropic material, in other words, a material with a low birefringence index is used for the substrate and a circular polarizing plate is provided to overlap with the display apparatus. For example, it is possible to use, for the substrate, a material that has an absolute value of a retardation (phase difference) of nm or less, preferably 20 nm or less, further preferably 10 nm or less. For example, a triacetyl cellulose (TAC, also referred to as cellulose triacetate) film, a cycloolefin polymer (COP) film, a cycloolefin copolymer (COC) film, or an acrylic resin film can be used as a highly optically isotropic film.

Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer, a silica layer (SiO, layer), diamond like carbon (DLC), aluminum oxide (AlOₓ), a polyester-based material, a polycarbonate-based material, or the like can be used for the surface protective layer. Note that a material having a high visible light transmittance can be suitably used for the surface protective layer. In addition, a material having high hardness can be suitably used for the surface protective layer.

### <<Display Apparatus 100B>>

FIG. 11B is a cross-sectional view illustrating a structure of a display apparatus 100B. For example, the display apparatus 100B can be used as the display apparatus 100 of the display module 280 (see FIG. 10).

The display apparatus 100B includes the substrate 301, a light-emitting device 61W, the capacitor 240, and the transistor 310. The light-emitting device 61W can emit white light, for example.

The display apparatus 100B includes a coloring layer 183R, a coloring layer 183G, and a coloring layer 183B. The coloring layer 183R overlaps with one light-emitting device 61W, the coloring layer 183G overlaps with another light-emitting device 61W, and the coloring layer 183B overlaps with another light-emitting device 61W. In the display apparatus 100B, a gap 276 is positioned between the coloring layer and the light-emitting devices.

For example, the coloring layer 183R, the coloring layer 183G, and the coloring layer 183B can transmit red light, green light, and blue light, respectively.

### <<Display Apparatus 100C>>

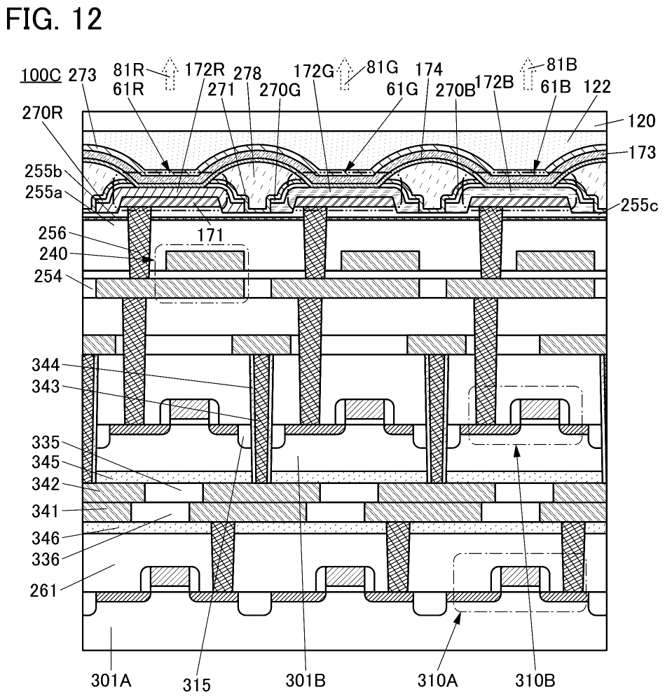

FIG. 12 is a cross-sectional view illustrating a structure of a display apparatus 100C. The display apparatus 100C can be used as the display apparatus 100 of the display module 280, for example (see FIG. 10). Note that in the following description of display apparatuses, the description of portions similar to those of the above-described display apparatuses may be omitted.

The display apparatus 100C includes a substrate 301B and a substrate 301A. The display apparatus 100C includes a transistor 310B, the capacitor 240, the light-emitting devices 61R, 61G, and 61B, and a transistor 310A. A channel of the transistor 310A is formed in part of the substrate 301A and a channel of the transistor 310B is formed in part of the substrate 301B.

### [Insulating Layer 345 and Insulating Layer 346]

An insulating layer 345 is in contact with the bottom surface of the substrate 301B, and an insulating layer 346 is positioned over the insulating layer 261. For example, the inorganic insulating film that can be used as the protective layer 273 can be used as the insulating layers 345 and 346. The insulating layers 345 and 346 function as protective layers and can inhibit impurities from being diffused into the substrates 301B and 301A.

### [Plug 343]

A plug 343 penetrates the substrate 301B and the insulating layer 345. An insulating layer 344 covers the side surface of the plug 343. For example, the inorganic insulating film that can be used as the protective layer 273 can be used as the insulating layer 344. The insulating layer 344 functions as a protective layer and can inhibit impurities from being diffused into the substrate 301B.

### [Conductive Layer 342]

A conductive layer 342 is positioned between the insulating layer 345 and the insulating layer 346. It is preferable that the conductive layer 342 be embedded in an insulating layer 335 and a plane formed by the conductive layer 342 and the insulating layer 335 be preferably flat. Note that the conductive layer 342 is electrically connected to the plug 343.

### [Conductive Layer 341]

A conductive layer 341 is positioned between the insulating layer 346 and the insulating layer 335. It is preferable that the conductive layer 341 be embedded in an insulating layer 336 and a plane formed by the conductive layer 341 and the insulating layer 336 be flat. The conductive layer 341 is bonded to the conductive layer 342. Thus, the substrate 301A is electrically connected to the substrate 301B.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layers 341 and 342. In that case, it is possible to employ copper-to-copper (Cu-to-Cu) direct bonding (a technique for achieving electrical continuity by connecting copper (Cu) pads).

### <<Display Apparatus 100D>>

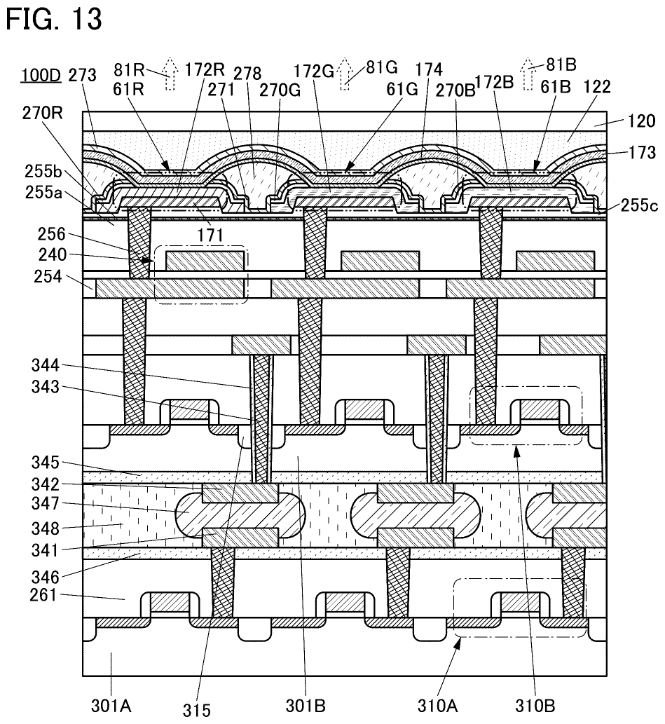

FIG. 13 is a cross-sectional view illustrating a structure of a display apparatus 100D. The display apparatus 100D can be used as the display apparatus 100 of the display module 280, for example (see FIG. 10).

The display apparatus 100D includes a bump 347, and the bump 347 bonds the conductive layer 341 to the conductive layer 342. The bump 347 electrically connects the conductive layer 341 to the conductive layer 342. The bump 347 can be formed using a conductive material containing gold (Au), nickel (Ni), indium (In), tin (Sn), or the like, for example. Solder can be used for the bump 347, for example.

The display apparatus 100D includes a bonding layer 348. The bonding layer 348 attaches the insulating layer 345 to the insulating layer 346.

### <<Display Apparatus 100E>>

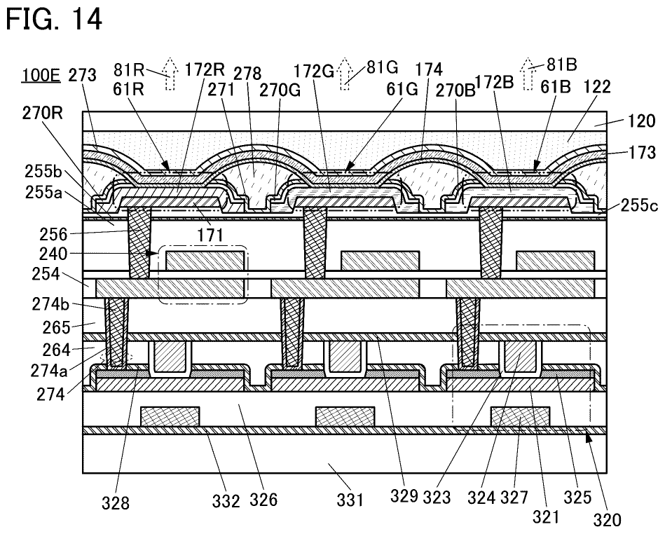

FIG. 14 is a cross-sectional view illustrating a structure of a display apparatus 100E. The display apparatus 100E can be used as the display apparatus 100 of the display module 280, for example (see FIG. 10). A substrate 331 corresponds to the substrate 71 in FIG. 10. An insulating substrate or a semiconductor substrate can be used as the substrate 331. The display apparatus 100E includes a transistor 320. Note that the display apparatus 100E is different from the display apparatus 100A in that the transistor is an OS transistor.

### [Insulating Layer 332]

An insulating layer 332 is provided over the substrate 331. For example, a film in which hydrogen or oxygen is less likely to be diffused than in a silicon oxide film can be used as the insulating layer 332. Specifically, an aluminum oxide film, a hafnium oxide film, a silicon nitride film, or the like can be used as the insulating layer 332. Thus, the insulating layer 332 can prevent impurities such as water and hydrogen from being diffused from the substrate 331 into the transistor 320. Furthermore, oxygen can be prevented from being released from a semiconductor layer 321 to the insulating layer 332 side.

### [Transistor 320]

The transistor 320 includes the semiconductor layer 321, an insulating layer 323, a conductive layer 324, a pair of conductive layers 325, an insulating layer 326, and a conductive layer 327.

The conductive layer 327 is provided over the insulating layer 332 and functions as a first gate electrode of the transistor 320. The insulating layer 326 covers the conductive layer 327. Part of the insulating layer 326 functions as a first gate insulating layer. The insulating layer 326 includes an oxide insulating film at least in a region in contact with the semiconductor layer 321. Specifically, a silicon oxide film or the like is preferably used. The insulating layer 326 has a flat top surface. The semiconductor layer 321 is provided over the insulating layer 326. A metal oxide film having semiconductor characteristics can be used as the semiconductor layer 321. The pair of conductive layers 325 is provided on and in contact with the semiconductor layer 321, and functions as a source electrode and a drain electrode.

### [Insulating Layer 328 and Insulating Layer 264]

An insulating layer 328 covers the top and side surfaces of the pair of conductive layers 325, the side surface of the semiconductor layer 321, and the like. An insulating layer 264 is provided over the insulating layer 328 and functions as an interlayer insulating layer. The insulating layers 328 and 264 have an opening reaching the semiconductor layer 321. For example, an insulating film similar to the insulating layer 332 can be used as the insulating layer 328. Thus, the insulating layer 328 can prevent impurities such as water and hydrogen from being diffused from the insulating layer 264 into the semiconductor layer 321. Furthermore, oxygen can be prevented from being released from the semiconductor layer 321.

### [Insulating Layer 323]

The insulating layer 323 is in contact with the side surfaces of the insulating layers 264 and 328 and the conductive layer 325 and the top surface of the semiconductor layer 321 inside the opening.

### [Conductive Layer 324]

Inside the opening, the conductive layer 324 is embedded and in contact with the insulating layer 323. The conductive layer 324 has a top surface subjected to planarization treatment, and is level with or substantially level with the top surface of the insulating layer 323 and the top surface of the insulating layer 264. The conductive layer 324 functions as a second gate electrode, and the insulating layer 323 functions as a second gate insulating layer.

### [Insulating Layer 329 and Insulating Layer 265]

An insulating layer 329 covers the conductive layer 324 and the insulating layers 323 and 264. An insulating layer 265 is provided over the insulating layer 329 and functions as an interlayer insulating layer. For example, an insulating film similar to the insulating layers 328 and 332 can be used as the insulating layer 329. Thus, impurities such as water and hydrogen can be prevented from being diffused from the insulating layer 265 into the transistor 320, for example.

### [Plug 274]

A plug 274 is embedded in the insulating layers 265, 329, 264, and 328 and is electrically connected to one of the pair of conductive layers 325. The plug 274 includes a conductive layer 274a and a conductive layer 274b. The conductive layer 274a is in contact with each of the side surfaces of openings in the insulating layers 265, 329, 264, and 328. In addition, the conductive layer 274a covers part of the top surface of the conductive layer 325. The conductive layer 274b is in contact with the top surface of the conductive layer 274a. For example, a conductive material in which hydrogen and oxygen are less likely to be diffused can be suitably used for the conductive layer 274a.

### <<Display Apparatus 100F>>

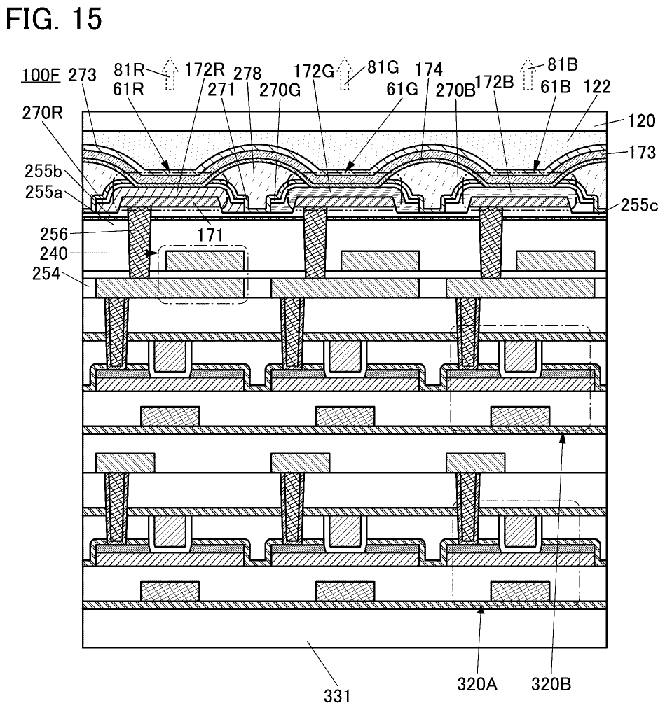

FIG. 15 is a cross-sectional view illustrating a structure of a display apparatus 100F. The display apparatus 100F has a structure in which a transistor 320A and a transistor 320B are stacked. Each of the transistors 320A and 320B includes an oxide semiconductor and a channel formed in the oxide semiconductor. Note that the structure of the display apparatus 100F is not limited to the stacked-layer structure of two transistors, and may be a structure in which three or more transistors are stacked, for example.

The structures of the transistor 320A and the peripheral components are the same as those of the transistor 320 and the peripheral components of the display apparatus 100E. The structures of the transistor 320B and the peripheral components are the same as those of the transistor 320 and the peripheral components of the display apparatus 100E.

### <<Display Apparatus 100G>>

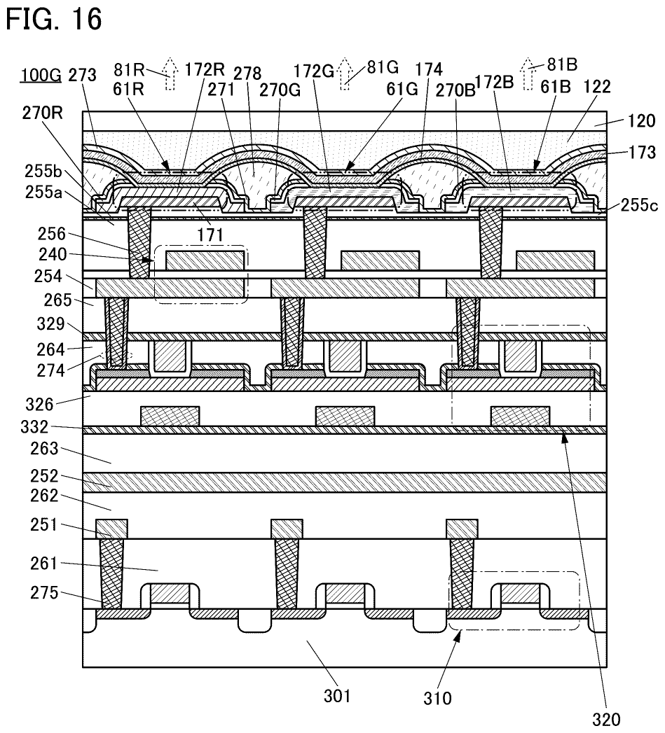

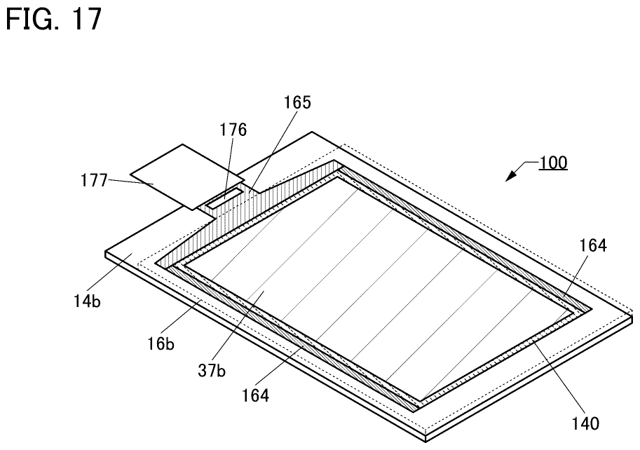

FIG. 16 is a cross-sectional view illustrating a structure of a display apparatus 100G. The display apparatus 100G has a structure in which the transistor 310 and the transistor 320 are stacked. The channel of the transistor 310 is formed in the substrate 301. The transistor 320 includes an oxide semiconductor and the channel formed in the oxide semiconductor.

The insulating layer 261 covers the transistor 310 and a conductive layer 251 is provided over the insulating layer 261. An insulating layer 262 covers the conductive layer 251 and a conductive layer 252 is provided over the insulating layer 262. An insulating layer 263 and the insulating layer 332 covers the conductive layer 252. The conductive layer 251 and the conductive layer 252 each function as a wiring.

The transistor 320 is provided over the insulating layer 332 and the insulating layer 265 covers the transistor 320. The capacitor 240 is provided over the insulating layer 265 and is electrically connected to the transistor 320 through the plug 274.

For example, the transistor 320 can be used as a transistor included in a pixel circuit. For another example, the transistor 310 can be used as a transistor included in a pixel circuit or for a driver circuit (e.g., a gate driver circuit or a source driver circuit) for driving the pixel circuit. The transistor 310 and the transistor 320 can be used for a variety of circuits such as an arithmetic circuit and a memory circuit. Thus, not only a pixel circuit but also a driver circuit can be provided directly under the light-emitting device, for example. The display apparatus can be downsized as compared to the case where a driver circuit is provided around a display region.

At least part of this embodiment can be implemented in combination with any of the other embodiments described in this specification, as appropriate.

### Embodiment 10

In this embodiment, a display module of one embodiment of the present invention is described.

### <Display Module>

FIG. 17 is a perspective view illustrating a structure of a display module.

The display module includes the display apparatus 100, an integrated circuit (IC) 176, and one of an FPC 177 and a connector. The display apparatus described in Embodiment 1 or Embodiment 2 can be used as the display apparatus 100, for example.

The display apparatus 100 is electrically connected to the IC 176 and the FPC 177. The FPC 177 is supplied with a signal and electric power from the outside and supplies the signal and the electric power to the display apparatus 100. Note that a connector is a mechanical component for electrical connection through a conductor, and the conductor can electrically connect the display apparatus 100 to a component to be connected. For example, the FPC 177 can be used as the conductor. The connector can detach the display apparatus 100 from the connected component.

The display module includes the IC 176. For example, the IC 176 can be provided for a substrate 14b by a chip on glass (COG) method. Alternatively, the IC 176 can be provided for an FPC by a chip on film (COF) method, for example. Note that a gate driver circuit, a source driver circuit, or the like can be used as the IC 176.

### <<Display Apparatus 100H>>

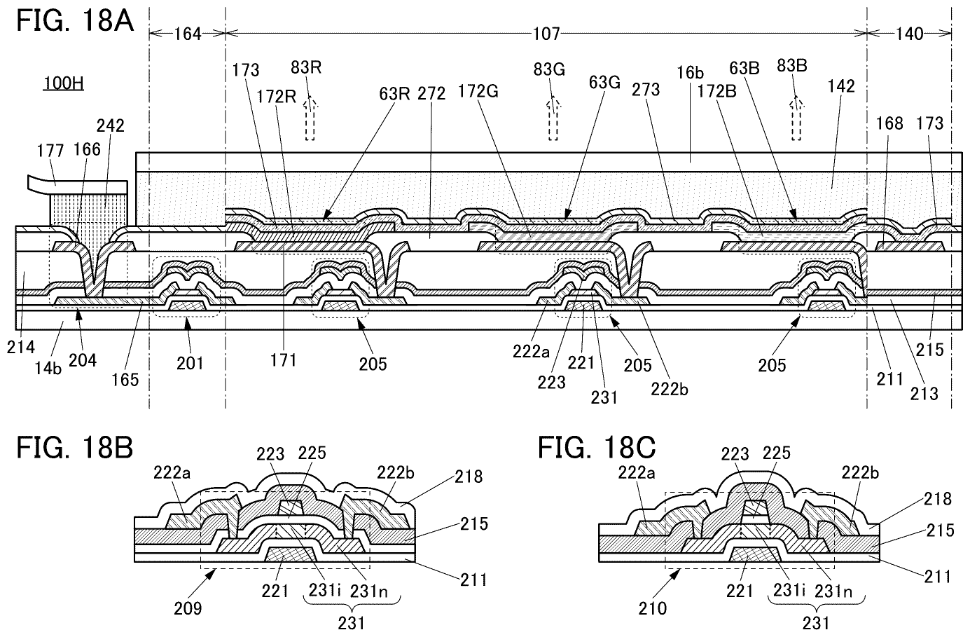

FIG. 18A is a cross-sectional view illustrating a structure of a display apparatus 100H.

The display apparatus 100H includes a display portion 37b, a connection portion 140, a circuit 164, a wiring 165, and the like. The display apparatus 100H includes a substrate 16b and the substrate 14b, which are bonded to each other. The display apparatus 100H includes one or more connection portions 140. The connection portion(s) 140 can be provided outside the display portion 37b. For example, the connection portion 140 can be provided along one side of the display portion 37b. Alternatively, the connection portion(s) 140 can be provided along a plurality of sides, for example, the connection portion(s) 140 can be provided to surround four sides. In the connection portion 140, a common electrode of a light-emitting device is electrically connected to a conductive layer, which supplies a predetermined potential to the common electrode.

The wiring 165 is supplied with a signal or electric power from the FPC 177 or the IC 176. The wiring 165 supplies a signal and electric power to the display portion 37b and the circuit 164.

For example, a gate driver circuit can be used as the circuit 164.

The display apparatus 100H includes the substrate 14b, the substrate 16b, a transistor 201, a transistor 205, a light-emitting device 63R, a light-emitting device 63G, a light-emitting device 63B, and the like (see FIG. 18A). For example, the light-emitting device 63R emits red light 83R, the light-emitting device 63G emits green light 83G, and the light-emitting device 63B emits blue light 83B. Note that a variety of optical members can be provided on the outer side of the substrate 16b. For example, a polarizing plate, a retardation plate, a light diffusion layer (e.g., a diffusion film), an anti-reflection layer, a light-condensing film, or the like can be provided.

For example, the light-emitting device described in any of Embodiments 3 to 7 can be used as each of the light-emitting devices 63R, 63G, and 63B.

The light-emitting device includes the conductive layer 171, which functions as a pixel electrode. The conductive layer 171 includes a recessed portion, which overlaps with an opening provided in an insulating layer 214, an insulating layer 215, and an insulating layer 213. The transistor 205 includes a conductive layer 222b, which is electrically connected to the conductive layer 171.

The display apparatus 100H includes an insulating layer 272. The insulating layer 272 covers an end portion of the conductive layer 171 to fill the recessed portion of the conductive layer 171 (see FIG. 18A).

The display apparatus 100H includes the protective layer 273 and a bonding layer 142. The protective layer 273 covers the light-emitting devices 63R, 63G, and 63B. The protective layer 273 and the substrate 16b are bonded to each other with the bonding layer 142. The bonding layer 142 fills a gap between the substrate 16b and the protective layer 273. Note that the bonding layer 142 may be formed in a frame shape so as not to overlap with the light-emitting devices and a region surrounded by the bonding layer 142, the substrate 16b, and the protective layer 273 may be filled with a resin different from the material of the bonding layer 142. Alternatively, a hollow sealing structure may be employed, in which the region is filled with an inert gas (e.g., nitrogen or argon). For example, the material that can be used for the bonding layer 122 can be used for the bonding layer 142.

The display apparatus 100H includes the connection portion 140, which includes a conductive layer 168. Note that a power supply potential is supplied to the conductive layer 168. The light-emitting device includes a conductive layer 173. The conductive layer 168 is electrically connected to the conductive layer 173, to which a power supply potential is supplied. Note that the conductive layer 173 functions as a common electrode. For example, the conductive layer 171 and the conductive layer 168 can be formed by processing one conductive film.

The display apparatus 100H has a top-emission structure. The light-emitting device emits light to the substrate 16b side. The conductive layer 171 contains a material reflecting visible light, and the conductive layer 173 transmits visible light.

### [Insulating Layer 211, Insulating Layer 213, Insulating Layer 215, and Insulating Layer 214]

An insulating layer 211, the insulating layer 213, the insulating layer 215, and the insulating layer 214 are provided in this order over the substrate 14b. Note that the number of insulating layers is not limited and each insulating layer may be a single layer or a stacked layer of two or more layers.

For example, an inorganic insulating film can be used as each of the insulating layers 211, 213, and 215. A silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

The insulating layers 215 and 214 cover the transistors. The insulating layer 214 functions as a planarization layer. For example, a material in which impurities such as water and hydrogen are less likely to be diffused is preferably used for the insulating layer 215 or the insulating layer 214. This can effectively inhibit impurities from being diffused to the transistors from the outside. Furthermore, the reliability of the display apparatus can be improved.

For example, an organic insulating layer can be favorably used as the insulating layer 214. Specifically, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the organic insulating layer. Alternatively, the insulating layer 214 can have a stacked-layer structure of an organic insulating layer and an inorganic insulating layer. Thus, the outermost layer of the insulating layer 214 can be used as an etching protective layer. For example, in the case where a phenomenon of forming a recessed portion in the insulating layer 214 should be avoided in processing the conductive layer 171 into a predetermined shape, the phenomenon can be inhibited.

### [Transistor 201 and Transistor 205]

The transistor 201 and the transistor 205 are formed over the substrate 14b. These transistors can be fabricated using the same materials in the same steps.

Each of the transistors 201 and 205 includes a conductive layer 221, the insulating layer 211, a conductive layer 222a, the conductive layer 222b, a semiconductor layer 231, the insulating layer 213, and a conductive layer 223. The insulating layer 211 is positioned between the conductive layer 221 and the semiconductor layer 231. The conductive layer 221 functions as a gate and the insulating layer 211 functions as a first gate insulating layer. The conductive layer 222a and the conductive layer 222b function as a source and a drain. The insulating layer 213 is positioned between the conductive layer 223 and the semiconductor layer 231. The conductive layer 223 functions as a gate and the insulating layer 213 functions as a second gate insulating layer. Here, a plurality of layers obtained by processing the same conductive film are shown with the same hatching pattern.

There is no particular limitation on the structure of the transistors included in the display apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistors 201 and 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor layer of the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable to use a semiconductor having crystallinity, in which case deterioration of the transistor characteristics can be suppressed.

The semiconductor layer of the transistor preferably contains a metal oxide. That is, an OS transistor is preferably used as the transistor included in the display apparatus of this embodiment.

### [Semiconductor Layer]

For example, indium oxide, gallium oxide, and zinc oxide can be used for the semiconductor layer. The metal oxide preferably contains two or three kinds selected from indium, an element M, and zinc. The element M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more of aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO).

When the metal oxide used for the semiconductor layer is In-M-Zn oxide, the atomic ratio of In is preferably greater than or equal to the atomic ratio of M in the In-M-Zn oxide. Examples of the atomic ratio of the metal elements in such In-M-Zn oxide are In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio is described as In:Ga:Zn=5:1:6 or a composition in the vicinity thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio is described as In:Ga:Zn=1:1:1 or a composition in the vicinity thereof, the case is included where the atomic ratio of Ga is greater than 0.1 and less than or equal to 2 and the atomic ratio of Zn is greater than 0.1 and less than or equal to 2 with the atomic ratio of In being 1.

The semiconductor layer may include two or more metal oxide layers having different compositions. For example, a stacked-layer structure of a first metal oxide layer having In:M:Zn=1:3:4 [atomic ratio] or a composition in the vicinity thereof and a second metal oxide layer having In:M:Zn=1:1:1 [atomic ratio] or a composition in the vicinity thereof and being formed over the first metal oxide layer can be favorably employed. In particular, gallium or aluminum is preferably used as the element M.

Alternatively, a stacked-layer structure of one selected from indium oxide, indium gallium oxide, and IGZO, and one selected from IAZO, IAGZO, and ITZO (registered trademark) may be employed, for example.

Examples of an oxide semiconductor having crystallinity include a c-axis-aligned crystalline oxide semiconductor (CAAC-OS) and a nanocrystalline oxide semiconductor (nc-OS).

Alternatively, a transistor using silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (also referred to as an LTPS transistor) can be used. The LTPS transistor has high field-effect mobility and excellent frequency characteristics.

With the use of Si transistors such as LTPS transistors, a circuit required to be driven at a high frequency (e.g., a data driver circuit) can be formed on the same substrate as the display portion. This allows simplification of an external circuit mounted on the display apparatus and a reduction in costs of parts and mounting costs.

An OS transistor has much higher field-effect mobility than a transistor containing amorphous silicon. In addition, the OS transistor has an extremely low leakage current between a source and a drain in an off state (hereinafter also referred to as off-state current), and charge accumulated in a capacitor that is connected in series to the transistor can be held for a long period. Furthermore, the power consumption of the display apparatus can be reduced with the OS transistor.

To increase the luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher withstand voltage between a source and a drain than a Si transistor; hence, high voltage can be applied between the source and the drain of the OS transistor. Therefore, when an OS transistor is used as the driving transistor in the pixel circuit, the amount of current flowing through the light-emitting device can be increased, so that the luminance of the light-emitting device can be increased.

When transistors are driven in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be minutely determined by controlling the gate source voltage. Thus, the amount of current flowing through the light-emitting device can be controlled. Consequently, the number of gray levels expressed by the pixel circuit can be increased.

Regarding saturation characteristics of current flowing when transistors are driven in the saturation region, even when the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor is driven in the saturation region, the source-drain current hardly changes with an increase in the source-drain voltage. Hence, the luminance of the light-emitting device can be stable.

As described above, by using OS transistors as the driving transistors included in the pixel circuits, it is possible to inhibit black-level degradation, increase the luminance, increase the number of gray levels, and suppress variations in characteristics of light-emitting devices, for example.

The transistors included in the circuit 164 and the transistors included in the display portion 107 may have the same structure or different structures. One structure or two or more kinds of structures may be employed for a plurality of transistors included in the circuit 164. Similarly, one structure or two or more kinds of structures may be employed for a plurality of transistors included in the display portion 107.

All transistors included in the display portion 107 may be OS transistors, or all transistors included in the display portion 107 may be Si transistors. Alternatively, some of the transistors included in the display portion 107 may be OS transistors and the others may be Si transistors.

For example, when both an LTPS transistor and an OS transistor are used in the display portion 107, the display apparatus can have low power consumption and high driving capability. Note that a structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling current.

For example, one transistor included in the display portion 107 functions as a transistor for controlling a current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased.

Another transistor included in the display portion 107 functions as a switch for controlling selection or non-selection of a pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML structure. This structure can significantly reduce a leakage current that would flow through a transistor and a leakage current that would flow between adjacent light-emitting devices. Displaying images on the display apparatus having this structure can bring one or more of image crispness, image sharpness, high color saturation, and a high contrast ratio to the viewer. When a leakage current that would flow through the transistor and a lateral leakage current that would flow between light-emitting devices are extremely low, display with little leakage of light at the time of black display (black-level degradation), for example, can be achieved.

In particular, current flowing between adjacent light-emitting devices having the MML structure can be extremely reduced.

### [Transistor 209 and Transistor 210]

FIGS. 18B and 18C are cross-sectional views each illustrating another example of a cross-sectional structure of a transistor that can be used for the display apparatus 100H.

A transistor 209 and a transistor 210 each include the conductive layer 221, the insulating layer 211, the semiconductor layer 231, the conductive layer 222a, the conductive layer 222b, an insulating layer 225, the conductive layer 223, and the insulating layer 215. The semiconductor layer 231 includes a channel formation region 231i and a pair of low-resistance regions 231n. The insulating layer 211 is positioned between the conductive layer 221 and the channel formation region 231i. The conductive layer 221 functions as a gate and the insulating layer 211 functions as a first gate insulating layer. The insulating layer 225 is positioned at least between the conductive layer 223 and the channel formation region 231i. The conductive layer 223 functions as a gate, and the insulating layer 225 functions as a second gate insulating layer. The conductive layer 222a is electrically connected to one of the pair of low-resistance regions 231n and the conductive layer 222b is electrically connected to the other of the pair of low-resistance regions 231n. The insulating layer 215 covers the conductive layer 223. An insulating layer 218 covers the transistor.

### Structure Example 1 of Insulating Layer 225

In the transistor 209, the insulating layer 225 covers the top and side surfaces of the semiconductor layer 231 (see FIG. 18B). The insulating layer 225 and the insulating layer 215 have openings, through which the conductive layers 222a and 222b are electrically connected to the low-resistance regions 231n. One of the conductive layers 222a and 222b functions as a source, and the other functions as a drain.

### Structure Example 2 of Insulating Layer 225

In the transistor 210, the insulating layer 225 overlaps with the channel formation region 231i of the semiconductor layer 231 and does not overlap with the low-resistance regions 231n (see FIG. 18C). For example, the insulating layer 225 can be processed into a predetermined shape using the conductive layer 223 as a mask. The insulating layer 215 covers the insulating layer 225 and the conductive layer 223. The insulating layer 215 has openings, and the conductive layers 222a and 222b are electrically connected to the low-resistance regions 231n.

### [Connection Portion 204]

A connection portion 204 is provided for the substrate 14b. The connection portion 204 includes a conductive layer 166, which is electrically connected to the wiring 165. Note that the connection portion 204 does not overlap with the substrate 16b, and the conductive layer 166 is exposed. Note that the conductive layer 166 and the conductive layer 171 can be formed by processing one conductive film. The conductive layer 166 is electrically connected to the FPC 177 through a connection layer 242. As the connection layer 242, for example, an anisotropic conductive film (ACF) or an anisotropic conductive paste (ACP) can be used.

### <<Display Apparatus 100I>>

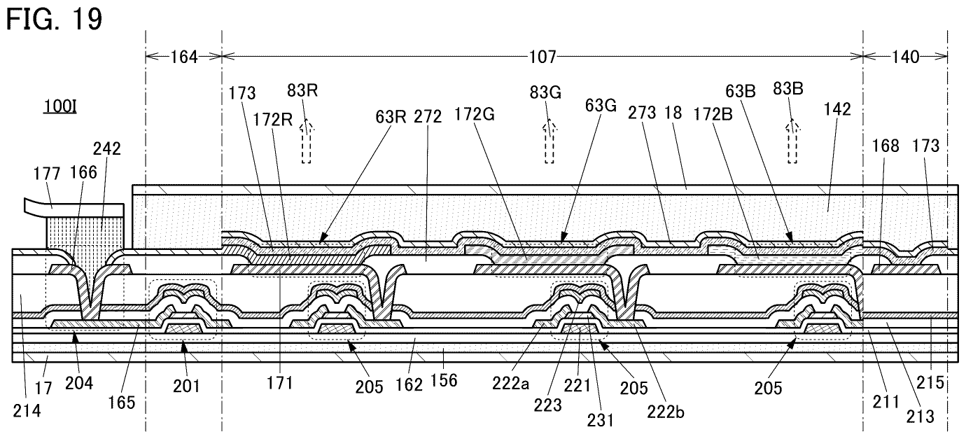

FIG. 19 is a cross-sectional view illustrating a structure of a display apparatus 100I. The display apparatus 100I is different from the display apparatus 100H in having flexibility. In other words, the display apparatus 100I is a flexible display. The display apparatus 100I includes a substrate 17 and a substrate 18 instead of the substrate 14b and the substrate 16b, respectively. The substrates 17 and 18 both have flexibility.

The display apparatus 100I includes a bonding layer 156 and an insulating layer 162. The insulating layer 162 and the substrate 17 are bonded to each other with the bonding layer 156. For example, the material that can be used for the bonding layer 122 can be used for the bonding layer 156. For example, the material that can be used for the insulating layer 211, the insulating layer 213, or the insulating layer 215 can be used for the insulating layer 162. Note that the transistors 201 and 205 are provided over the insulating layer 162.

For example, the insulating layer 162 is formed over a formation substrate, and the transistors, the light-emitting devices, and the like are formed over the insulating layer 162. Then, the bonding layer 142 is formed over the light-emitting devices, and the formation substrate and the substrate 18 are bonded to each other with the bonding layer 142. After that, the formation substrate is separated from the insulating layer 162 and the surface of the insulating layer 162 is exposed. Then, the bonding layer 156 is formed on the exposed surface of the insulating layer 162, and the insulating layer 162 and the substrate 17 are bonded to each other with the bonding layer 156. In this manner, the components formed over the formation substrate can be transferred onto the substrate 17, whereby the display apparatus 100I can be manufactured.

### <<Display Apparatus 100J>>

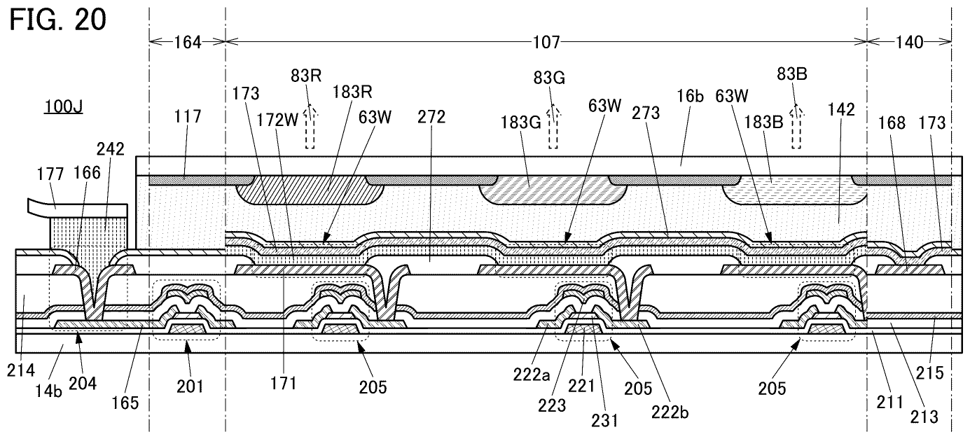

FIG. 20 is a cross-sectional view illustrating a structure of a display apparatus 100J. The display apparatus 100J is different from the display apparatus 100H in including light-emitting devices 63W, instead of the light-emitting devices 63R, 63G and 63B, and the coloring layers 183R, 183G, and 183B.

The display apparatus 100J includes the coloring layers 183R, 183G, and 183B between the substrate 16b and the substrate 14b. The coloring layer 183R overlaps with one light-emitting device 63W, the coloring layer 183G overlaps with another light-emitting device 63W, and the coloring layer 183B overlaps with another light-emitting device 63W.

The display apparatus 100J includes a light-blocking layer 117. For example, the light-blocking layer 117 is provided between the coloring layers 183R and 183G, between the coloring layers 183G and 183B, and between the coloring layers 183B and 183R. The light-blocking layer 117 includes a region overlapping with the connection portion 140 and a region overlapping with the circuit 164.

The light-emitting device 63W can emit white light, for example. For example, the coloring layer 183R, the coloring layer 183G, and the coloring layer 183B can transmit red light, green light, and blue light, respectively. In this manner, the display apparatus 100J can emit the red light 83R, the green light 83G, and the blue light 83B, for example, to perform full color display.

### <<Display Apparatus 100K>>

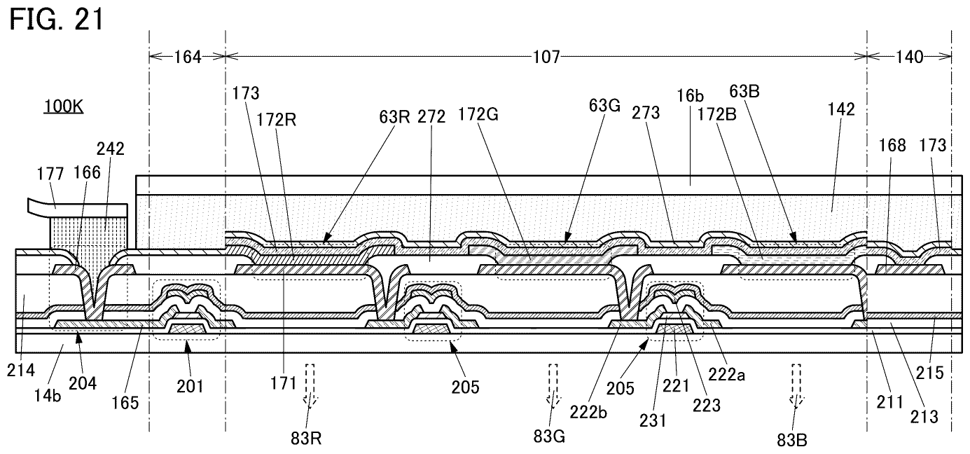

FIG. 21 is a cross-sectional view illustrating a structure of a display apparatus 100K. The display apparatus 100K is different from the display apparatus 100H in having a bottom-emission structure. The light-emitting devices emit the light 83R, the light 83G, and the light 83B to the substrate 14b side. A visible-light-transmitting material is used for the conductive layer 171. A visible-light-reflecting material is used for the conductive layer 173.

### <<Display Apparatus 100L>>

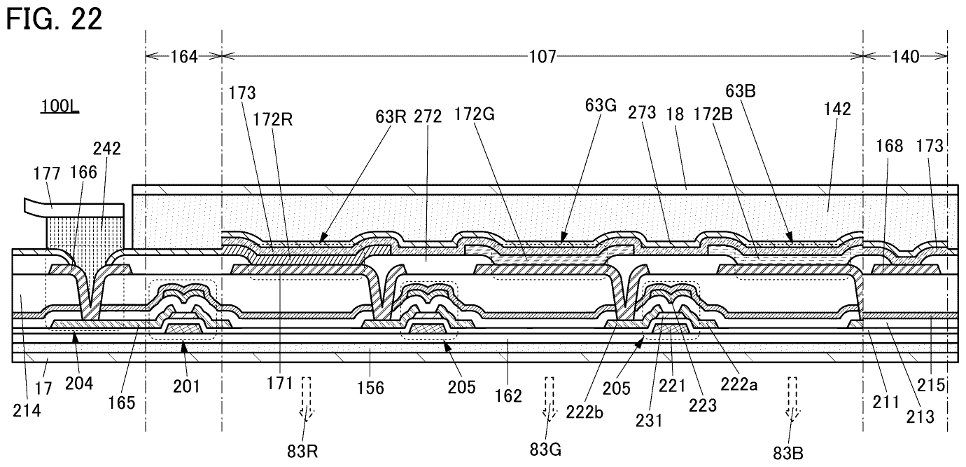

FIG. 22 is a cross-sectional view illustrating a structure of a display apparatus 100L. The display apparatus 100L is different from the display apparatus 100H in having flexibility and a bottom-emission structure. The display apparatus 100L includes the substrate 17 and the substrate 18 instead of the substrate 14b and the substrate 16b, respectively. The substrates 17 and 18 both have flexibility. The light-emitting devices emit the light 83R, the light 83G, and the light 83B to the substrate 17 side.

The conductive layer 221 and the conductive layer 223 may have a property of transmitting visible light and a property of reflecting visible light. When the conductive layers 221 and 223 have a property of transmitting visible light, the visible-light transmittance in the display portion 107 can be improved. Meanwhile, when the conductive layers 221 and 223 have a property of reflecting visible light, the amount of visible light entering the semiconductor layer 231 can be reduced. In addition, damage to the semiconductor layer 231 can be reduced. Accordingly, the reliability of the display apparatus 100K or the display apparatus 100L can be increased.

Even in a top-emission display apparatus such as the display apparatus 100H or the display apparatus 100I, at least part of the layers included in the transistor 205 may have a property of transmitting visible light. In this case, the conductive layer 171 also has a property of transmitting visible light. Accordingly, the visible-light transmittance in the display portion 107 can be improved.

### <<Display Apparatus 100M>>

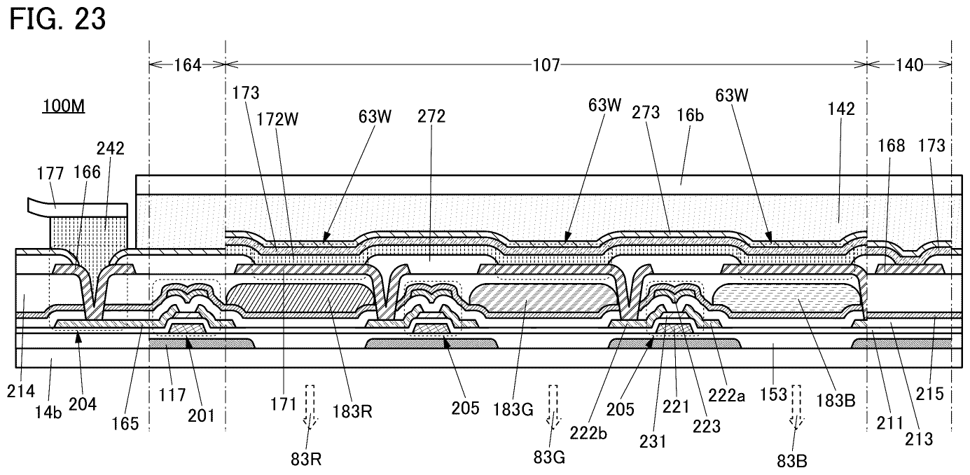

FIG. 23 is a cross-sectional view illustrating a structure of a display apparatus 100M. The display apparatus 100M is different from the display apparatus 100H in having a bottom-emission structure and including the light-emitting devices 63W, instead of the light-emitting devices 63R, 63G and 63B, and the coloring layers 183R, 183G, and 183B.

The display apparatus 100M includes the coloring layers 183R, 183G, and 183B. The display apparatus 100M includes the light-blocking layer 117.

### [Coloring Layer 183R, Coloring Layer 183G, and Coloring Layer 183B]

The coloring layers 183R, 183G, and 183B are positioned between the substrate 14b and the respective light-emitting devices 63W. For example, the coloring layers 183R, 183G, and 183B can be provided between the insulating layer 215 and the insulating layer 214.

### [Light-Blocking Layer 117]

The light-blocking layer 117 is provided over the substrate 14b and positioned between the substrate 14b and the transistor 205. The insulating layer 153 is positioned between the light-blocking layer 117 and the transistor 205. For example, the light-blocking layer 117 does not overlap with a light-emitting region of the light-emitting device 63W. For example, the light-blocking layer 117 overlaps with the connection portion 140 and the circuit 164.

The light-blocking layer 117 can also be provided in the display apparatus 100K or the display apparatus 100L. In this case, light emitted from the light-emitting devices 63R, 63G, and 63B can be inhibited from being reflected by the substrate 14b and being diffused inside the display apparatus 100K or the display apparatus 100L, for example. Thus, the display apparatus 100K and the display apparatus 100L can provide high display quality. Meanwhile, when the light-blocking layer 117 is not provided, the extraction efficiency of light emitted from the light-emitting devices 63R, 63G, and 63B can be increased.

At least part of this embodiment can be implemented in combination with any of the other embodiments described in this specification, as appropriate.

### Embodiment 11

In this embodiment, electronic devices of embodiments of the present invention will be described.

Electronic devices of this embodiment are each provided with the display apparatus of one embodiment of the present invention in a display portion. The display apparatus of one embodiment of the present invention is highly reliable and can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display apparatus of one embodiment of the present invention can have high definition, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×10⁸⁰), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With such a display apparatus having one or both of high definition and high resolution, the electronic device can have higher realistic sensation, sense of depth, and the like in personal use such as portable use or home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

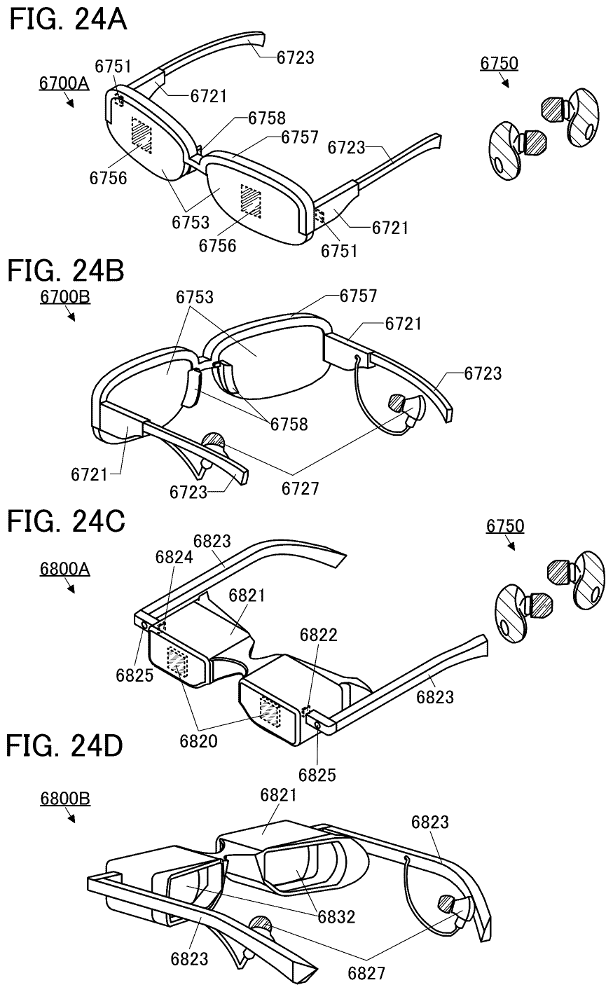

Examples of head-mounted wearable devices are described with reference to FIGS. 24A to 24D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 6700A illustrated in FIG. 24A and an electronic device 6700B illustrated in FIG. 24B each include a pair of display panels 6751, a pair of housings 6721, a communication portion (not illustrated), a pair of wearing portions 6723, a control portion (not illustrated), an image capturing portion (not illustrated), a pair of optical members 6753, a frame 6757, and a pair of nose pads 6758.

The display apparatus of one embodiment of the present invention can be used for the display panels 6751. Thus, a highly reliable electronic device is obtained.

The electronic devices 6700A and 6700B can each project images displayed on the display panels 6751 onto display regions 6756 of the optical members 6753. Since the optical members 6753 have a light-transmitting property, the user can see images displayed on the display regions, which are superimposed on transmission images seen through the optical members 6753. Accordingly, the electronic devices 6700A and 6700B are electronic devices capable of AR display.

In the electronic devices 6700A and 6700B, a camera capable of capturing images of the front side may be provided as the image capturing portion. Furthermore, when the electronic devices 6700A and 6700B are provided with an acceleration sensor such as a gyroscope sensor, the orientation of the user's head can be sensed and an image corresponding to the orientation can be displayed on the display regions 6756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 6700A and 6700B are provided with a battery so that they can be charged wirelessly and/or by wire.

A touch sensor module may be provided in the housing 6721. The touch sensor module has a function of detecting a touch on the outer surface of the housing 6721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 6721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 6800A illustrated in FIG. 24C and an electronic device 6800B illustrated in FIG. 24D each include a pair of display portions 6820, a housing 6821, a communication portion 6822, a pair of wearing portions 6823, a control portion 6824, a pair of image capturing portions 6825, and a pair of lenses 6832.

The display apparatus of one embodiment of the present invention can be used in the display portions 6820. Thus, a highly reliable electronic device is obtained.

The display portions 6820 are positioned inside the housing 6821 so as to be seen through the lenses 6832. When the pair of display portions 6820 display different images, three-dimensional display using parallax can be performed.

The electronic devices 6800A and 6800B can be regarded as electronic devices for VR. The user who wears the electronic device 6800A or the electronic device 6800B can see images displayed on the display portions 6820 through the lenses 6832.

The electronic devices 6800A and 6800B preferably include a mechanism for adjusting the lateral positions of the lenses 6832 and the display portions 6820 so that the lenses 6832 and the display portions 6820 are positioned optimally in accordance with the positions of the user's eyes. Moreover, the electronic devices 6800A and 6800B preferably include a mechanism for adjusting focus by changing the distance between the lenses 6832 and the display portions 6820.

The electronic device 6800A or the electronic device 6800B can be mounted on the user's head with the wearing portions 6823. FIG. 24C, for instance, shows an example where the wearing portion 6823 has a shape like a temple (also referred to as a joint or the like) of glasses; however, one embodiment of the present invention is not limited thereto. The wearing portion 6823 can have any shape with which the user can wear the electronic device, for example, a shape of a helmet or a band.

The image capturing portion 6825 has a function of obtaining information on the external environment. Data obtained by the image capturing portion 6825 can be output to the display portion 6820. An image sensor can be used for the image capturing portion 6825. Moreover, a plurality of cameras may be provided so as to support a plurality of fields of view, such as a telescope field of view and a wide field of view.

Although an example where the image capturing portions 6825 are provided is shown here, a range sensor (also referred to as a sensing portion) capable of measuring a distance between the user and an object just needs to be provided. In other words, the image capturing portion 6825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 6800A may include a vibration mechanism that functions as bone-conduction earphones. For example, at least one of the display portion 6820, the housing 6821, and the wearing portion 6823 can include the vibration mechanism. Thus, without additionally requiring an audio device such as headphones, earphones, or a speaker, the user can enjoy video and sound only by wearing the electronic device 6800A.

The electronic devices 6800A and 6800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 6750. The earphones 6750 include a communication portion (not illustrated) and have a wireless communication function. The earphones 6750 can receive information (e.g., audio data) from the electronic device with the wireless communication function. For example, the electronic device 6700A in FIG. 24A has a function of transmitting information to the earphones 6750 with the wireless communication function. As another example, the electronic device 6800A in FIG. 24C has a function of transmitting information to the earphones 6750 with the wireless communication function.

The electronic device may include an earphone portion. The electronic device 6700B in FIG. 24B includes earphone portions 6727. For example, the earphone portion 6727 can be connected to the control portion by wire. Part of a wiring that connects the earphone portion 6727 and the control portion may be positioned inside the housing 6721 or the wearing portion 6723.

Similarly, the electronic device 6800B in FIG. 24D includes earphone portions 6827. For example, the earphone portion 6827 can be connected to the control portion 6824 by wire. Part of a wiring that connects the earphone portion 6827 and the control portion 6824 may be positioned inside the housing 6821 or the wearing portion 6823. Alternatively, the earphone portions 6827 and the wearing portions 6823 may include magnets. This is preferred because the earphone portions 6827 can be fixed to the wearing portions 6823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 6700A and 6700B) and the goggles-type device (e.g., the electronic devices 6800A and 6800B) are preferable as the electronic device of one embodiment of the present invention.

The electronic device of one embodiment of the present invention can transmit information to earphones by wire or wirelessly.

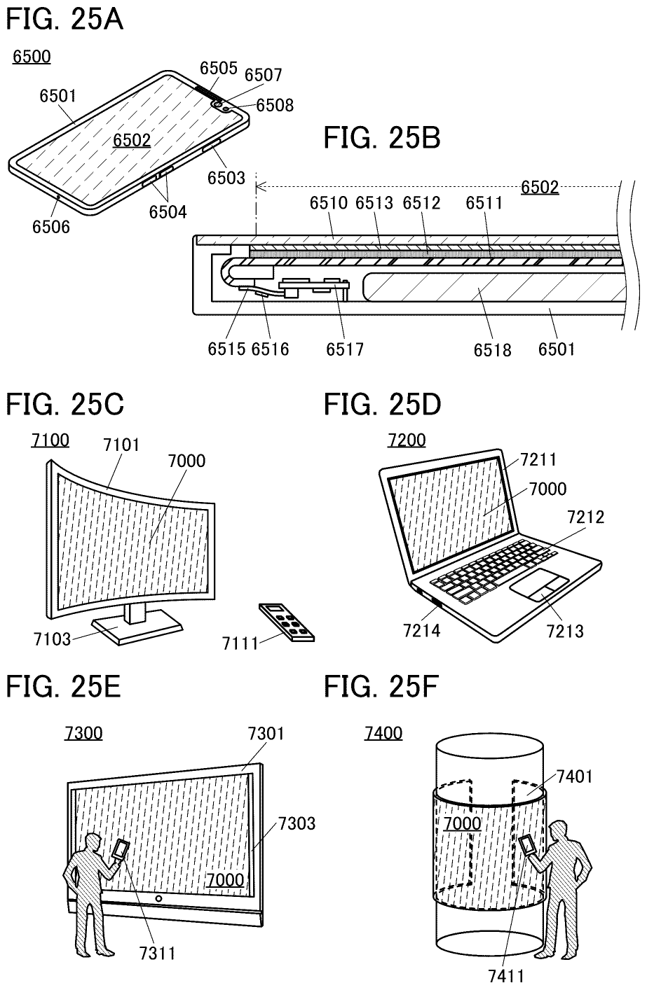

An electronic device 6500 illustrated in FIG. 25A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic device is obtained.

FIG. 25B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

The flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 25C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000. Thus, a highly reliable electronic device is obtained.

Operation of the television device 7100 illustrated in FIG. 25C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel of the remote controller 7111, channels and volume can be controlled and images displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 25D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, a highly reliable electronic device is obtained.

FIGS. 25E and 25F illustrate examples of digital signage.

Digital signage 7300 illustrated in FIG. 25E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 25F shows digital signage 7400 attached to a cylindrical pillar 7401. The digital signage 7400 includes the display portion 7000 provided along a curved surface of the pillar 7401.

In FIGS. 25E and 25F, the display apparatus of one embodiment of the present invention can be used in the display portion 7000. Thus, a highly reliable electronic device is obtained.

A larger area of the display portion 7000 can increase the amount of information that can be provided at a time. The larger display portion 7000 attracts more attention, so that the effectiveness of the advertisement can be increased, for example.

The use of the touch panel in the display portion 7000 is preferable because in addition to display of still or moving images on the display portion 7000, intuitive operation by a user is possible. Moreover, for an application for providing information such as route information or traffic information, usability can be enhanced by intuitive operation.

As illustrated in FIGS. 25E and 25F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

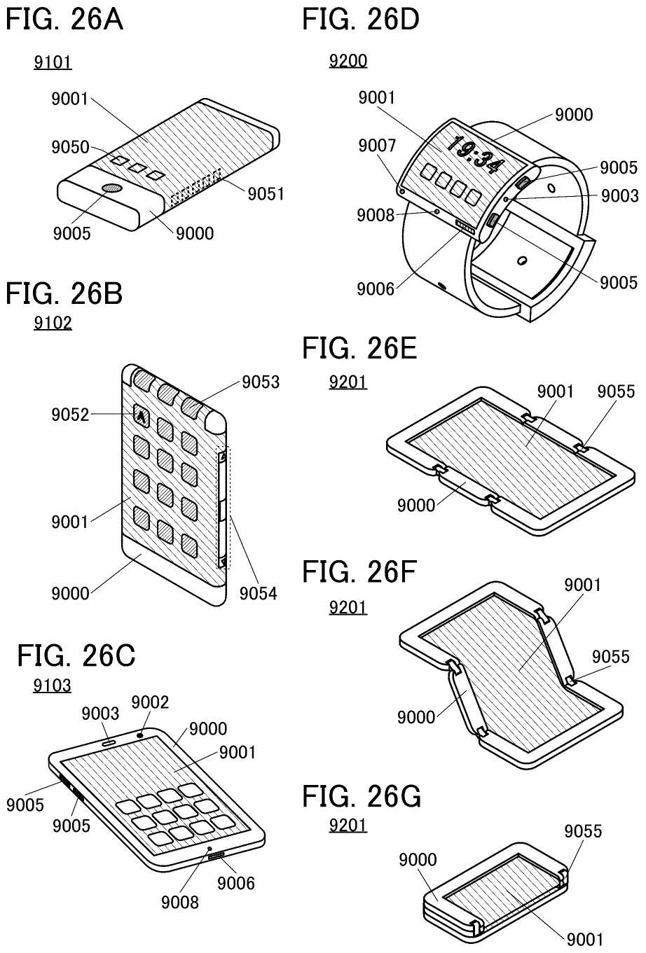

Electronic devices illustrated in FIGS. 26A to 26G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays), a microphone 9008, and the like.

The electronic devices illustrated in FIGS. 26A to 26G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of taking a still image or a moving image, a function of storing the taken image in a storage medium (an external storage medium or a storage medium incorporated in the camera), a function of displaying the taken image on the display portion, and the like.

The electronic devices in FIGS. 26A to 26G are described in detail below.

FIG. 26A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 26A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050, for example, may be displayed at the position where the information 9051 is displayed.

FIG. 26B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of user's clothes. Thus, the user can see the display without taking out the portable information terminal 9102 from the pocket and decide whether to answer the call, for example.

FIG. 26C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 26D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 26E to 26G are perspective views of a foldable portable information terminal 9201. FIG. 26E is a perspective view showing the portable information terminal 9201 that is opened. FIG. 26G is a perspective view showing the portable information terminal 9201 that is folded. FIG. 26F is a perspective view showing the portable information terminal 9201 that is shifted from one of the states in FIGS. 26E and 26G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate. In this specification, in the case where a plurality of structure examples are shown in one embodiment, the structure examples can be combined as appropriate.

### Example 1

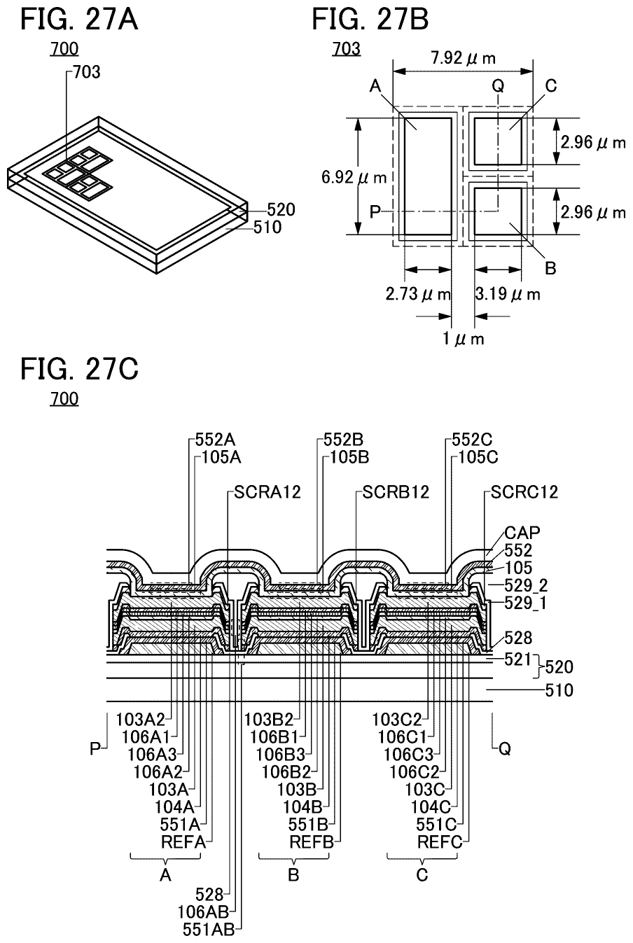

In this example, a display apparatus fabricated by a method for manufacturing a display apparatus of one embodiment of the present invention is described with reference to FIGS. 27A to 27C, FIGS. 28A to 28C, FIG. 29, FIG. 30, FIG. 31, FIG. 32, FIG. 33, FIG. 34, FIG. 35, FIG. 36, FIG. 37, FIG. 38, FIG. 39, FIG. 40, FIG. 41, FIG. 42, FIG. 43, FIG. 44, FIG. 45, FIG. 46, FIG. 47, FIG. 48, FIG. 49, FIG. 50, FIG. 51, FIG. 52, FIG. 53, FIG. 54, FIG. 55, FIG. 56, and FIG. 57.

FIG. 27A is a perspective view illustrating a structure of the display apparatus fabricated in this example. FIG. 27B is a top view illustrating part of FIG. 27A. FIG. 27C is a cross-sectional view taken along a cutting line P-Q in FIG. 27B.

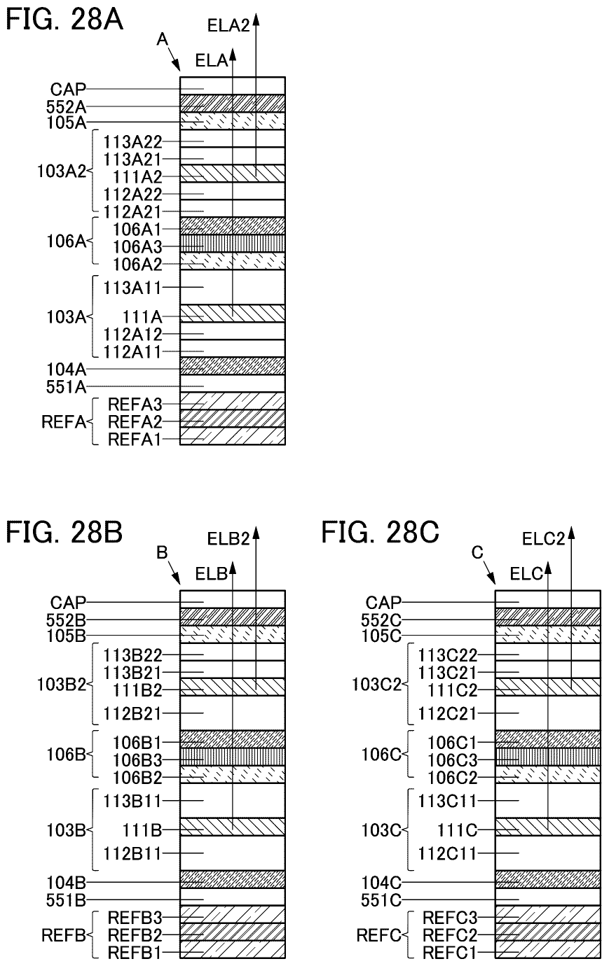

FIG. 28A illustrates a structure of a light-emitting device A. FIG. 28B illustrates a structure of a light-emitting device B. FIG. 28C illustrates a structure of a light-emitting device C.

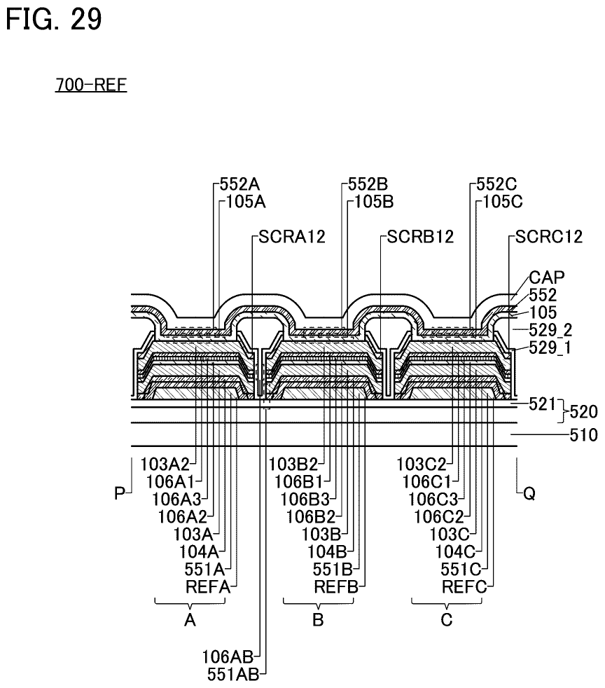

FIG. 29 is a cross-sectional view illustrating a structure of a comparative apparatus.

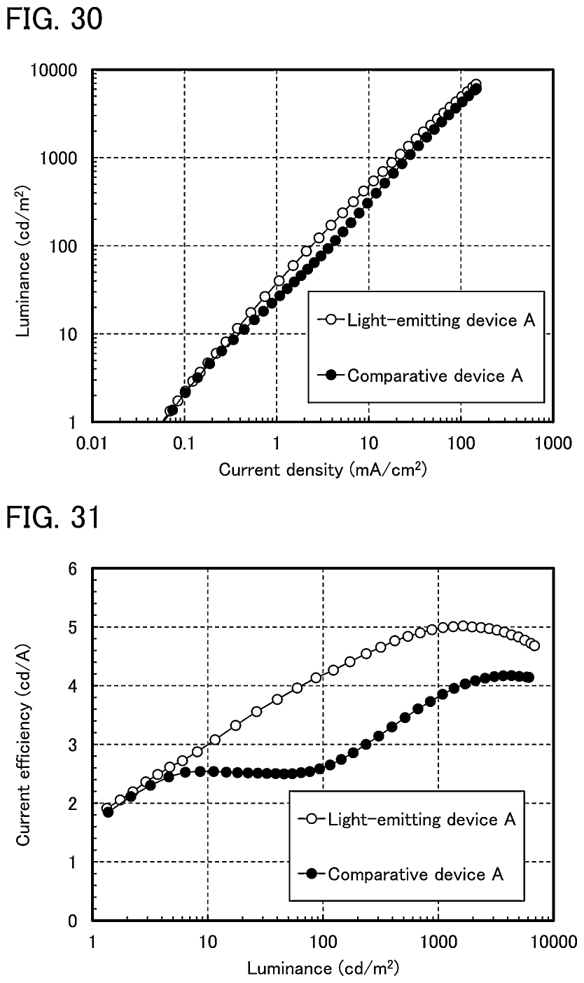

FIG. 30 shows current density-luminance characteristics of the light-emitting device A.

FIG. 31 shows luminance-current efficiency characteristics of the light-emitting device A.

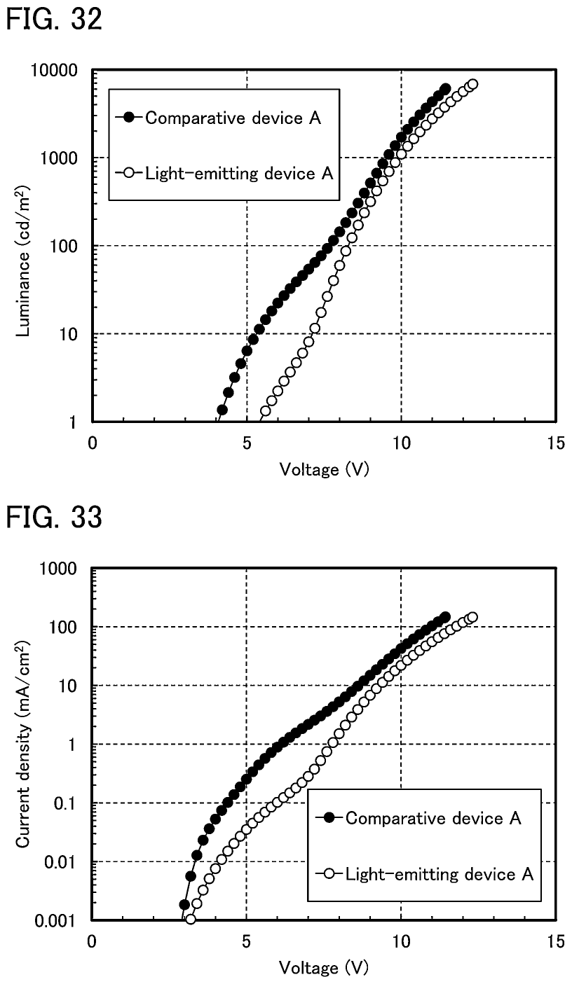

FIG. 32 shows voltage-luminance characteristics of the light-emitting device A.

FIG. 33 shows voltage current density characteristics of the light-emitting device A.

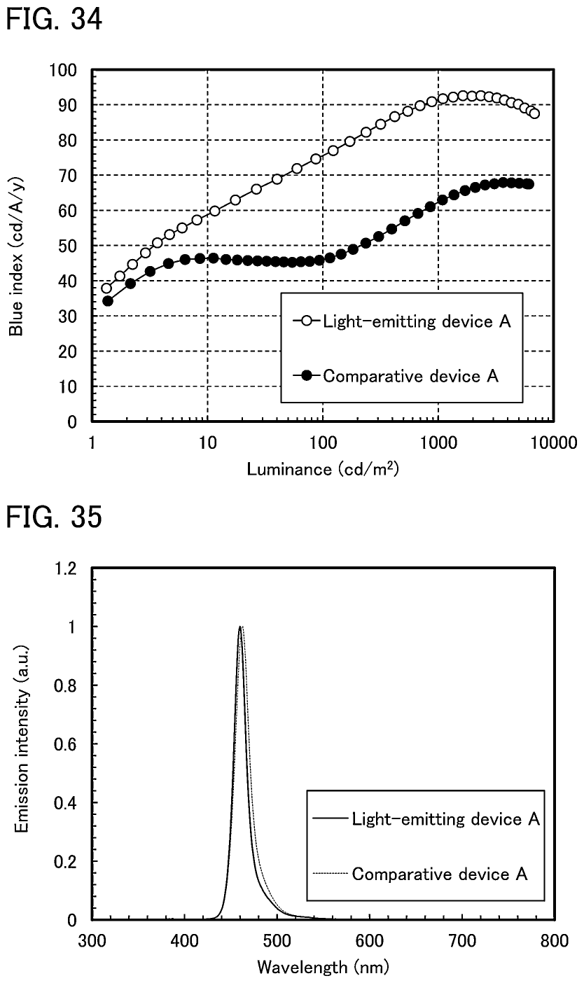

FIG. 34 shows luminance-blue index characteristics of the light-emitting device A. Note that the blue index (BI) is one of the indicators of characteristics of a blue light-emitting device, and is a value obtained by dividing current efficiency (cd/A) by chromaticity y. In general, blue light with high color purity is useful in expressing a wide color gamut. In addition, blue light with higher color purity tends to have lower chromaticity y. Thus, a value obtained by dividing current efficiency (cd/A) by chromaticity y is the indicator of usefulness of a blue light-emitting device. In other words, a blue light-emitting device with a large BI is suitable for providing a highly efficient display apparatus capable of displaying an image with a wide color gamut.

FIG. 35 shows an emission spectrum of the light-emitting device A emitting light at a luminance of 1000 cd/m².

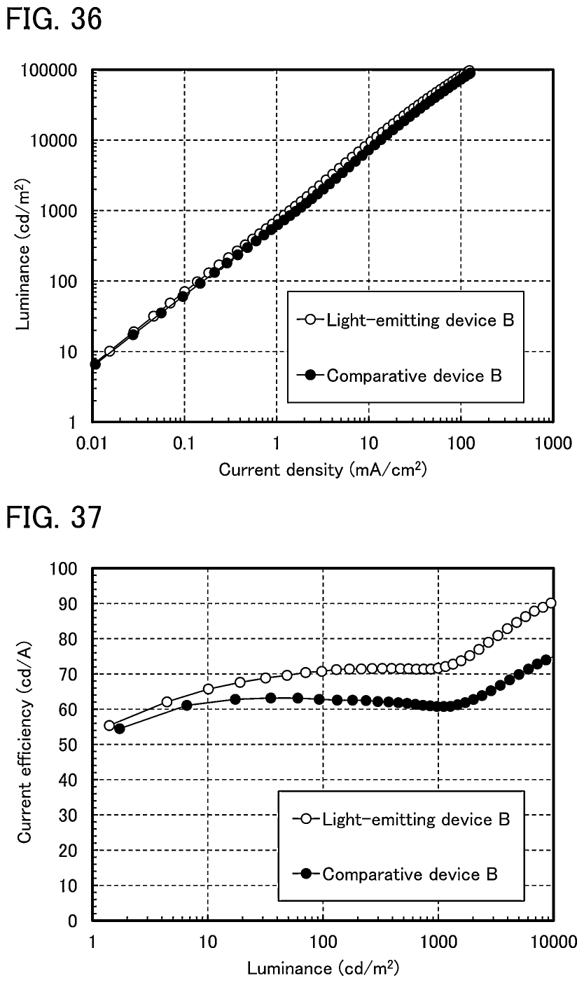

FIG. 36 shows current density-luminance characteristics of the light-emitting device B.

FIG. 37 shows luminance-current efficiency characteristics of the light-emitting device B.

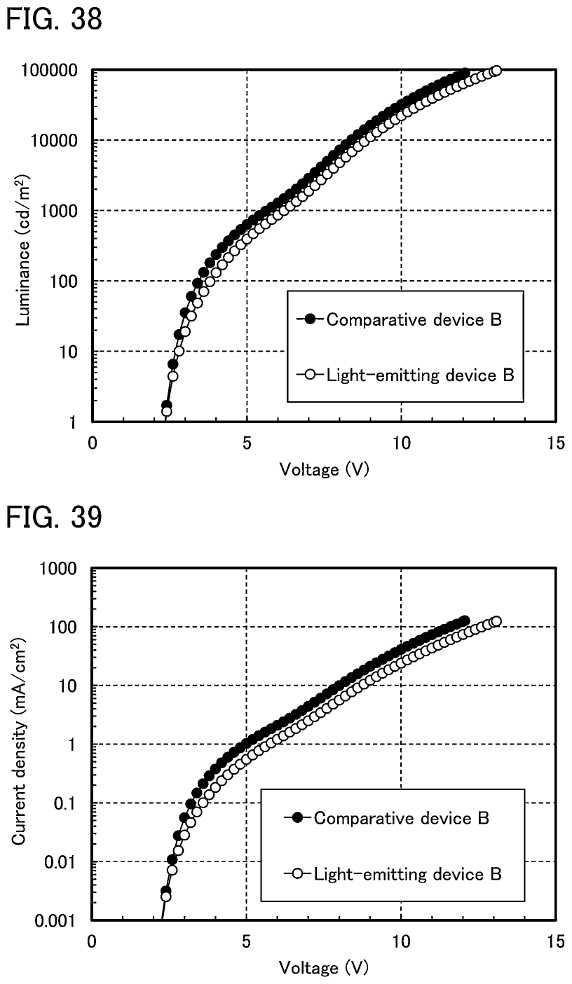

FIG. 38 shows voltage-luminance characteristics of the light-emitting device B.

FIG. 39 shows voltage-current density characteristics of the light-emitting device B.

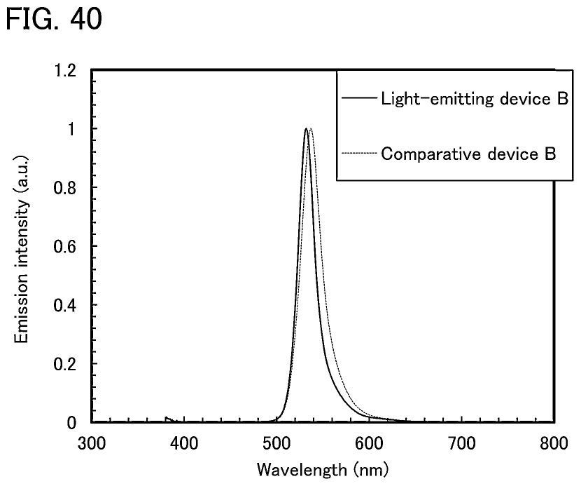

FIG. 40 shows an emission spectrum of the light-emitting device B emitting light at a luminance of 1000 cd/m².

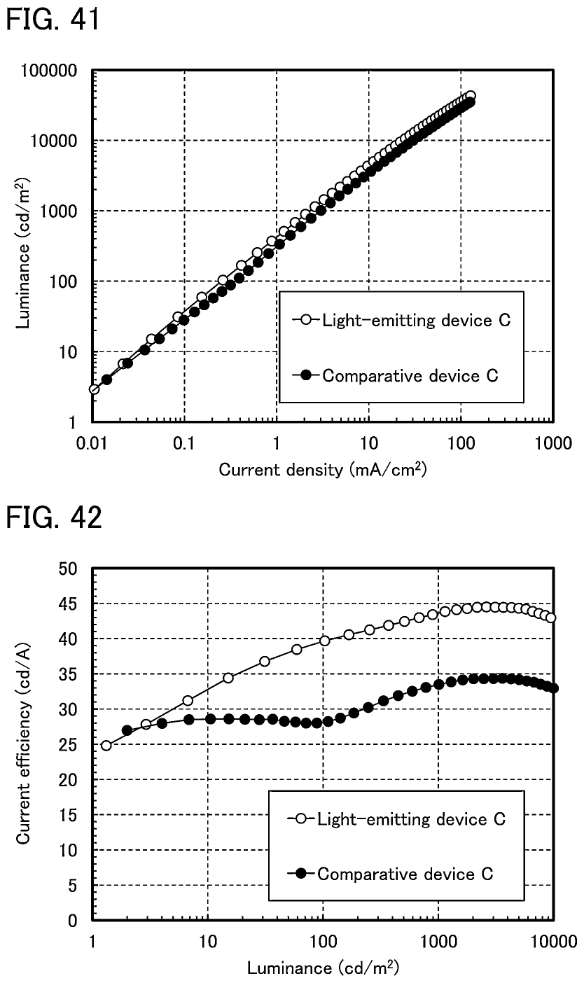

FIG. 41 shows current density-luminance characteristics of the light-emitting device C.

FIG. 42 shows luminance-current efficiency characteristics of the light-emitting device C.

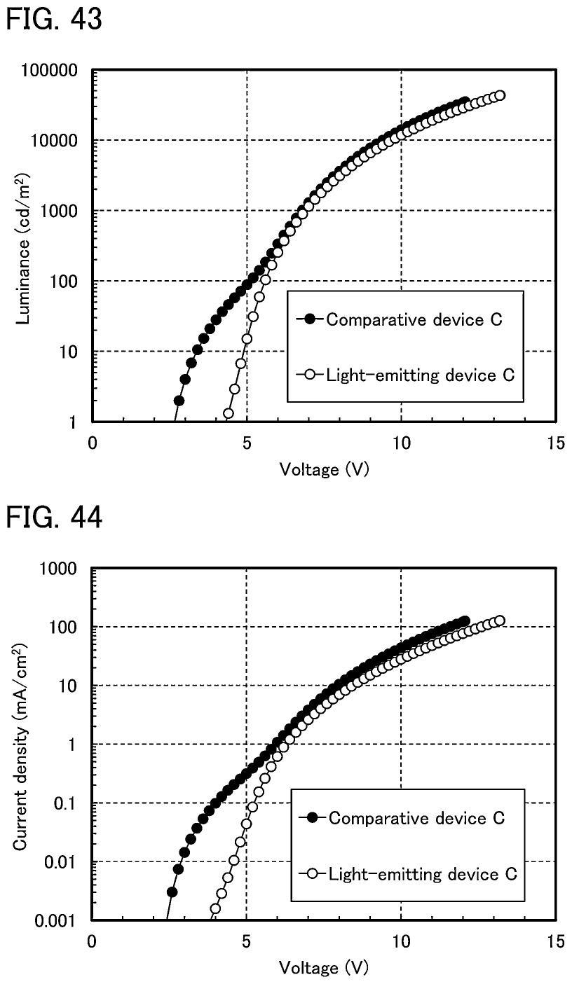

FIG. 43 shows voltage-luminance characteristics of the light-emitting device C.

FIG. 44 shows voltage-current density characteristics of the light-emitting device C.

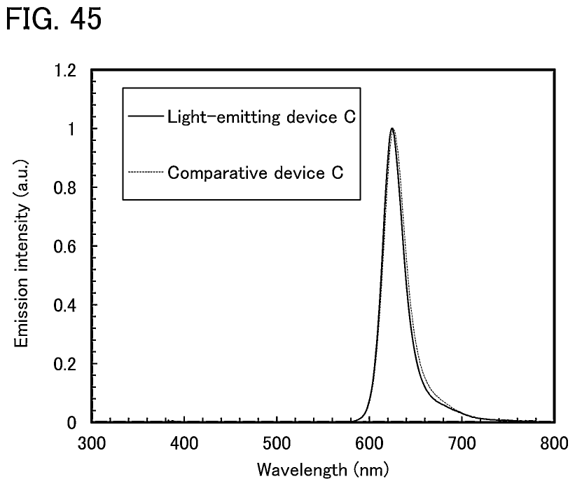

FIG. 45 shows an emission spectrum of the light-emitting device C emitting light at a luminance of 1000 cd/m².

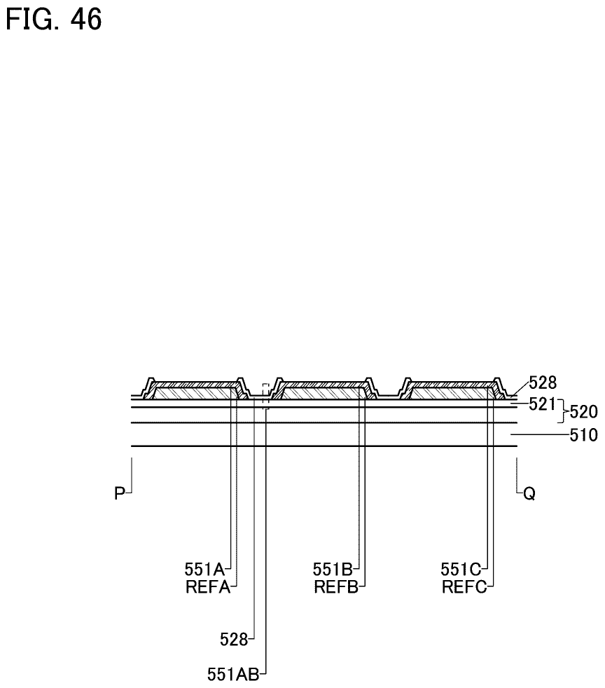

FIG. 46 illustrates a fabrication method of the display apparatus.

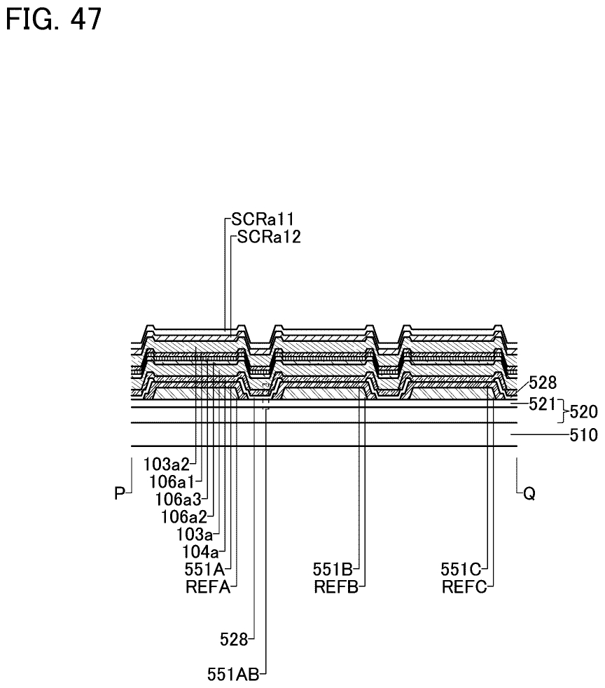

FIG. 47 illustrates the fabrication method of the display apparatus.

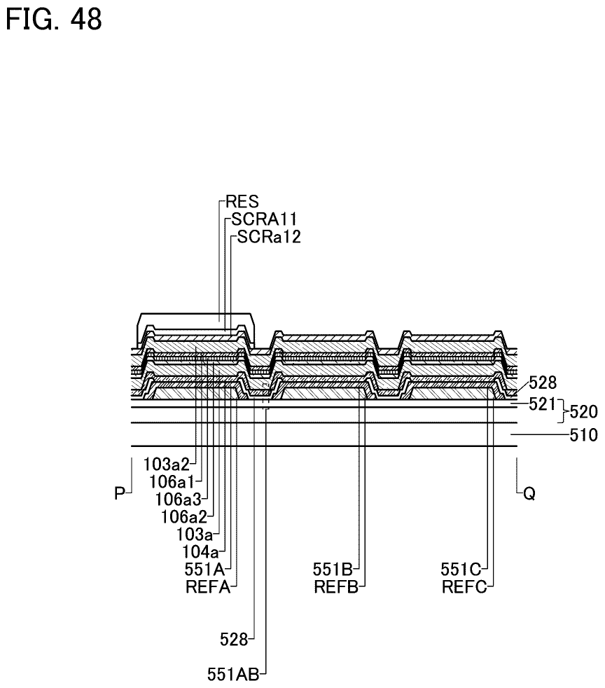

FIG. 48 illustrates the fabrication method of the display apparatus.

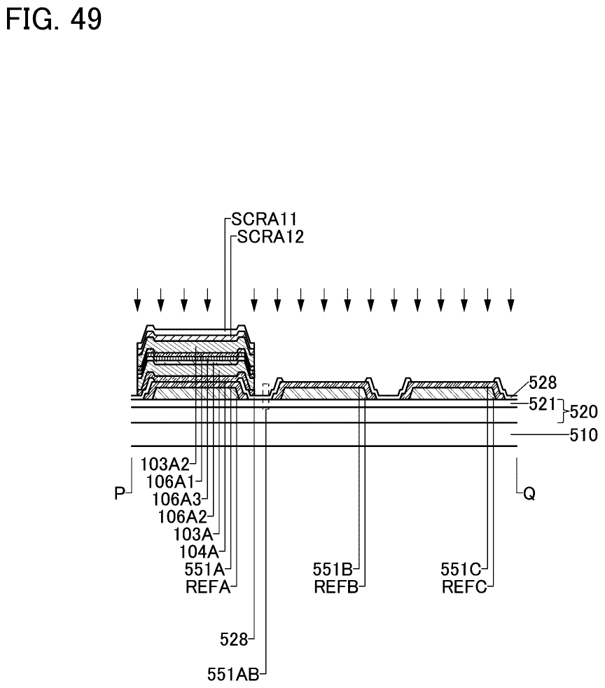

FIG. 49 illustrates the fabrication method of the display apparatus.

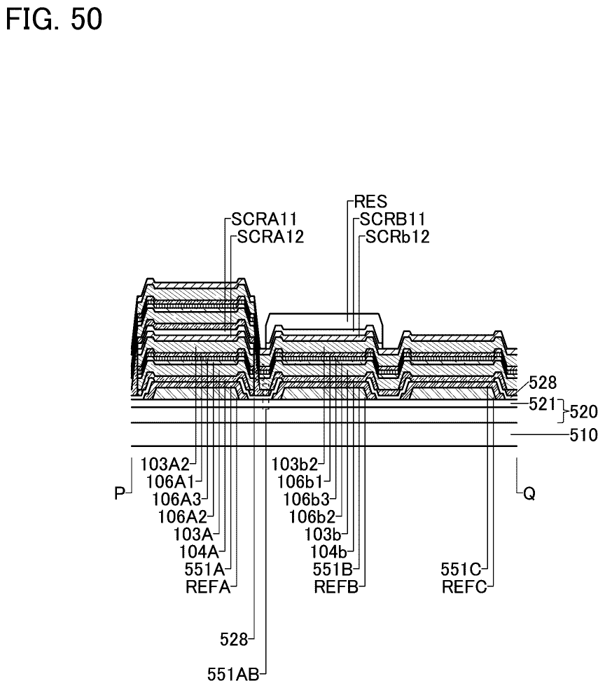

FIG. 50 illustrates the fabrication method of the display apparatus.

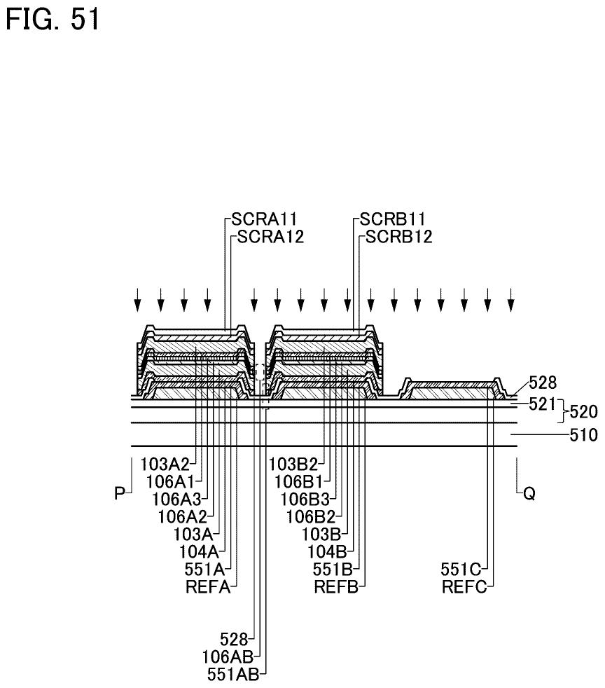

FIG. 51 illustrates the fabrication method of the display apparatus.

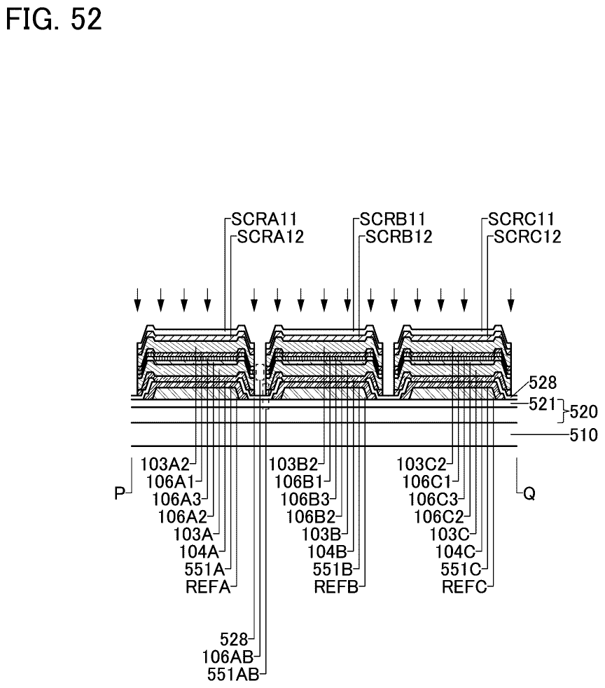

FIG. 52 illustrates the fabrication method of the display apparatus.

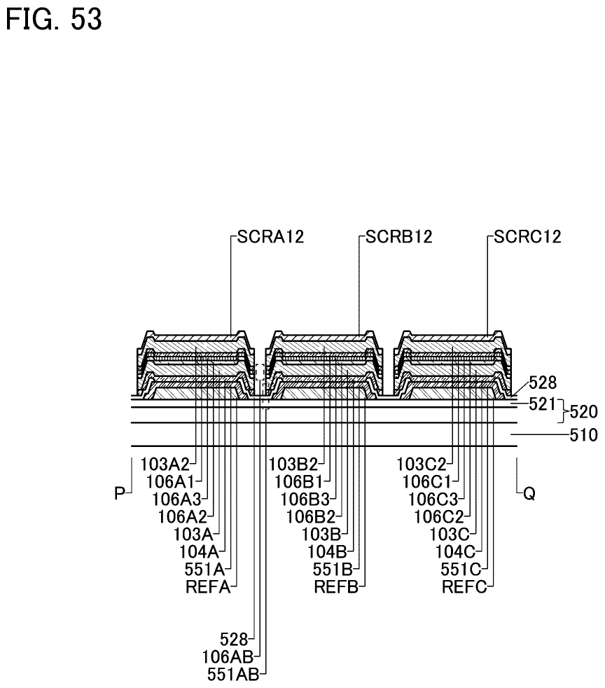

FIG. 53 illustrates the fabrication method of the display apparatus.

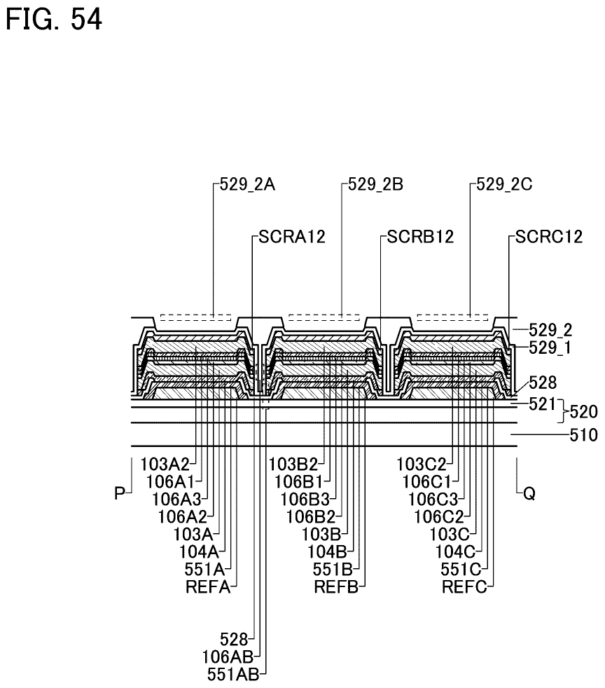

FIG. 54 illustrates the fabrication method of the display apparatus.

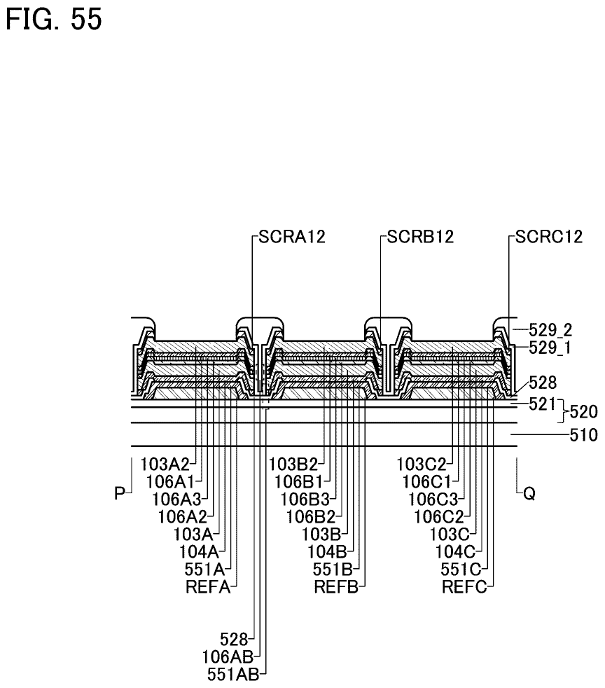

FIG. 55 illustrates the fabrication method of the display apparatus.

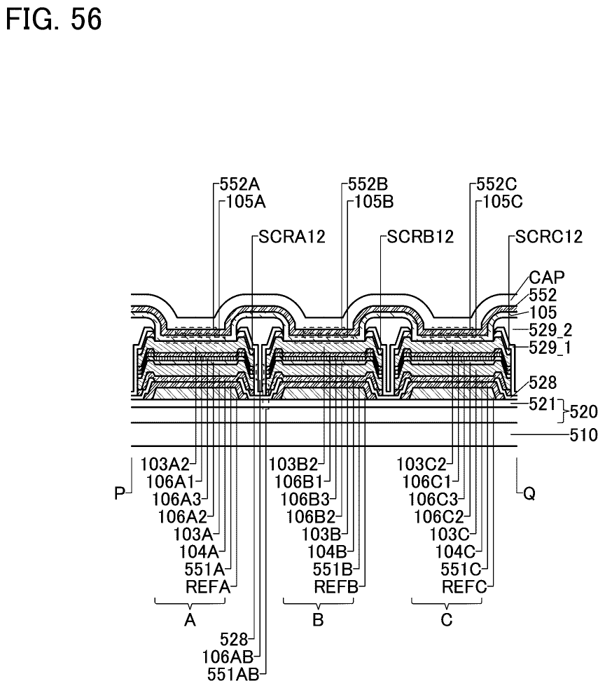

FIG. 56 illustrates the fabrication method of the display apparatus.

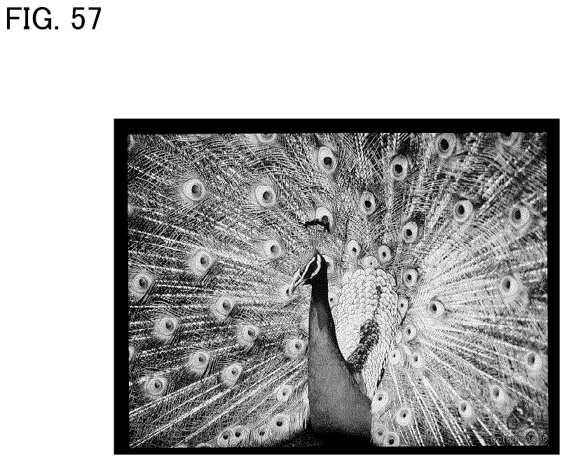

FIG. 57 is a photograph showing a display state of the fabricated display apparatus.

### <Display Apparatus>

Specifications of the fabricated display apparatus, which is described in this example, are shown below. Note that a pixel circuit includes an OS transistor using an oxide semiconductor.

TABLE 1

| | Specifications | |
|---|---|---|
| Screen size | 1.50 | inches |
| Panel size | 30.41 mm (H) × 22.81 mm (V) | |
| Structure | OLED/OS | |
| Pixel number | 3840 (H) × 2880 (V) | |
| Pixel density | 3207 | ppi |

| | |
|---|---|
| Pixel size | 7.92 μm (H) × 7.92 μm (V) |
| Pixel arrangement | RGB S-stripe arrangement |
| Aperture ratio | 42.9% |
| Coloring method | SBS (using photolithography method) |
| Emission structure | Top-emission structure |
| Source driver | IC bonding |
| Gate driver | Integrated |

FIG. 57 is a photograph of the display apparatus displaying an image. The display apparatus was capable of displaying a clear image with an ultra-high resolution of 3207 ppi. In addition, occurrence of a cross talk phenomenon between adjacent pixels was suppressed, so that a wide color gamut was able to be expressed. Specifically, the color gamut of the fabricated display apparatus covered higher than 100% of DCI-P3 (standard for digital cinemas). Moreover, a wide viewing angle was able to be achieved. A difference between chromaticity observed in front of the display apparatus and chromaticity observed at a point in the oblique direction with respect to the display apparatus was able to be reduced. The current efficiency for performing white display at a luminance of 5000 cd/m² was 41.1 cd/A; meanwhile, the current efficiency for performing white display at a luminance of 5000 cd/m² was 11.5 cd/A in the case of using a conventional display apparatus including a white organic EL device and a color filter. The fabricated display apparatus exhibited extremely high current efficiency.

### <Display Apparatus 700>

The fabricated display apparatus 700, which is described in this example, includes the substrate 510, the functional layer 520, and the pixel set 703 (see FIG. 27A). Note that the display apparatus 700 includes a plurality of pixel sets 703 arranged longitudinally and horizontally at a 7.92 μm pitch to achieve a resolution of 3207 ppi.

The pixel set 703 includes the light-emitting devices A, B, and C (see FIGS. 27B and 27C).

The functional layer 520 is positioned between the substrate 510 and the light-emitting device A. The functional layer 520 includes the insulating layer 521, and the light-emitting devices A, B, and C are formed over the insulating layer 521.

The display apparatus 700 includes the conductive film 552 and the layers 105, 529_2, 529_1, SCRA12, SCRB12, SCRC12, and 528.

The conductive film 552 overlaps with the insulating layer 521 and includes the electrodes 552A, 552B, and 552C. The layer 105 is positioned between the conductive film 552 and the insulating layer 521 and includes the layers 105A, 105B, and 105C.

The layer 529_2 is positioned between the conductive film 552 and the insulating layer 521. The gap 551AB is positioned between the electrode 551B and the electrode 551A and the layer 529_2 overlaps with the gap 551AB. The layer 529_2 has a plurality of openings; one opening overlaps with the electrode 551A, another opening overlaps with the electrode 551B, and another opening overlaps with the electrode 551C.

The layer 529_1 is positioned between the layer 529_2 and the insulating layer 521. The layer 529_1 includes regions in contact with the layer 104A, the layer 104B, and the layer 104C. The layer 529_1 includes regions in contact with the unit 103A, the unit 103B, and the unit 103C. The layer 529_1 includes a region in contact with an intermediate layer in which the layers 106A1, 106A2, and 106A3 are stacked. The layer 529_1 includes a region in contact with an intermediate layer in which the layers 106B1, 106B2, and 106B3 are stacked. The layer 529_1 includes a region in contact with an intermediate layer in which the layers 106C1, 106C2, and 106C3 are stacked. The layer 529_1 includes regions in contact with the unit 103A2, the unit 103B2, and the unit 103C2.

The layer 529_1 has openings; one opening overlaps with the electrode 551A, another opening overlaps with the electrode 551B, and another opening overlaps with the electrode 551C. The layer 529_1 overlaps with the gap 551AB.

The layer SCRA12 is positioned between the layer 529_1 and the insulating layer 521. The layer SCRA12 includes a region in contact with the unit 103A2 and has an opening overlapping with the electrode 551A.

The layer SCRB12 is positioned between the layer 529_1 and the insulating layer 521. The layer SCRB12 includes a region in contact with the unit 103B2 and has an opening overlapping with the electrode 551B.

The layer SCRC12 is positioned between the layer 529_1 and the insulating layer 521. The layer SCRC12 includes a region in contact with the unit 103C2 and has an opening overlapping with the electrode 551C.

The layer 528 is positioned between the conductive film 552 and the insulating layer 521. The layer 528 overlaps with the gap 551AB and is in contact with the insulating layer 521. The layer 528 has a plurality of openings; one opening overlaps with the electrode 551A, another opening overlaps with the electrode 551B, and another opening overlaps with the electrode 551C. The layer 528 covers the end portion of the electrode 551A, an end portion of the electrode 551B, and an end portion of the electrode 551C and overlaps with the gap 551AB. The layer 528 includes a region in contact with the layer 529_1.

### <<Structure of Light-Emitting Device A>>

The light-emitting device A includes a reflective film REFA, the electrode 551A, the electrode 552A, the unit 103A, the unit 103A2, the layer 106A1, the layer 106A2, the layer 106A3, the layer 104A, the layer 105A, and a layer CAP (see FIG. 27C). The light-emitting device A has a rectangular shape with a size of 6.92 μm×2.73 μm (see FIG. 27B).

The light-emitting device A includes the reflective film REFA, the unit 103A, the unit 103A2, the intermediate layer 106A, the layer 104A, the layer 105A, and the layer CAP. The reflective film REFA includes a layer REFA1, a layer REFA2, and a layer REFA3 (see FIG. 28A). The unit 103A includes a layer 112A11, a layer 112A12, a layer 113A11, and a layer 111A. The unit 103A2 includes a layer 112A21, a layer 112A22, a layer 113A21, a layer 113A22, and a layer 111A2. The intermediate layer 106A includes the layer 106A1, the layer 106A2, and the layer 106A3.

Table 2 shows the specific structure of the fabricated light-emitting device A, which is described in this example. Structural formulae of materials used in the light-emitting devices described in this example are shown below. Note that in the tables in this specification, subscript and superscript characters are written in ordinary size for convenience. For example, a subscript character in an abbreviation and a superscript character in a unit are written in ordinary size in the tables. The corresponding description in the specification gives an accurate reading of such notations in the tables.

TABLE 2

| | | | Compo- | |
|---|---|---|---|---|
| | Reference | | sition | Thickness/ |
| Components | numerals | Materials | ratio | nm |
| Layer | CAP | ITO | | 70 |
| Electrode | 552A | Ag:Mg | 1:0.1 | 25 |
| Layer | 105A | LiF:Yb | 1:0.5 | 1.5 |
| Layer | 113A22 | mPPhen2P | | 15 |
| Layer | 113A21 | 2mPCCzPDBq | | 10 |
| Layer | 111A2 | αN-βNP Anth:3,10PCA2Nbf(IV)-02 | 1:0.015 | 25 |
| Layer | 112A22 | DBfBB1TP | | 10 |
| Layer | 112A21 | PCBBiF | | 30 |
| Layer | 106A1 | PCBBiF:OCHD-003 | 1:0.15 | 10 |
| Layer | 106A3 | CuPc | | 2 |
| Layer | 106A2 | 11mDBtBPPnfpr:2′7′tBu-2hppSF | 1:1 | 5 |
| Layer | 113A11 | DACT-II | | 10 |
| Layer | 111A | αN-βNP Anth:3,10PCA2Nbf(IV)-02 | 1:0.015 | 25 |
| Layer | 112X12 | DBfBB1TP | | 10 |
| Layer | 112A11 | PCBBiF | | 12.5 |
| Layer | 104A | PCBBiF:OCHD-003 | 1:0.03 | 10 |
| Electrode | 551A | ITSO | | 10 |
| Layer | REFA3 | Ti | | 6 |
| Layer | REFA2 | Al | | 70 |
| Layer | REFA1 | Ti | | 50 |

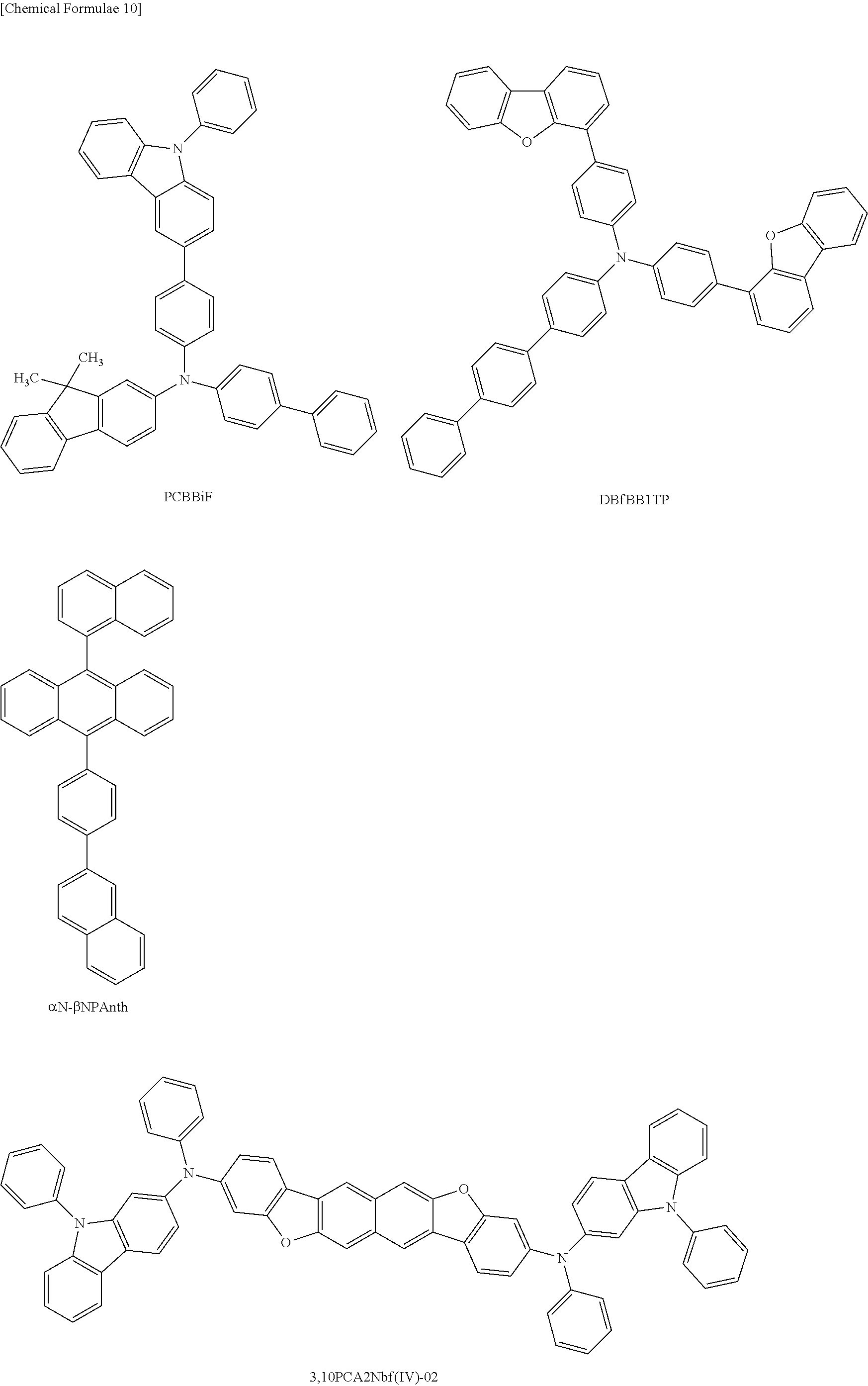

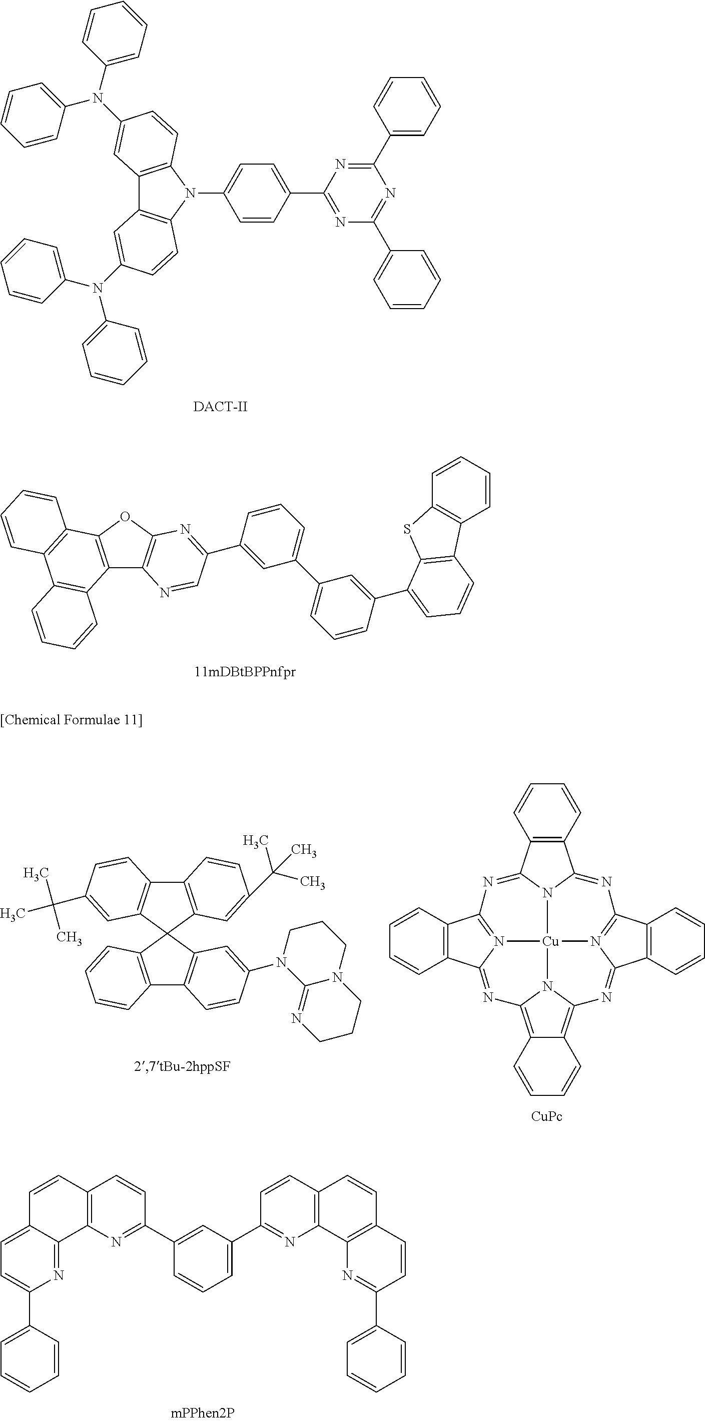

In this example, the light-emitting devices were fabricated using titanium (Ti), aluminum (Al), indium oxide-tin oxide containing silicon or silicon oxide (abbreviation: ITSO), N-(biphenyl-4-yl)-N-[4-(9-phenyl-9H-carbazol-3-yl)phenyl]-9,9-dimethyl-9H-fluoren-2-amine (abbreviation: PCBBiF), an electron-accepting material (OCHD-003), N,N-bis[4-(dibenzofuran-4-yl)phenyl]-4-amino-p-terphenyl (abbreviation: DBfBB1TP), 9-(1-naphthyl)-10-[4-(2-naphthyl)phenyl]anthracene (abbreviation: αN-βNPAnth), N,N′-diphenyl-N,N-bis(9-phenyl-9H-carbazol-2-yl)naphtho[2,3-b;6,7-b′]bisbenzofuran-3,10-diamine (abbreviation: 3,10PCA2Nbf(IV)-02), 3,6-bis(diphenylamino)-9-[4-(4,6-diphenyl-1,3,5-triazin-2-yl)phenyl]-9H-carbazole (abbreviation: DACT-II), 11-[(3′-dibenzothiophen-4-yl)biphenyl-3-yl]phenanthro[9′,10′:4,5]furo[2,3-b]pyrazine (abbreviation: 11mDBtBPPnfpr), 1-(2′,7′-di-tert-butyl-9,9′-spirobi[9H-fluoren]-2-yl)-1,3,4,6,7,8-hexahydro-2H-pyrimido[1,2-a]pyrimidine (abbreviation: 2′7′tBu-2hppSF), copper(II) phthalocyanine (abbreviation: CuPc), 2-{3-[3-(N-phenyl-9H-carbazol-3-yl)-9H-carbazol-9-yl]phenyl}dibenzo[f,h]quinoxaline (abbreviation: 2mPCCzPDBq), 2,2′-(1,3-phenylene)bis(9-phenyl-1,10-phenanthroline) (abbreviation: mPPhen2P), lithium fluoride (abbreviation: LiF), ytterbium (Yb), silver (Ag), magnesium (Mg), and indium oxide-tin oxide (abbreviation: ITO). Note that OCHD-003 contains fluorine, and has a molecular weight of 672. In addition, 3,10PCA2Nbf(IV)-02 is a fluorescent material that emits blue light.

### <<Operation Characteristics of Light-Emitting Device A>>

When supplied with electric power, the light-emitting device A emitted blue light. Operation characteristics of the light-emitting device A were measured at room temperature (see FIG. 30 to FIG. 35). Note that luminance, CIE chromaticity, and emission spectra were measured with a spectroradiometer (SR-ULIR manufactured by TOPCON TECHNOHOUSE CORPORATION). The light-emitting devices A are arranged longitudinally and horizontally at a 7.92 μm pitch to achieve a resolution of 3207 ppi. Note that the aperture ratio of the light-emitting device A is 21.4%.

Table 3 shows main initial characteristics of the fabricated light-emitting device emitting light at a luminance of approximately 1000 cd/m². Table 3 also shows the characteristics of other light-emitting devices each having a structure described later.

TABLE 3

| | | | Current | | | Current | |
|---|---|---|---|---|---|---|---|
| | Voltage | Current | density | Chromaticity | Chromaticity | efficiency | BI |
| | (V) | (mA) | (mA/cm2) | x | y | (cd/A) | (cd/A/y) |
| Light-emitting device A | 11.8 | 0.26 | 21.9 | 0.14 | 0.05 | 4.8 | 90.1 |
| Light-emitting device B | 8.8 | 0.01 | 1.1 | 0.25 | 0.72 | 90.1 | — |
| Light-emitting device C | 9.6 | 0.03 | 2.3 | 0.69 | 0.31 | 42.9 | — |
| Comparative device A | 11.2 | 0.30 | 25.7 | 0.14 | 0.06 | 4.2 | 67.7 |
| Comparative device B | 8.2 | 0.01 | 1.2 | 0.28 | 0.70 | 74.0 | — |
| Comparative device C | 9.2 | 0.03 | 2.9 | 0.69 | 0.31 | 33.2 | — |

The light-emitting device A was found to exhibit favorable characteristics. For example, the light-emitting device A functioned as a tandem light-emitting device that emits blue light and exhibited high current efficiency. Moreover, as indicated by the chromaticities, the emission color was deep blue. The tandem light-emitting device having the structure of one embodiment of the present invention was found to be highly resistant to an atmospheric component and a chemical solution, to which the light-emitting device is exposed in the manufacturing process. In the light-emitting device A, current that did not contribute to light emission was able to be suppressed as compared with that in a comparative device A. Furthermore, the light-emitting device A exhibited significantly higher current efficiency than the comparative device A particularly in a high-luminance region.

### <<Structure of Light-Emitting Device B>>

The light-emitting device B includes a reflective film REFB, the electrode 551B, the electrode 552B, the unit 103B, the unit 103B2, the layer 106B1, the layer 106B2, the layer 106B3, the layer 104B, the layer 105B, and the layer CAP (see FIG. 27C). The light-emitting device B has a rectangular shape with a size of 2.96 μm×3.19 μm (see FIG. 27B).

The light-emitting device B includes the reflective film REFB, the unit 103B, the unit 103B2, the intermediate layer 106B, the layer 104B, the layer 105B, and the layer CAP (see FIG. 28B). The reflective film REFB includes a layer REFB1, a layer REFB2, and a layer REFB3. The unit 103B includes a layer 112B11, a layer 113B11, and a layer 111B. The unit 103B2 includes a layer 112B21, a layer 113B21, a layer 113B22, and a layer 111B2. The intermediate layer 106B includes the layer 106B1, the layer 106B2, and the layer 106B3.

Table 4 shows the specific structure of the fabricated light-emitting device B, which is described in this example. Structural formulae of materials used in the light-emitting devices described in this example are shown below.

TABLE 4

| | Reference | | Composition | Thickness/ |
|---|---|---|---|---|
| Components | numerals | Materials | ratio | nm |
| Layer | CAP | ITO | | 70 |
| Electrode | 552B | Ag:Mg | 1:0.1 | 25 |
| Layer | 105B | LiF:Yb | 1:0.5 | 1.5 |
| Layer | 113B22 | mPPhen2P | | 15 |
| Layer | 113B21 | 2mPCCzPDBq | | 10 |
| Layer | 111B2 | 8mpTP-4mDBtPBfpm:βNCCP:Ir(5mppy-d3)2(mbfpypy-d3) | 0.6:0.4:0.1 | 40 |
| Layer | 112B21 | PCBBiF | | 55 |
| Layer | 106B1 | PCBBiF:OCHD-003 | 1:0.15 | 10 |
| Layer | 106B3 | CuPc | | 2 |
| Layer | 106B2 | 11mDBtBPPnfpr:2′7′tBu-2hppSF | 1:1 | 5 |
| Layer | 113B11 | DACT-II | | 10 |
| Layer | 111B | 8mpTP-4mDBtPBfpm:βNCCP:Ir(5mppy-d3)2(mbfpypy-d3) | 0.6:0.4:0.1 | 40 |
| Layer | 112B11 | PCBBiF | | 35 |
| Layer | 104B | PCBBiF:OCHD-003 | 1:0.03 | 10 |
| Electrode | 551B | ITSO | | 10 |
| Layer | REFB3 | Ti | | 6 |
| Layer | REFB2 | Al | | 70 |
| Layer | REFB1 | Ti | | 50 |

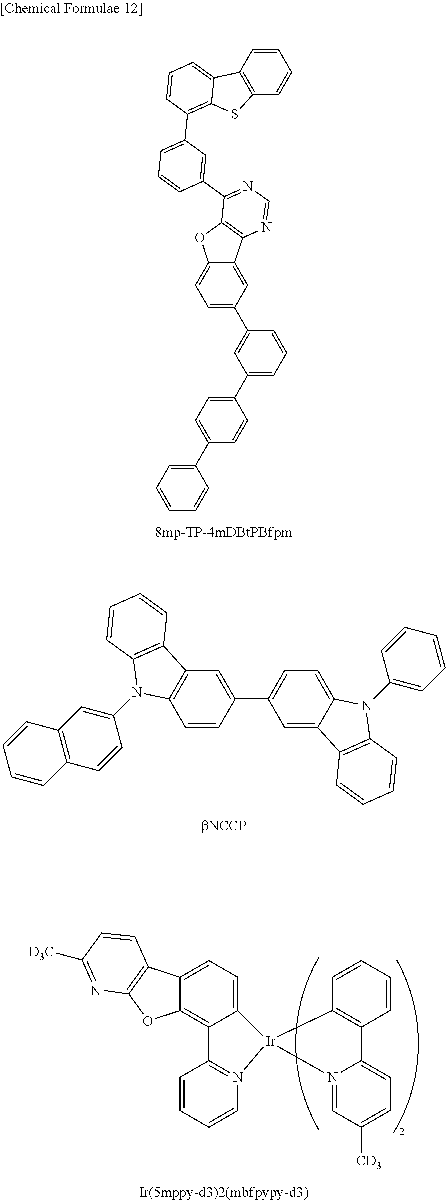

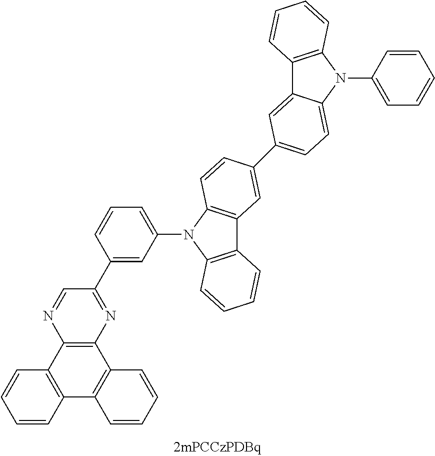 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1]

In this example, the light-emitting devices were fabricated using 9-(2-naphthyl)-9′-phenyl-9H,9′H-3,3′-bicarbazole (abbreviation: BNCCP) and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)).

### <<Operation Characteristics of Light-Emitting Device B>>

When supplied with electric power, the light-emitting device B emitted green light. Operation characteristics of the light-emitting device B were measured at room temperature (see FIG. 36 to FIG. 40).

Table 3 shows the main initial characteristics of the fabricated light-emitting device emitting light at a luminance of approximately 1000 cd/m². The light-emitting devices B are arranged longitudinally and horizontally at a 7.92 μm pitch to achieve a resolution of 3207 ppi. The aperture ratio of the light-emitting device B is 10.90%.

The light-emitting device B was found to exhibit favorable characteristics. For example, the light-emitting device B functioned as a tandem light-emitting device that emits green light and exhibited high current efficiency. Moreover, as indicated by the chromaticities, the emission color was bright green. The tandem light-emitting device having the structure of one embodiment of the present invention was found to be highly resistant to an atmospheric component and a chemical solution, to which the light-emitting device is exposed in the manufacturing process. In the light-emitting device B, current that did not contribute to light emission was able to be suppressed as compared with that in a comparative device B. For example, the light-emitting device B exhibited higher current efficiency than the comparative device B in a high-luminance region.

### <<Structure of Light-Emitting Device C>>

The light-emitting device C includes a reflective film REFC, the electrode 551C, the electrode 552C, the unit 103C, the unit 103C2, the layer 106C1, the layer 106C2, the layer 106C3, the layer 104C, the layer 105C, and the layer CAP (see FIG. 27C). The light-emitting device C has a rectangular shape with a size of 2.96 μm×3.19 μm (see FIG. 27B).

The light-emitting device C includes the reflective film REFC, the unit 103C, the unit 103C2, the intermediate layer 106C, the layer 104C, the layer 105C, and the layer CAP (see FIG. 28C). The reflective film REFC includes a layer REFC1, a layer REFC2, and a layer REFC3. The unit 103C includes a layer 112C11, a layer 113C11, and a layer 111C. The unit 103C2 includes a layer 112C21, a layer 113C21, a layer 113C22, and a layer 111C2. The intermediate layer 106C includes the layer 106C1, the layer 106C2, and the layer 106C3.

Table 5 shows the specific structure of the fabricated light-emitting device C, which is described in this example. Structural formulae of materials used in the light-emitting devices described in this example are shown below.

TABLE 5

| | Reference | | Composition | Thickness/ |
|---|---|---|---|---|
| Components | numerals | Materials | ratio | nm |
| Layer | CAP | ITO | | 70 |
| Electrode | 552C | Ag:Mg | 1:0.1 | 25 |
| Layer | 105C | LiF:Yb | 1:0.5 | 1.5 |
| Layer | 113C22 | mPPhen2P | | 25 |
| Layer | 113C21 | 2mPCCzPDBq | | 20 |
| Layer | 111C2 | 11mDBtBPPnfpr:PCBBiF:OCPG-006 | 0.7:0.3:0.05 | 40 |
| Layer | 112C2 | PCBBiF | | 65 |
| Layer | 106C1 | PCBBiF:OCHD-003 | 1:0.15 | 10 |
| Layer | 106C3 | CuPc | | 2 |
| Layer | 106C2 | 11mDBtBPPnfpr:2′7′tBu-2hppSF | 1:1 | 5 |
| Layer | 113C11 | DACT-II | | 10 |
| Layer | 111C | 11mDBtBPPnfpr:PCBBiF:OCPG-006 | 0.7:0.3:0.05 | 40 |
| Layer | 112C11 | PCBBiF | | 60 |
| Layer | 104C | PCBBiF:OCHD-003 | 1:0.03 | 10 |
| Electrode | 551C | ITSO | | 10 |
| Layer | REFC3 | Ti | | 6 |
| Layer | REFC2 | Al | | 70 |
| Layer | REFC1 | Ti | | 50 |

In this example, the light-emitting devices were fabricated using a phosphorescent dopant (OCPG-006). Note that OCPG-006 is a phosphorescent material that emits red light.

### <<Operation Characteristics of Light-Emitting Device C>>

When supplied with electric power, the light-emitting device C emitted red light. Operation characteristics of the light-emitting device C were measured at room temperature (see FIG. 41 to FIG. 45).

Table 3 shows the main initial characteristics of the fabricated light-emitting device emitting light at a luminance of approximately 1000 cd/m². The light-emitting devices C are arranged longitudinally and horizontally at a 7.92 μm pitch to achieve a resolution of 3207 ppi. The aperture ratio of the light-emitting device C is 10.60%.

The light-emitting device C was found to exhibit favorable characteristics. For example, the light-emitting device C functioned as a tandem light-emitting device that emits red light and exhibited high current efficiency. Moreover, as indicated by the chromaticities, the emission color was bright red. The tandem light-emitting device having the structure of one embodiment of the present invention was found to be highly resistant to an atmospheric component and a chemical solution, to which the light-emitting device is exposed in the manufacturing process. In the light-emitting device C, current that did not contribute to light emission was able to be suppressed as compared with that in a comparative device C. Furthermore, the light-emitting device C exhibited significantly higher current efficiency than the comparative device C particularly in a high-luminance region.

### <Comparative Apparatus 700-REF>

A fabricated comparative apparatus 700-REF, which is described in this example, is different from the display apparatus 700 in not including the layer 528 (see FIG. 29). Different portions are described in detail here, and the above description is referred to for portions where a method similar to the above was employed.

The comparative apparatus 700-REF includes the electrodes 551A, 551B, and 551C. The electrode 551B is adjacent to the electrode 551A and the gap 551AB is positioned between the electrode 551B and the electrode 551A.

The top and side surfaces of the electrode 551A are in contact with the layer 104A, top and side surfaces of the electrode 551B are in contact with the layer 104B, and top and side surfaces of the electrode 551C are in contact with the layer 104C.

The comparative apparatus 700-REF includes the layer 529_1. The layer 529_1 is in contact with the insulating layer 521 in the gap 551AB.

### <Method for Fabricating Display Apparatus 700>

The display apparatus 700 described in this example was fabricated by a method including the following steps (see FIG. 27C).

In Step 1 to Step 3, the reflective films REFA, REFB, and REFC, the electrodes 551A, 551B, and 551C, and the layer 528 are formed (see FIG. 46).

In Step 4 to Step 16, films to be the layers 104A, 106A2, 106A3, and 106A1 and the units 103A and 103A2 later are stacked, and in Step 17-1 and Step 17-2, films to be the layer SCRA12 and a layer SCRA11 later are stacked (see FIG. 47). Step 4 to Step 16 include a step common to the fabrication methods of the light-emitting devices A, B, and C.

In Step 17-3, Step 17-4, and Step 18-1 to Step 18-4, the stacked-layer films formed in Step 4 to Step 16, Step 17-1, and Step 17-2 are microfabricated by a photolithography method into predetermined shapes (see FIG. 49). Step 17-3, Step 17-4, and Step 18-1 to Step 18-4 include a step common to the fabrication methods of the light-emitting devices A, B, and C (see FIG. 51 and FIG. 52).

In Step 19 to Step 21, the layer 105, the conductive film 552, and the layer CAP are formed over the units 103A2, 103B2, and 103C2 (see FIG. 56).

### <<Method for Fabricating Light-Emitting Device A>>

The light-emitting device A described in this example was fabricated using a method including the following steps.

### [Step 1]

In Step 1, the reflective films REFA, REFB, and REFC were formed over the insulating layer 521 (see FIG. 46). Specifically, a 50-nm-thick film containing Ti, a 70-nm-thick film containing Al, and a 6-nm-thick film containing Ti were stacked by a sputtering method, and the stacked-layer film was processed into a predetermined shape by a photolithography method.

### [Step 2]

In Step 2, the electrodes 551A, 551B, and 551C were formed over the reflective films REFA, REFB, and REFC, respectively. Specifically, a conductive film was formed by a sputtering method using ITSO as a target and then processed into a predetermined shape by a photolithography method. The electrode 551B is adjacent to the electrode 551A and the gap 551AB is positioned between the electrode 551B and the electrode 551A. The electrodes 551A, 551B, and 551C each contain ITSO and have a thickness of 10 nm.

### [Step 3]

In Step 3, the layer 528 having a plurality of openings was formed.

Specifically, an insulating film to be the layer 528 later was formed by a CVD method and then processed into a predetermined shape by a photolithography method. Note that the layer 528 has an opening overlapping with the electrode 551A, an opening overlapping with the electrode 551B, and an opening overlapping with the electrode 551C. The layer 528 covers the end portions of the electrodes 551A, 551B, and 551C and overlaps with the gap 551AB. The layer 528 contains oxygen and silicon and has a thickness of 100 nm.

Then, a workpiece provided with a plurality of electrodes was washed with water and then transferred into a vacuum evaporation apparatus in which the pressure was reduced to approximately 10-4 Pa, and vacuum baking was performed at 170° C. for 60 minutes in a heating chamber of the vacuum evaporation apparatus. Then, the workpiece was cooled down for approximately 30 minutes.

### [Step 4]

In Step 4, a film 104a to be the layer 104A later was formed over the electrode 551A (see FIG. 47). Specifically, materials of the layer 104A were co-deposited by a resistance-heating method. The layer 104A contains PCBBiF and OCHD-003 at 1:0.03 in a weight ratio and has a thickness of 10 nm.

### [Step 5]

In Step 5 to Step 8, a stacked-layer film 103a was formed. First, in Step 5, a film to be the layer 112A11 later was formed over the film 104a. Specifically, a material of the layer 112A11 was deposited by a resistance-heating method. The layer 112A11 contains PCBBiF and has a thickness of 12.5 nm.

### [Step 6]

In Step 6, a film to be the layer 112A12 later was formed over the film to be the layer 112A11 later. Specifically, a material of the layer 112A12 was deposited by a resistance-heating method. The layer 112A12 contains DBfBB1TP and has a thickness of 10 nm.

### [Step 7]

In Step 7, a film to be the layer 111A later was formed over the film to be the layer 112A12 later. Specifically, materials of the layer 111A were co-deposited by a resistance-heating method. The layer 111A contains αN-βNPAnth and 3,10PCA2Nbf(IV)-02 at 1:0.015 in a weight ratio and has a thickness of 25 nm.

### [Step 8]

In Step 8, a film to be the layer 113A11 later was formed over the film to be the layer 111A later. Specifically, a material of the layer 113A11 was deposited by a resistance-heating method. The layer 113A11 contains DACT-II and has a thickness of nm.

### [Step 9]

In Step 9, a film 106a2 to be the layer 106A2 later was formed over the film to be the layer 113A11 later. Specifically, materials of the layer 106A2 were co-deposited by a resistance-heating method. The layer 106A2 contains 11mDBtBPPnfpr and 2′7′tBu-2hppSF at 1:1 in a weight ratio and has a thickness of 5 nm.

### [Step 10]

In Step 10, a film 106a3 to be the layer 106A3 later was formed over the film 106a2. Specifically, a material of the layer 106A3 was deposited by a resistance-heating method. The layer 106A3 contains CuPc and has a thickness of 2 nm.

### [Step 11]

In Step 11, a film 106al to be the layer 106A1 later was formed over the film 106a3. Specifically, materials of the layer 106A1 were co-deposited by a resistance-heating method. The layer 106A1 contains PCBBiF and OCHD-003 at 1:0.15 in a weight ratio and has a thickness of 10 nm.

### [Step 12]

In Step 12 to Step 16, a stacked-layer film 103a2 was formed. First, in Step 12, a film to be the layer 112A21 later was formed over the film 106al. Specifically, a material of the layer 112A21 was deposited by a resistance-heating method. The layer 112A21 contains PCBBiF and has a thickness of 30 nm.

### [Step 13]

In Step 13, a film to be the layer 112A22 later was formed over the film to be the layer 112A21 later. Specifically, a material of the layer 112A22 was deposited by a resistance-heating method. The layer 112A22 contains DBfBB1TP and has a thickness of 10 nm.

### [Step 14]

In Step 14, a film to be the layer 111A2 later was formed over the film to be the layer 112A22 later. Specifically, materials of the layer 111A2 were co-deposited by a resistance-heating method. The layer 111A2 contains αN-βNPAnth and 3,10PCA2Nbf(IV)-02 at 1:0.015 in a weight ratio and has a thickness of 25 nm.

### [Step 15]

In Step 15, a film to be the layer 113A21 later was formed over the film to be the layer 111A2 later. Specifically, a material of the layer 113A21 was deposited by a resistance-heating method. The layer 113A21 contains 2mPCCzPDBq and has a thickness of 10 nm.

### [Step 16]

In Step 16, a film to be the layer 113A22 later was formed over the film to be the layer 113A21 later. Specifically, a material of the layer 113A22 was deposited by a resistance-heating method. The layer 113A22 contains mPPhen2P and has a thickness of 15 nm.

### [Step 17-1]

In Step 17-1, a film SCRa12 to be the layer SCRA12 later was formed over the film to be the layer 113A22 later. Specifically, the workpiece provided with components up to the layer 113A22 was taken out from a vacuum evaporation apparatus and then transferred into an ALD deposition apparatus, and a material was deposited by an ALD method. Note that the film SCRa12 contains aluminum oxide (abbreviation: AlOₓ) and has a thickness of 30 nm.

### [Step 17-2]

In Step 17-2, a film SCRa11 to be the layer SCRA11 later was formed over the film SCRa12. Specifically, the workpiece provided with components up to the film SCRa12 was taken out from the ALD deposition apparatus and then transferred into a sputtering apparatus, and a material was deposited by a sputtering method. Note that the film SCRa11 contains tungsten and has a thickness of 50 nm.

### [Step 17-3]

In Step 17-3, the film SCRa11 was processed into a predetermined shape to form the layer SCRA11. Specifically, the workpiece was taken out from the sputtering apparatus and a resist RES was formed over the film SCRa11. Then, an unnecessary portion was etched by an etching method using the resist RES so that a portion overlapping with the electrode 551A was left (see FIG. 48).

### [Step 17-4]

In Step 17-4, the layers SCRA12, 106A1, 106A3, 106A2, and 104A and the units 103A and 103A2 were formed (see FIG. 49). Specifically, unnecessary portions were etched so that portions overlapping with the electrode 551A were left. Note that an oxygen-containing gas can be used as an etching gas. The layer SCRA11 functions as a hard mask.

After Step 17-1 to Step 17-4, the electrode 551A, the layer 113A22, and the components therebetween in the light-emitting device A are formed on the workpiece and the layer SCRA12 and the layer SCRA11 are formed over the layer 113A22. Alternatively, a plurality of predetermined electrodes can be exposed, for example. Note that the workpiece provided with the electrode 551A, the layer 113A22, and the components therebetween in the light-emitting device A can be referred to as work in process.

In the case where fabrication of the light-emitting device A is continued using the work in process provided with the electrode 551A, the layer 113A22, and the components therebetween, the process proceeds to Step 18-1 after Step 17-4.

In the case where the electrode 551B was exposed on the work in process, the light-emitting device B was fabricated over the electrode 551B. Similarly, in the case where the electrode 551C was exposed on the work in process, the light-emitting device C was fabricated over the electrode 551C. In that case, after Step 17-4, the workpiece was transferred into a vacuum evaporation apparatus in which the pressure was reduced to approximately 10-4 Pa, the process proceeded to Step 4, and then the light-emitting device B or the light-emitting device C was fabricated.

### [Step 18-1]

In Step 18-1, the layer SCRA11, a layer SCRB11, and a layer SCRC11 were removed (see FIG. 53). Specifically, etching was performed by a dry etching method.

### [Step 18-2]

In Step 18-2, an insulating film to be the layer 529_1 later was formed. Specifically, the layer 529_1 was formed by an ALD method to cover a top surface of the layer SCRA12, side surfaces of the units 103A and 103A2, and side surfaces of the layers 106A1, 106A3, 106A2, and 104A. Note that the layer 529_1 contains AlOₓ and has a thickness of 10 nm.

### [Step 18-3]

In Step 18-3, the layer 529_2 was formed into a predetermined shape (see FIG. 54). Specifically, a photosensitive resin was used. A portion between the electrode 551A and the electrode 551B adjacent to the electrode 551A was left, and a portion overlapping with the electrode 551A, a portion overlapping with the electrode 551B, and a portion overlapping with the electrode 551C were removed to form the opening 529_2A, the opening 529_2B, and the opening 529_2C, respectively.

### [Step 18-4]

In Step 18-4, the layers SCRA12, SCRB12, SCRC12, and 529_1 were formed into predetermined shapes (FIG. 55). Specifically, an opening overlapping with the opening 529_2A, an opening overlapping with the opening 529_2B, and an opening overlapping with the opening 529_2C were formed in the layer 529_2 with the layer 529_2 used as a resist. Moreover, an opening overlapping with the opening 529_2A, an opening overlapping with the opening 529_2B, and an opening overlapping with the opening 529_2C were formed in the layer SCRA12, the layer SCRB12, and the layer SCRC12, respectively. A wet etching method can be employed, for example. Specifically, an aqueous solution containing hydrofluoric acid (HF) or an aqueous solution containing tetramethyl ammonium hydroxide (abbreviation: TMAH) can be used as an etchant. Accordingly, the units 103A2, 103B2, and 103C2 are exposed in the openings. In other words, the layers 113A22, 113B22, and 113C22 are exposed.

Then, the workpiece was transferred into a vacuum evaporation apparatus in which the pressure was reduced to approximately 10-4 Pa, and vacuum baking was performed at 70° ° C. for 90 minutes in a heating chamber of the vacuum evaporation apparatus.

### [Step 19]

In Step 19, the layer 105 was formed over the layer 113A22 (see FIG. 56). Specifically, materials of the layer 105 were co-deposited by a resistance-heating method. Note that the layer 105 includes the layers 105A, 105B, and 105C. The layer 105 contains LiF and Yb at 1:0.5 in a volume ratio and has a thickness of 1.5 nm.

### [Step 20]

In Step 20, the conductive film 552 was formed over the layer 105. Specifically, materials of the conductive film 552 were co-deposited by a resistance-heating method. The conductive film 552 includes the electrodes 552A, 552B, and 552C. The conductive film 552 contains Ag and Mg at 1:0.1 in a weight ratio and has a thickness of 25 nm.

### [Step 21]

In Step 21, the layer CAP was formed over the electrode 552A. Specifically, the layer CAP was formed by a sputtering method using ITO as a target. The layer CAP contains ITO and has a thickness of 70 nm.

### <<Method for Fabricating Light-Emitting Device B>>

The light-emitting device B described in this example was fabricated using a method including the following steps. Specifically, the light-emitting device B was fabricated by a method similar to that in Step 1 to Step 17-4 of the fabrication method of the light-emitting device A. Note that the reflective film REFB and the electrode 551B of the light-emitting device B were formed in Step 1 to Step 3 of the fabrication method of the light-emitting device A.

The fabrication method of the light-emitting device B is different from that of the light-emitting device A in that, in Step 4, the work in process of the light-emitting device A is used as a workpiece (see FIG. 49). Specifically, the workpiece is provided with the electrodes 551A and 551B, and the layers 104A, 106A2, 106A3, 106A1, SCRA12, and SCRA11 and the units 103A and 103A2 are formed over the electrode 551A.

The fabrication method of the light-emitting device B is different from that of the light-emitting device A in that the thickness of the film was 35 nm in Step 5; Step 6 was omitted; the material and the thickness of the film in Step 7 were different from those in the fabrication method of the light-emitting device A; the thickness of the film was 55 nm in Step 12; Step 13 was omitted; and the material and the thickness of the film in Step 14 were different from those in the fabrication method of the light-emitting device A. Different portions are described in detail here, and the description of the fabrication method of the light-emitting device A is referred to for portions where a method similar to the above was employed in the description of the fabrication method of the light-emitting device B by replacing “a” and “A” in the reference numerals with “b” and “B”, respectively.

### [Step 5]

In Step 5 to Step 8, a stacked-layer film 103b was formed. First, in Step 5, a film to be the layer 112B11 later was formed over a film 104b to be the layer 104B later. Specifically, a material of the layer 112B11 was deposited by a resistance-heating method. The layer 112B11 contains PCBBiF and has a thickness of 35 nm.

### [Step 7]

In Step 7, a film to be the layer 111B later was formed over the film to be the layer 112B11 later. Specifically, materials of the layer 111B were co-deposited by a resistance-heating method. The layer 111B contains 8mpTP-4mDBtPBfpm, BNCCP, and Ir(5mppy-d₃)₂(mbfpypy-d₃) at 0.6:0.4:0.1 in a weight ratio and has a thickness of 40 nm.

### [Step 12]

In Step 12 to Step 16, a stacked-layer film 103b2 was formed. First, in Step 12, a film to be the layer 112B21 later was formed over a film 106b1. Specifically, a material of the layer 112B21 was deposited by a resistance-heating method. The layer 112B21 contains PCBBiF and has a thickness of 55 nm.

### [Step 14]

In Step 14, a film to be the layer 111B2 later was formed over the film to be the layer 112B21 later. Specifically, materials of the layer 111B2 were co-deposited by a resistance-heating method. The layer 111B2 contains 8mpTP-4mDBtPBfpm, BNCCP, and Ir(5mppy-d₃)₂(mbfpypy-d₃) at 0.6:0.4:0.1 in a weight ratio and has a thickness of 40 nm.

### [Step 17-3]

In Step 17-3, the layer SCRB11 was formed (see FIG. 50). Specifically, the workpiece provided with a film to be the layer SCRB11 later was taken out from the sputtering apparatus and an unnecessary portion was etched by an etching method using the resist RES so that a portion overlapping with the electrode 551B was left.

### [Step 17-4]

In Step 17-4, the layers SCRB12, 106B1, 106B3, 106B2, and 104B and the units 103B and 103B2 were formed (see FIG. 51). Specifically, unnecessary portions were etched so that portions overlapping with the predetermined electrode 551B were left. The layer SCRB11 functions as a hard mask.

After Step 17-1 to Step 17-4, the electrode 551B, the layer 113B22, and the components therebetween in the light-emitting device B are formed on the workpiece and the layer SCRB12 and the layer SCRB11 are formed over the layer 113B22. Alternatively, a plurality of predetermined electrodes can be exposed, for example. Note that the workpiece provided with the electrode 551B, the layer 113B22, and the components therebetween in the light-emitting device B can be referred to as work in process.

In the case where fabrication of the light-emitting device B is continued using the work in process provided with the electrode 551B, the layer 113B22, and the components therebetween, the process proceeds to Step 18-1 after Step 17-4.

In the case where the electrode 551C was exposed on the work in process, the light-emitting device C was fabricated over the electrode 551C. In that case, after Step 17-4, the workpiece was transferred into a vacuum evaporation apparatus in which the pressure was reduced to approximately 10-4 Pa, the process proceeded to Step 4, and then the light-emitting device C was fabricated.

### <<Method for Fabricating Light-Emitting Device C>>

The light-emitting device C described in this example was fabricated using a method including the following steps. Specifically, the light-emitting device C was fabricated by a method similar to that in Step 1 to Step 17-4 of the fabrication method of the light-emitting device A. Note that the reflective film REFC and the electrode 551C of the light-emitting device C were formed in Step 1 to Step 3 of the fabrication method of the light-emitting device A.

The fabrication method of the light-emitting device C is different from that of the light-emitting device A in that, in Step 4, the work in process of the light-emitting devices A and B is used as a workpiece (see FIG. 51). Specifically, the workpiece is provided with the electrodes 551A, 551B, and 551C. The layers 104A, 106A2, 106A3, 106A1, SCRA12, and SCRA11 and the units 103A and 103A2 are formed over the electrode 551A, and the layers 104B, 106B2, 106B3, 106B1, SCRB12, and SCRB11 and the units 103B and 103B2 are formed over the electrode 551B.

The fabrication method of the light-emitting device C is different from that of the light-emitting device A in that the thickness of the film was 60 nm in Step 5; Step 6 was omitted; the material and the thickness of the film in Step 7 were different from those in the fabrication method of the light-emitting device A; the thickness of the film was 65 nm in Step 12; Step 13 was omitted; the material and the thickness of the film in Step 14 were different from those in the fabrication method of the light-emitting device A; the thickness of the film was 20 nm in Step 15; and the thickness of the film was 25 nm in Step 16. Different portions are described in detail here, and the description of the fabrication method of the light-emitting device A is referred to for portions where a method similar to the above was employed in the description of the fabrication method of the light-emitting device C by replacing “a” and “A” in the reference numerals with “c” and “C”, respectively.

### [Step 5]

In Step 5 to Step 8, a stacked-layer film to be the unit 103C later was formed. First, in Step 5, a film to be the layer 112C11 later was formed over a film to be the layer 104C later. Specifically, a material of the layer 112C11 was deposited by a resistance-heating method. The layer 112C11 contains PCBBiF and has a thickness of 60 nm.

### [Step 7]

In Step 7, a film to be the layer 111C later was formed over the film to be the layer 112C11 later. Specifically, materials of the layer 111C were co-deposited by a resistance-heating method. The layer 111C contains 11mDBtBPPnfpr, PCBBiF, and OCPG-006 at 0.7:0.3:0.05 in a weight ratio and has a thickness of 40 nm.

### [Step 12]

In Step 12 to Step 16, a stacked-layer film was formed. First, in Step 12, a film to be the layer 112C21 later was formed over a film to be the layer 106C1 later. Specifically, a material of the layer 112C21 was deposited by a resistance-heating method. The layer 112C21 contains PCBBiF and has a thickness of 65 nm.

### [Step 14]

In Step 14, a film to be the layer 111C2 later was formed over the film to be the layer 112C21 later. Specifically, materials of the layer 111C2 were co-deposited by a resistance-heating method. The layer 111C2 contains 11mDBtBPPnfpr, PCBBiF, and OCPG-006 at 0.7:0.3:0.05 in a weight ratio and has a thickness of 40 nm.

### [Step 15]

In Step 15, a film to be the layer 113C21 later was formed over the film to be the layer 111C2 later. Specifically, a material of the layer 113C21 was deposited by a resistance-heating method. The layer 113C21 contains 2mPCCzPDBq and has a thickness of 20 nm.

### [Step 16]

In Step 16, a film to be the layer 113C22 later was formed over the film to be the layer 113C21 later. Specifically, a material of the layer 113C22 was deposited by a resistance-heating method. The layer 113C22 contains mPPhen2P and has a thickness of 25 nm.

### [Step 17-3]

In Step 17-3, the layer SCRC11 was formed. Specifically, the workpiece provided with a film to be the layer SCRC11 later was taken out from the sputtering apparatus and an unnecessary portion was etched by an etching method using the resist RES so that a portion overlapping with the electrode 551B was left.

### [Step 17-4]

In Step 17-4, the layers SCRC12, 106C1, 106C3, 106C2, and 104C and the units 103C and 103C2 were formed (see FIG. 52). Specifically, unnecessary portions were etched so that portions overlapping with the predetermined electrode 551C were left. The layer SCRC11 functions as a hard mask.

After Step 17-1 to Step 17-4, the electrode 551C, the layer 113C22, and the components therebetween in the light-emitting device C are formed on the workpiece and the layer SCRC12 and the layer SCRC11 are formed over the layer 113C22. Note that the workpiece provided with the electrode 551C, the layer 113C22, and the components therebetween in the light-emitting device C can be referred to as work in process.

In the case where fabrication of the light-emitting device C is continued using the work in process provided with the electrode 551C, the layer 113C22, and the components therebetween, the process proceeds to Step 18-1 after Step 17-4.

### <Method for Fabricating Comparative Apparatus>

The fabrication method of the comparative apparatus described in this example is different from that of the display apparatus 700 in that Step 3 was omitted. Here, the above description is referred to for portions where a method similar to the above was employed.

### <ESR Measurement>

The spin densities of films containing materials used for the intermediate layer 106A of the light-emitting device A, the intermediate layer 106B of the light-emitting device B, and the intermediate layer 106C of the light-emitting device C were measured by an ESR method.

Specifically, the spin density of the material used for the layer 106A2, the layer 106B2, and the layer 106C2 was measured when the material was in a film state. A measurement sample was fabricated by co-depositing 11mDBtBPPnfpr and 2′7′tBu-2hppSF at a weight ratio of 1:1 to a thickness of 50 nm over a quartz substrate.

Note that measurement of an ESR spectrum of the measurement sample using an ESR method was performed at room temperature with an ESR spectrometer E500 (manufactured by Bruker Corporation). The measurement was performed at room temperature under the conditions where the resonance frequency was 9.56 GHz, the output power was 1 mW, the modulated magnetic field was 50 mT, the modulation width was 0.5 mT, the time constant was 0.04 sec, and the sweep time was 1 min. As a result, it was found that the intensity of a signal at a g-factor of around 2.00 was not observed and the spin density was 8×10¹⁶ spins/cm³. The spin density less than or equal to 1×10¹⁷ spins/cm³ suggests that electrons are not transferred between the organic compounds contained in the film. Therefore, it can be said that 2′7′tBu-2hppSF shows no electron-donating property with respect to 11mDBtBPPnfpr.

The spin density of the material used for the layer 106A1, the layer 106B1, and the layer 106C1 was measured when the material was in a film state. A measurement sample was fabricated by co-depositing PCBBiF and OCHD-003 at a weight ratio of 1:0.1 to a thickness of 100 nm over a quartz substrate.

Note that measurement of an ESR spectrum of the measurement sample using an ESR method was performed at room temperature with an ESR spectrometer JES FA300 (manufactured by JEOL Ltd.). The measurement was performed at room temperature under the conditions where the resonance frequency was 9.18 GHZ, the output power was 1 mW, the modulated magnetic field was 50 mT, the modulation width was 0.5 mT, the time constant was 0.03 sec, and the sweep time was 1 min. As a result, it was found that a signal was observed at a g-factor of around 2.00 and the spin density is 5×10¹⁹ spins/cm³. Therefore, it can be said that OCHD-003 shows an electron-accepting property with respect to PCBBiF and a layer containing PCBBiF and OCHD-003 has a function of a charge-generation layer.

### Example 2

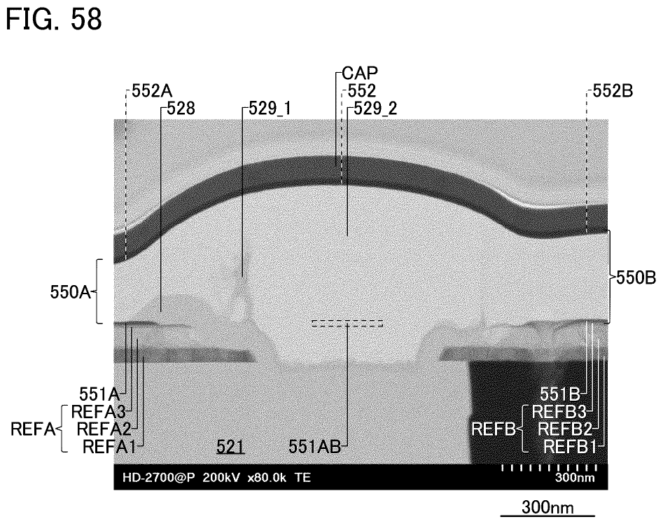

In this example, a display apparatus of one embodiment of the present invention is described with reference to FIG. 58.

FIG. 58 is a scanning transmission electron microscope (STEM) image illustrating a cross-sectional structure of the display apparatus fabricated in this example. The fabricated display apparatus includes the light-emitting devices 550A and 550B (see FIG. 58).

The light-emitting device A includes the reflective film REFA, the electrode 551A, and the electrode 552A. Note that the light-emitting device A includes a layer containing a light-emitting material between the electrode 551A and the electrode 552A. The reflective film REFA includes the layer REFA1, the layer REFA2, and the layer REFA3. The layer REFA1, the layer REFA2, and the layer REFA3 contain titanium, aluminum, and titanium, respectively.

The light-emitting device B includes the reflective film REFB, the electrode 551B, and the electrode 552B. Note that the light-emitting device B includes a layer containing a light-emitting material between the electrode 551B and the electrode 552B. The gap 551AB is positioned between the electrode 551B and the electrode 551A. The reflective film REFB includes the layer REFB1, the layer REFB2, and the layer REFB3.

The fabricated display apparatus includes the conductive film 552 and the layer CAP. The conductive film 552 includes the electrodes 552A and 552B. The conductive film 552 contains silver and magnesium. The layer CAP contains indium, tin, and oxygen.

The fabricated display apparatus includes the insulating layer 521 and the layers 528, 529_1, and 529_2.

The light-emitting devices A and B are positioned between the insulating layer 521 and the layer CAP. The insulating layer 521 has an insulating property.

The layer 528 has an opening overlapping with the electrode 551A, contains silicon, oxygen, and nitrogen, and has an insulating property.

The layer 529_2 overlaps with the gap 551AB and has an insulating property.

The layer 529_1 is positioned between the layer 528 and the layer 529_2 and in contact with the layer 529_2. The layer 529_1 contains aluminum and oxygen and has an insulating property.

### Example 3

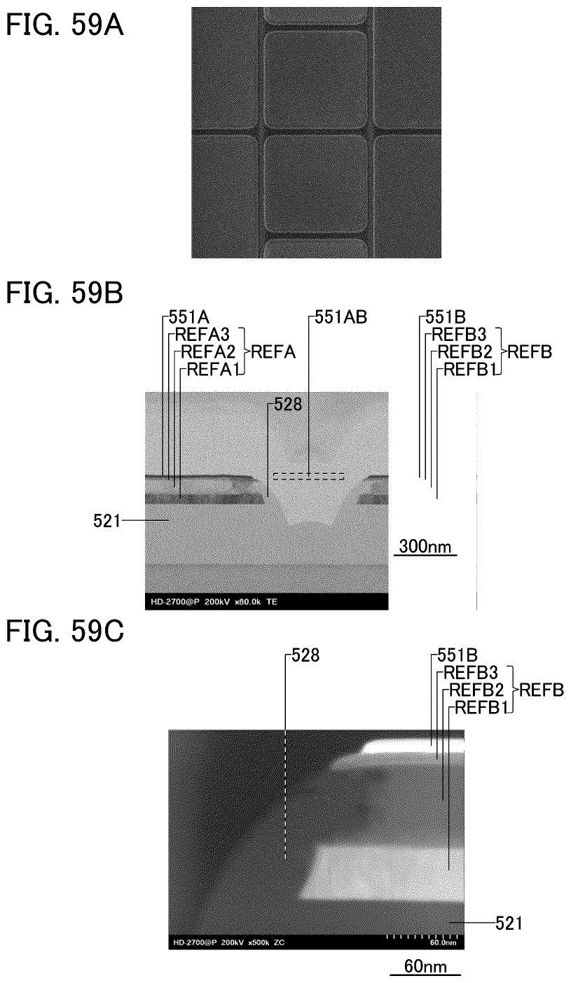

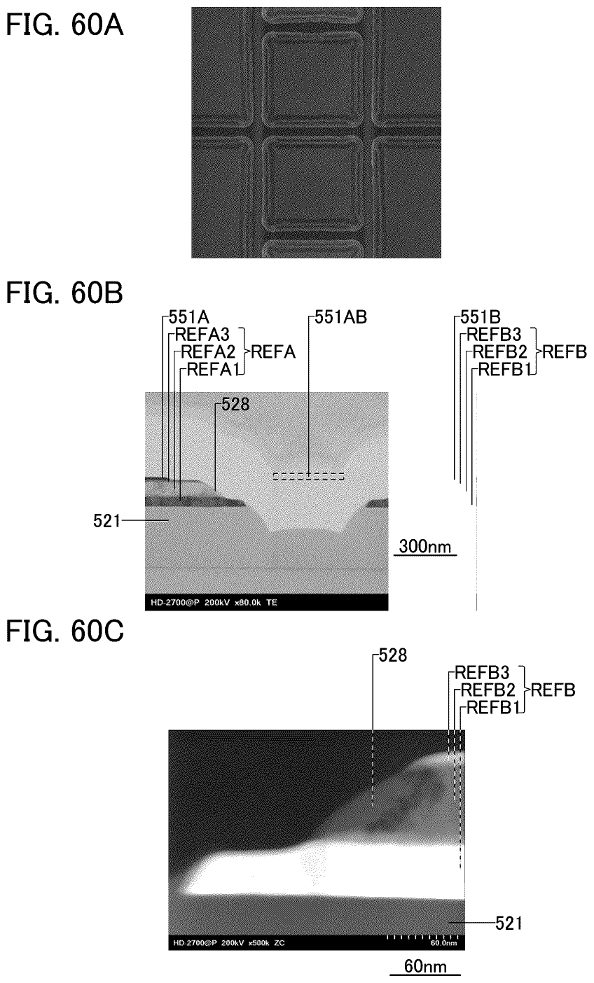

In this example, a display apparatus of one embodiment of the present invention is described with reference to FIGS. 59A to 59C and FIGS. 60A to 60C.

FIG. 59A is a plan-view scanning electron microscope (SEM) image taken from the front, which illustrates a structure of the display apparatus fabricated in this example. FIG. 59B is a STEM image illustrating a cross-sectional structure of the display apparatus fabricated in this example, and FIG. 59C is a STEM image illustrating part of FIG. 59B.

FIG. 60A is a plan-view SEM image taken from the front, which illustrates a structure of the display apparatus fabricated in this example. FIG. 60B is a STEM image illustrating a cross-sectional structure of the display apparatus fabricated in this example, and FIG. 60C is a STEM image illustrating part of FIG. 60B.

### <Structure 1 of Display Apparatus>

The structure of the fabricated display apparatus, which is described in this example, includes a plurality of electrodes. The electrodes each have a square front surface (see FIG. 59A).

The structure of the fabricated display apparatus, which is described in this example, includes the electrodes 551A and 551B, the reflective films REFA and REFB, and the insulating layer 521 (see FIG. 59B). The display apparatus further includes the layer 528.

### <<Structure of Electrode 551A>>

The electrode 551A is positioned between the insulating layer 521 and the reflective film REFA. The electrode 551A contains ITSO.

### <<Structure of Reflective Film REFA>>

The reflective film REFA includes the layer REFA1, the layer REFA2, and the layer REFA3. The layer REFA1, the layer REFA2, and the layer REFA3 contain Ti, Al, and Ti, respectively.

### <<Structure of Electrode 551B>>

The electrode 551B is adjacent to the electrode 551A and the gap 551AB is positioned between the electrode 551B and the electrode 551A. The electrode 551B is positioned between the insulating layer 521 and the reflective film REFB.

### <<Structure of Reflective Film REFB>>

The reflective film REFB includes the layer REFB1, the layer REFB2, and the layer REFB3. The layer REFB1, the layer REFB2, and the layer REFB3 contain Ti, Al, and Ti, respectively.

### <<Structure of Insulating Layer 521>>

The insulating layer 521 includes a recessed portion in a region overlapping with the gap 551AB. The insulating layer 521 contains oxygen, nitrogen, and silicon. For example, when the electrodes 551A and 551B are formed using one conductive film by a dry etching method, a recessed portion can be formed in a region overlapping with the gap 551AB. With this structure, even when the distance between the electrode 551B and the electrode 551A is short, the residue of the conductive film can be reduced. A phenomenon in which current flows between the electrode 551B and the electrode 551A through the residue of the conductive film can be suppressed. Even when the resolution is high, a phenomenon in which current flows between the electrode 551B and the electrode 551A can be suppressed.

<<Structure of layer 528>>

The layer 528 has a shape in contact with not the top surface of the electrode 551A but a side surface of the reflective film REFA (see FIG. 59B). Moreover, the layer 528 has a shape in contact with not a top surface of the electrode 551B but a side surface of the reflective film REFB (see FIG. 59C). The layer 528 has a convex surface on the gap 551AB side. This structure can suppress a phenomenon in which current flows through an unintended path between the electrode 551A and the intermediate layer.

### <Structure 2 of Display Apparatus>

The structure of the fabricated display apparatus, which is described in this example, includes a plurality of electrodes. The electrodes each have a square front surface (see FIG. 60A).

Note that in the structure of the display apparatus described with reference to FIG. 60A, four corners of the electrode are curved more gently than those in the structure of the display apparatus described with reference to FIG. 59A. Thus, the structure of the display apparatus described with reference to FIG. 60A can relieve electric field concentration at the four corners of the electrode.

The structure of the fabricated display apparatus, which is described in this example, includes the electrodes 551A and 551B, the reflective films REFA and REFB, and the insulating layer 521 (see FIG. 60B). The display apparatus further includes the layer 528.

Note that the angle between the insulating layer 521 and a side surface of an end portion of the reflective film REFB in the structure of the display apparatus described with reference to FIG. 60B is smaller than that in the structure of the display apparatus described with reference to FIG. 59B. That is, the angle between the insulating layer 521 and the side surface of the end portion of the reflective film REFB in the structure of the display apparatus described with reference to FIG. 59B is closer to 90° than that in the structure of the display apparatus described with reference to FIG. 60B.

### <Supplementary Explanation 1 of Example>

A supplementary explanation of the description of the example related to the fabricated display apparatus will be provided with use of Table 6 to Table 9.

A white color (D65, 5000 cd/m²) was displayed using the display apparatus described in Example 1. At this time, the current efficiency of the display apparatus was 41.1 cd/A.

In Table 6, the current efficiencies and chromaticities of light-emitting devices of red, green, and blue pixels are shown in R, G, and B columns, respectively. The color gamut of the fabricated display apparatus covered 100% of DCI-P3 (standard for digital cinemas).

TABLE 6

| | Display apparatus | | |
|---|---|---|---|
| | R | G | B |
| Current efficiency (cd/A) | 42.7 | 97 | 5.4 |
| Chromaticity x | 0.69 | 0.247 | 0.142 |
| Chromaticity y | 0.309 | 0.72 | 0.053 |

A white color (D65, 5000 cd/m²) was displayed using a display apparatus in which a light-emitting device that emits white light and a color filter are combined (a reference display apparatus). At this time, the current efficiency of the display apparatus was 11.5 cd/A. Note that the light-emitting device that emits white light includes a unit that emits blue light and a unit that emits yellow light.

In Table 7, the current efficiencies and chromaticities of red, green, and blue pixels are shown in R, G, and B columns, respectively. The color gamut of the fabricated display apparatus covered 81% of DCI-P3 (standard for digital cinemas).

TABLE 7

| | Reference display apparatus | | |
|---|---|---|---|
| | R | G | B |
| Current efficiency (cd/A) | 6.4 | 31.6 | 2.9 |
| Chromaticity x | 0.631 | 0.31 | 0.147 |
| Chromaticity y | 0.34 | 0.669 | 0.06 |

### <Supplementary Explanation 2 of Example>

A white color (D65, 5000 cd/m²) was displayed using the display apparatus described in Example 1. At this time, the current efficiency of the display apparatus was 39.6 cd/A. Note that the luminance was measured using an apparatus with a measurement accuracy of +2%.

In Table 8, the current efficiencies, chromaticities, voltages, and current densities of light-emitting devices of red, green, and blue pixels are shown in R, G, and B columns, respectively. The color gamut of the fabricated display apparatus covered 100% of DCI-P3 (standard for digital cinemas).

TABLE 8

| | Driving at 5000 cd/m2 | | |
|---|---|---|---|
| | R | G | B |
| Current efficiency (cd/A) | 43.3 | 95.5 | 5.3 |
| Chromaticity x | 0.69 | 0.248 | 0.141 |
| Chromaticity y | 0.31 | 0.719 | 0.053 |
| Voltage (V) | 9.2 | 10.3 | 9.8 |
| Current density (mA/cm2) | 20.5 | 27.2 | 23.9 |

A white color (D65, 15000 cd/m²) was displayed using the display apparatus described in Example 1. At this time, the current efficiency of the display apparatus was 35.9 cd/A.

In Table 9, the current efficiencies, chromaticities, voltages, and current densities of light-emitting devices of red, green, and blue pixels are shown in R, G, and B columns, respectively. The color gamut of the fabricated display apparatus covered 100% of DCI-P3 (standard for digital cinemas).

TABLE 9

| | Driving at 15000 cd/m2 | | |
|---|---|---|---|
| | R | G | B |
| Current efficiency (cd/A) | 38.4 | 86.7 | 4.9 |
| Chromaticity x | 0.69 | 0.248 | 0.141 |
| Chromaticity y | 0.31 | 0.719 | 0.052 |
| Voltage (V) | 11.7 | 12.8 | 11.4 |
| Current density (mA/cm2) | 70.7 | 89.8 | 76.8 |

This application is based on Japanese Patent Application Serial No. 2022-191812 filed with Japan Patent Office on Nov. 30, 2022, Japanese Patent Application Serial No. 2023-017616 filed with Japan Patent Office on Feb. 8, 2023, and Japanese Patent Application Serial No. 2023-060377 filed with Japan Patent Office on Apr. 3, 2023, the entire contents of which are hereby incorporated by reference.

What is claimed is:

1. A display apparatus comprising:
a first light-emitting device comprising:
a first electrode;
a second electrode;
a first unit between the first electrode and the second electrode; and
a second layer between the first electrode and the first unit;
a second light-emitting device comprising:
a third electrode adjacent to the first electrode;
a fourth electrode;
a second unit between the third electrode and the fourth electrode; and
a third layer between the third electrode and the second unit; and
a first layer,
wherein the first unit comprises a first light-emitting material,
wherein the second layer has an electrical resistivity greater than or equal to 1×10⁴ Ω·cm and less than or equal to 1×10⁷ Ω·cm in a film state,
wherein a first gap is between the first electrode and the third electrode,
wherein the second unit comprises a second light-emitting material,
wherein the first layer comprises a first region between the first electrode and the second layer, a second region between the third electrode and the third layer, and a third region between the first region and the second region,
wherein the third region overlaps with the first gap, and
wherein the first layer has an insulating property.

2. The display apparatus according to claim 1,
wherein a second gap is between the second layer and the third layer, and
wherein the second gap overlaps with the first gap.

3. The display apparatus according to claim 1,
wherein the first layer comprises a first opening and a second opening,
wherein the first opening overlaps with the first electrode, and
wherein the second opening overlaps with the third electrode.

4. The display apparatus according to claim 1, further comprising a fourth layer,
wherein the fourth layer is between the first unit and the second electrode,
wherein the fourth layer is between the second unit and the fourth electrode,
wherein the fourth layer is in contact with the first layer in a region overlapping with the first gap,
wherein the fourth layer comprises a third opening and a fourth opening,
wherein the third opening overlaps with the first electrode, and
wherein the fourth opening overlaps with the third electrode.

5. The display apparatus according to claim 4, further comprising a fifth layer,
wherein the fifth layer is between the fourth layer and the second electrode,
wherein the fifth layer is between the fourth layer and the fourth electrode,
wherein the fifth layer is in contact with the fourth layer in a region overlapping with the first gap,
wherein the fifth layer comprises a fifth opening and a sixth opening,
wherein the fifth opening overlaps with the first electrode, and
wherein the sixth opening overlaps with the third electrode.

6. A display apparatus comprising:
a first light-emitting device comprising:
a first electrode;
a second electrode;
a first unit between the first electrode and the second electrode;
a third unit between the first unit and the second electrode; and
a first intermediate layer between the first unit and the third unit;
a second light-emitting device comprising:
a third electrode adjacent to the first electrode;
a fourth electrode;
a second unit between the third electrode and the fourth electrode;
a fourth unit between the second unit and the fourth electrode; and
a second intermediate layer between the second unit and the fourth unit; and
a first layer,
wherein the first unit comprises a first light-emitting material,
wherein the third unit comprises a third light-emitting material,
wherein the first intermediate layer comprises a sixth layer and a seventh layer,
wherein the sixth layer is between the third unit and the seventh layer,
wherein the sixth layer comprises a material having a spin density greater than or equal to 1×10¹⁸ spins/cm³ observed by an electron spin resonance method when the material is in a film state,
wherein the seventh layer comprises a material having a spin density less than or equal to 1×10¹⁷ spins/cm³ observed by an electron spin resonance method when the material is in a film state,
wherein a first gap is between the first electrode and the third electrode,
wherein the second unit comprises a second light-emitting material,
wherein the fourth unit comprises a fourth light-emitting material,
wherein a third gap is between the first intermediate layer and the second intermediate layer,
wherein the third gap overlaps with the first gap,
wherein the first layer comprises a first region between the first electrode and the first intermediate layer, a second region between the third electrode and the second intermediate layer, and a third region between the first region and the second region,
wherein the third region overlaps with the first gap, and
wherein the first layer has an insulating property.

7. The display apparatus according to claim 6,
wherein the first layer comprises a first opening and a second opening,
wherein the first opening overlaps with the first electrode, and
wherein the second opening overlaps with the third electrode.

8. The display apparatus according to claim 6,
wherein the sixth layer has an electrical resistivity greater than or equal to 1×10⁴ Ω·cm and less than or equal to 1×10⁷ Ω·cm in a film state,
wherein the seventh layer comprises a first organic compound and a second organic compound,
wherein the first organic compound has an acid dissociation constant pKa larger than or equal to 8, and
wherein the second organic compound comprises no pyridine ring, no phenanthroline ring, or one phenanthroline ring.

9. The display apparatus according to claim 6,
wherein the sixth layer has an electrical resistivity greater than or equal to 1×10⁴ Ω·cm and less than or equal to 1×10⁷ Ω·cm in a film state,
wherein the seventh layer comprises a first organic compound and a second organic compound,
wherein the first organic compound has an acid dissociation constant pKa larger than or equal to 8, and
wherein the second organic compound has an acid dissociation constant pKa smaller than 4.

10. The display apparatus according to claim 6,
wherein the sixth layer has an electrical resistivity greater than or equal to 1×10⁴ Ω·cm and less than or equal to 1×10⁷ Ω·cm in a film state,
wherein the seventh layer comprises a first organic compound and a second organic compound,
wherein the first organic compound has an acid dissociation constant pKa larger than or equal to 8, and
wherein the second organic compound has a polarization term op less than or equal to 4.0 MPa^{0.5} of a solubility parameter δ.

11. The display apparatus according to claim 6, further comprising a fourth layer,
wherein the fourth layer is between the second electrode and the fourth electrode,
wherein the fourth layer is between the second unit and the fourth electrode,
wherein the fourth layer is in contact with the first layer in a region overlapping with the first gap,
wherein the fourth layer comprises a third opening and a fourth opening,
wherein the third opening overlaps with the first electrode, and
wherein the fourth opening overlaps with the third electrode.

12. The display apparatus according to claim 11, further comprising a fifth layer,
wherein the fifth layer is between the fourth layer and the second electrode,
wherein the fifth layer is between the fourth layer and the fourth electrode,
wherein the fifth layer is in contact with the fourth layer in a region overlapping with the first gap,
wherein the fifth layer comprises a fifth opening and a sixth opening,
wherein the fifth opening overlaps with the first electrode, and
wherein the sixth opening overlaps with the third electrode.

13. A display module comprising:
the display apparatus according to claim 6; and
at least one of a connector and an integrated circuit.

14. An electronic device comprising:
the display apparatus according to claim 6; and
at least one of a battery, a camera, a speaker, and a microphone.
